(19) United States
(12) Patent Application Publication
(10) Pub. No.: US 2009/0246693 A1
(43) Pub. Date: Oct. 1, 2009

(54) NEGATIVE-WORKING LITHOGRAPHIC PRINTING PLATE PRECURSOR AND METHOD OF LITHOGRAPHIC PRINTING USING SAME

(76) Inventors: Takashi NAKAMURA, Haibara-gun (JP); Norio Aoshima, Haibara-gun (JP); Yu Iwai, Haibara-gun (JP)

Correspondence Address: BIRCH STEWART KOLASCH & BIRCH, PO BOX 747, FALLS CHURCH, VA, 22040-0747, US

(21) Appl. No.: 12/413,115

(22) Filed: Mar. 27, 2009

(30) Foreign Application Priority Data
Mar. 28, 2008 (JP) 2008-087161
Aug. 29, 2008 (JP) 2008-221175

(51) Int. Cl. G03F 7/20; G03F 7/004

(52) U.S. Cl. 430/283.1; 430/270.1; 430/325

(57) ABSTRACT

A negative-working lithographic printing plate precursor is disclosed that can be developed on the press without going through a development processing step, and a method of lithographic printing is also disclosed that uses this negative-working lithographic printing plate precursor. Also disclosed are a negative-working lithographic printing plate precursor that can be developed by a water-soluble resin-containing aqueous solution and a method of lithographic printing that uses this negative-working lithographic printing plate precursor. A negative-working lithographic printing plate precursor is provided that exhibits an excellent fine line reproducibility in nonimage areas even when printing is performed using ultraviolet-curing ink (UV ink). Also provided is a negative-working lithographic printing plate precursor that exhibits an excellent combination of fine line reproducibility and printing durability and that resists the production of scum during on-press development. The negative-working lithographic printing plate precursor has a hydrophilic support and has thereon a photopolymerizable layer that contains a polymer compound that has the urea bond in the side chain position and a hydrophilic group. The method of lithographic printing uses this negative-working lithographic printing plate precursor.

### BACKGROUND OF THE INVENTION

1. Field of the Invention

The present invention relates to a lithographic printing plate precursor and to a method of lithographic printing that uses this lithographic printing plate precursor. More particularly, the present invention relates to negative-working lithographic printing plate precursor that enables direct platemaking in which platemaking is carried out directly based on a digital signal from, e.g., a computer, by scanning with, for example, a laser having a wavelength from 300 to 1200 nm. The present invention further relates to a method of lithographic printing in which printing is carried out, without going through a development processing step, by directly developing the aforementioned lithographic printing plate precursor on the press. The present invention further relates to a method of lithographic printing in which printing is carried out after a development processing step has been executed on the lithographic printing plate precursor using a gum solution.

2. Description of the Related Art

A lithographic printing plate typically comprises an oleophilic image area that is ink receptive during the printing process and a hydrophilic nonimage area that is fountain solution receptive during the printing process. Lithographic printing is a method that utilizes the fact that water and oleophilic ink repel each other: differences in the ink attachment behavior are produced on the surface of the lithographic printing plate by using the oleophilic image areas on the lithographic printing plate as ink receptive areas and using the hydrophilic nonimage areas on the lithographic printing plate as fountain solution receptive areas (areas not receptive to ink). After ink uptake has been brought about only in the image areas, the ink is transferred to the receiving medium, e.g., paper.

A lithographic printing plate precursor (PS plate) comprising an oleophilic photosensitive resin layer (image recording layer) disposed on a hydrophilic support has heretofore been widely used to produce the aforementioned lithographic printing plate. Platemaking is typically carried out by a method in which the lithographic printing plate precursor is exposed to light through an original image, for example, a lith film, after which the areas forming the image areas of the image recording layer remain while the unwanted image recording layer outside these areas is dissolved and removed by an alkaline developing solution or an organic solvent to expose the hydrophilic surface of the support, thus yielding the lithographic printing plate.

The conventional platemaking process for lithographic printing plate precursors has required a step in which, after photoexposure, the unwanted image recording layer is dissolved and removed by, for example, a developing solution adapted to the image recording layer; however, a concern with these separately conducted wet processes has been to render them unnecessary or to simplify them. In particular, attention to the global environment has in recent years caused the disposal of the waste solutions discharged in association with these wet processes to become a major issue for the industrial sector as a whole, and as a consequence there has been an even stronger desire to address the aforementioned concern.

In this context, the method known as on-press development has been introduced as a convenient platemaking method. In on-press development, an image recording layer is used that enables the removal of unwanted areas of the image recording layer to be carried out during an ordinary printing process: after photoexposure, the lithographic printing plate is obtained by removal of the unwanted areas of the image recording layer on the press.

The following are examples of specific methods of on-press development: use of a lithographic printing plate precursor that has an image recording layer that can be dissolved or dispersed in the fountain solution, in the ink solvent, or in an emulsion of the fountain solution and ink; mechanical removal of the image recording layer by contact with rollers or the blanket cylinder on the press; mechanical removal of the image recording layer by carrying out contact with rollers or the blanket cylinder after the cohesive strength within the image recording layer or the adhesive force between the image recording layer and support has been weakened by penetration by, for example, the fountain solution or the ink solvent.

Unless stated otherwise, in the present invention, the “development processing step” refers to a step in which the hydrophilic surface of the support is exposed by the removal of those areas of the image recording layer that have not been exposed to the laser, wherein this removal is effected by contact with a fluid (typically an alkaline developing solution) using an apparatus (typically an automatic developing apparatus) outside of the press, and “on-press development” denotes a step and a method in which the hydrophilic surface of the support is exposed by the removal of those areas of the image recording layer that have not been exposed to the laser, wherein this removal is effected by contact with a fluid (typically the printing ink and/or fountain solution) using the press.

In another convenient platemaking method, removal of the unwanted areas of the image recording layer is carried out with a gum solution (this is typically an aqueous solution that contains a hydrophilic resin), i.e., gum development is carried out, and subsequent to this contact with printing ink and fountain solution on the press is executed in a conventional manner and printing is carried out.

At the same time, digital technology, in which the image data is electronically processed, stored, and output using a computer, has become widespread during the last few years, and various new image output methods have entered into practice in association with this digital technology. Accompanying this, interest has been growing in computer-to-plate (CTP) technology, in which the digitized image data is carried by a highly convergent beam of radiation, for example, laser light, and the lithographic printing plate precursor is subjected to a scanning photoexposure with this light in order to directly produce the lithographic printing plate without going through lith film. As a consequence, the appearance of lithographic printing plate precursors adapted to this technology has become a technical problem of the utmost importance.

Thus, as described in the preceding, based on global environmental concerns and the need to adapt and conform to digital technology, there has recently been an even stronger desire than before for a simplification of platemaking technology, for its conversion to a dry technology, and for its conversion into a processless technology.

Within the sphere of lithographic printing plate precursors, a scanning-photoexposable lithographic printing plate precursor comprising a hydrophilic support bearing an oleophilic photosensitive resin layer that contains a photosensitive compound that can produce an active species (e.g., a radical or a Bronsted acid) upon laser photoexposure has been introduced and has already appeared on the market. An active species can be produced by scanning this lithographic printing plate precursor with a laser based on digital data, and this action causes a physical or chemical change in the photosensitive layer, which induces insolubilization. A negative-working lithographic printing plate is then obtained by executing a development process. In particular, the advantages of excellent productivity, simple development processing, good resolution, and good receptivity are provided by a lithographic printing plate precursor comprising a hydrophilic support provided with a photopolymerizable photosensitive layer containing a photopolymerizable initiator with an excellent photosensitive speed, an addition-polymerizable ethylenically unsaturated compound, and a binder polymer soluble in alkaline development solution, and optionally provided with an oxygen-blocking protective layer, thus providing a plate that exhibits desirable printing characteristics.

The lithographic printing plate precursor described in Japanese Patent No. 2,938,397 is an example of an on-press-developable lithographic printing plate precursor. In this lithographic printing plate precursor, an image-forming layer comprising particles of a hydrophobic thermoplastic polymer dispersed in a hydrophilic binder is disposed on a hydrophilic support. The essential narrative laid out in Japanese Patent No. 2,938,397 is as follows: this lithographic printing plate precursor is photoexposed by an infrared laser in order to bring about image formation by the heat-induced coalescence of the hydrophobic thermoplastic polymer particles and is thereafter installed on the cylinder in the press and can be on-press developed by the fountain solution and/or the ink.

This method of causing image formation by coalescence by the simple thermal melting/bonding of finely divided particles does exhibit an excellent on-press developability; however, the image strength (adhesion to the support) is very weak and the printing durability is thus inadequate.

This on-press developability can be evaluated, for example, in terms of the number of waste sheets of paper, that is, the number of sheets of printing paper required when on-press development is started to reach a state in which ink is not transferred to the nonimage areas.

The lithographic printing plate precursor described in Japanese Patent Application Publication Nos. 2001-277740 and 2001-277742 comprises a hydrophilic support on which there is disposed an image recording layer (heat-sensitive layer) comprising microcapsules that enclose a polymerizable compound.

A lithographic printing plate precursor is described in Japanese Patent Application Publication No. 2002-287334 in which an image recording layer (photosensitive layer) comprising an infrared absorber, a radical polymerization initiator, and a polymerizable compound is disposed on a support.

Due to the high chemical bond density in the image areas, the use of these polymerization reactions does characteristically provide a relatively better image strength than is provided by the image areas formed by the hot melting/bonding of finely divided polymer particles; however, when viewed in terms of practicality, the on-press developability, fine line reproducibility, and printing durability are all still unsatisfactory. In particular, the printing durability using UV inks is very unsatisfactory.

An on-press-developable lithographic printing plate precursor is also described in US Published Application 2003-0064318. This on-press-developable lithographic printing plate precursor comprises a support bearing an image recording layer that contains a polymerizable compound and a graft polymer having pendant polyethylene oxide chains or a block polymer that has a polyethylene oxide block.

The use of this art does provide an excellent on-press developability, but the fine line reproducibility is still inadequate. This fine line reproducibility refers to the reproducibility of a nonimage area interposed between fine lines. In specific terms, using an image chart in which a fine line image of constant width is disposed in alternation with an interposed nonimage area of the same width, the fine line reproducibility refers to the degree to which the nonimage areas between the fine line images on the print are not interrupted by scumming. This characteristic is referred to hereafter as the nonimage area fine line reproducibility or the fine line reproducibility.

In particular, the nonimage area fine line reproducibility is even worse with a UV ink than for a standardly used printing ink (e.g., process ink).

Separately from the preceding, another problem is that components of a photopolymerizable layer that has undergone a typical on-press development form a scum on the dampening roller and ink roller, which impairs the maintenance characteristics of the press and lowers the print quality.

The nonimage area fine line reproducibility is similarly poor even with gum development; moreover, a relatively large amount of scum is produced in gum development and re-attachment to the plate by the scum floating in the liquid has been a problem.

### DISCLOSURE OF THE INVENTION

### Problem to be Solved by the Invention

An object of the present invention is to provide a negative-working lithographic printing plate precursor that can record an image when subjected to photoexposure with a laser. A further object of the present invention is to provide a negative-working lithographic printing plate precursor that can be developed on the press without carrying out a development processing step and a method of lithographic printing that uses this negative-working lithographic printing plate precursor. Another object of the present invention is to provide a negative-working lithographic printing plate precursor that can be developed by an aqueous solution that contains a water-soluble resin and a method of lithographic printing that uses this negative-working lithographic printing plate precursor.

A particular object of the present invention is to provide a negative-working lithographic printing plate precursor that performs satisfactorily with regard to all of the following and that does so even with UV ink: developability, nonimage area fine line reproducibility, inhibition of scum production, and printing durability.

### Means to Solve the Problem

As a result of investigations into various polymer compounds in order to achieve the objects cited above, the present inventors discovered that these objects could be achieved by the use in the photopolymerizable layer (image recording layer) of a polymer compound that has a plurality of specific functional groups. The present invention was achieved based on this discovery.

Thus, the present invention is a negative-working lithographic printing plate precursor that characteristically comprises a support and thereon a photopolymerizable layer that contains a polymer compound that has the urea bond in side chain position and a hydrophilic group. An example of this polymer compound is a polymer compound having a unit derived from a monomer that has the urea bond in a side chain position and that is represented by the following general formula (I)

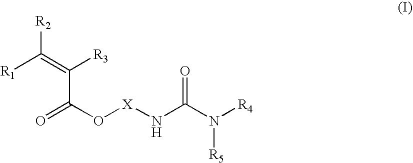

(in the formula, R₁ and R₂ each represent a hydrogen atom, a halogen atom, an alkyl, aryl, heterocyclic group, or a carboxyl group or a salt thereof; R₃ represents a hydrogen atom, a halogen atom, an alkyl or aryl group; R₄ and R₅ each independently represent a hydrogen atom, an alkyl, aryl, or heterocyclic group; and X represents a divalent linking group).

The alkylene oxide structure shown by the following general formula (II) is an example of the hydrophilic group present in the aforementioned polymer compound

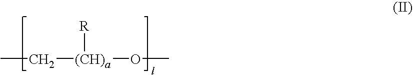

(in the formula, R represents a hydrogen atom or methyl group; a is 1, 3, or 5; and I is an integer of 1 to 9).

In an embodiment of this polymer compound, the polymer compound has an ethylenically unsaturated bond in the side chain position.

In a specific embodiment of the photopolymerizable layer under consideration, this photopolymerizable layer contains, in addition to the polymer compound described above, a sensitizing dye, a polymerization initiator, and a polymerizable monomer. In another embodiment of this photopolymerizable layer, the photopolymerizable layer contains, in addition to the polymer compound described above, an infrared absorber, a polymerization initiator, and a polymerizable monomer. In another embodiment this polymerizable layer contains microcapsules or a microgel.

The aforementioned polymer compound functions as a binder polymer in the photopolymerizable layer. In an embodiment of the present invention, the mass ratio in the aforementioned photopolymerizable layer between binder polymer including the aforementioned polymer compound, having the urea bond in the side chain position and a hydrophilic group, and the polymerizable monomer (binder polymer/polymerizable monomer) is preferably 3/2 to 1/3.

An undercoat layer comprising a compound that has a group that adsorbs to the hydrophilic support and an addition-polymerizable ethylenic double bond may be disposed between the hydrophilic support and the photopolymerizable layer in the negative-working lithographic printing plate precursor of the present invention.

A photopolymerizable layer that can be removed by printing ink and/or fountain solution is a specific exemplary embodiment of the photopolymerizable layer in the negative-working lithographic printing plate precursor of the present invention; in a more specific embodiment, this photopolymerizable layer is removable by UV ink and/or fountain solution.

Such a negative-working lithographic printing plate precursor can be used in methods of lithographic printing that utilize on-press development. Accordingly, the present invention is also directed to a method of lithographic printing that uses the hereinabove-described negative-working lithographic printing plate precursor. More particularly, the present invention is a method of lithographic printing comprising mounting the aforementioned negative-working lithographic printing plate precursor on a press and thereafter subjecting the negative-working lithographic printing plate precursor to imagewise exposure with a laser, or subjecting the negative-working lithographic printing plate precursor to imagewise exposure with a laser and thereafter mounting the same on a press; removing unexposed areas of the photopolymerizable layer by feeding printing ink and fountain solution to the negative-working lithographic printing plate precursor to perform printing. In a specific example of the inventive method of lithographic printing, printing is carried out by removing unexposed areas of the polymerizable layer by supplying a IN ink and fountain solution to the negative-working lithographic printing plate precursor.

In a specific exemplary embodiment of the photopolymerizable layer in the negative-working lithographic printing plate precursor according to the present invention, the photopolymerizable layer can be removed by an aqueous solution that contains a water-soluble resin. In a more specific exemplary embodiment of this photopolymerizable layer, it can be removed by an aqueous solution that contains a water-soluble resin and that has a pH in the range from 8.5 to 10.8. In another specific embodiment of this photopolymerizable layer, the photopolymerizable layer can be removed by an aqueous solution that contains carbonate ion, bicarbonate ion, and water-soluble resin and that has a pH in the range from 8.5 to 10.8. In the case of the photopolymerizable layer removable by an aqueous solution that contains a water-soluble resin and that has a pH in the range from 8.5 to 10.8, the hydrophilic group in the aforementioned polymer compound is preferably an acid group; this acid group can be, for example, the carboxyl group and so forth. Thus, the present invention is also a method of lithographic printing comprising imagewise photoexposing the aforementioned negative-working lithographic printing plate precursor with a laser; removing unexposed areas of the photopolymerizable layer by carrying out a development process by effecting contact with an aqueous solution that contains a water-soluble resin and rubbing with a brush; mounting the lithographic printing plate precursor on a press; and printing while supplying printing ink and fountain solution to the negative-working lithographic printing plate precursor.

The objects cited above can be achieved by the present invention through the use of the polymer compound that has the urea bond in side chain position and a hydrophilic group. While the action mechanism here is not certain, it is believed that due to the presence of the urea bond, the penetration/permeation of the fountain solution (or the aqueous solution containing a water-soluble resin) in the nonimage areas is accelerated by the high polarity exhibited by the urea bond, which facilitates removal.

It is also hypothesized that the presence of the urea bond in the molecule facilitates dispersion in the aqueous component by the components that have been removed and thereby acts to prevent the removed components from making scum. In addition, the presence of the hydrophilic group accelerates these properties.

### Effect of the Invention

The negative-working lithographic printing plate precursor of the present invention exhibits an excellent on-press developability, can reduce the number of waste sheets of paper (i.e., the number of sheets of printing paper required when on-press development is started to reach a state in which ink is not transferred to the nonimage areas), exhibits an excellent fine line reproducibility, and can inhibit scum production, and thus enables good productivity and high-quality printing.

In addition, the negative-working lithographic printing plate precursor of the present invention also exhibits an excellent developability by an aqueous solution that contains a water-soluble resin, and when employed in simplified platemaking using a water-soluble resin-containing aqueous solution provides an excellent fine line reproducibility and acts to prevent scum production because it also provides a good dispersibility for the photopolymerizable layer components that been developed by such an aqueous solution. As a result, the negative-working lithographic printing plate precursor of the present invention can in this case again enable good productivity and high-quality printing. Moreover, the execution of development with a weakly basic, water-soluble resin-containing aqueous solution using the negative-working lithographic printing plate precursor of the present invention can provide a platemaking method for lithographic printing plates that exhibits an excellent developability and an excellent fine line reproducibility; that prevents the production of development scum; that is resistant to scumming in nonimage areas sandwiched by fine lines - and that is resistant even when printing is carried out using a UV ink (ultraviolet-curing ink); and that also provides printing durability.

Moreover, the negative-working lithographic printing plate precursor of the present invention can provide long runs of high-quality printed material even when printing is carried out using a UV ink.

The negative-working lithographic printing plate precursor of the present invention also makes it possible to proceed via a method of lithographic printing that employs on-press development or via a method of lithographic printing that employs development with a water-soluble resin-containing aqueous solution.

### BRIEF DESCRIPTION OF THE DRAWINGS

FIG. 1 shows the structure, in schematic form, of an example of an automatic developing apparatus that can be used to carry out development with a water-soluble resin-containing aqueous solution, wherein the reference numbers in the figure are defined as follows: 10 refers to a development processing section, 12 refers to a lithographic printing plate, 14 refers to a development section, 16 refers to a water rinse section, 18 refers to a desensitization section, 20 refers to a drying section, 24 refers to a development tank, 141 and 142 refer to a brush roller (rubbing member), and 200 refers to a pre-treatment section;

FIG. 2 shows the structure, in schematic form, of an example of an automatic developing apparatus that can be used to carry out development with a water-soluble resin-containing aqueous solution, wherein the reference numbers in the figure are defined as follows: 1 refers to a rotating brush roll, 2 refers to a receiving roll, 3 refers to a transport roll, 4 refers to a transport guide plate, 5 refers to a spray pipe, 6 refers to a conduit, 7 refers to a filter, 8 refers to a plate feed table, 9 refers to a plate discharge table, 100 refers to a developing fluid tank, 101 refers to a circulation pump, and 102 refers to a plate; and

FIG. 3 shows the structure, in schematic form, of an example of an apparatus that carries out mechanical surface roughening of an aluminum support.

### MODE CARRYING OUT THE INVENTION

The Negative-Working Lithographic Printing Plate Precursor

The prerequisite for the negative-working lithographic printing plate precursor of the present invention is the presence of a laser-sensitive photopolymerizable layer on a hydrophilic support. The photopolymerizable layer and other constituent elements are described in detail in the following.

### [The Special Polymer Binder]

The photopolymerizable layer in the negative-working lithographic printing plate precursor of the present invention contains, as an essential component, a polymer compound whose molecule contains the urea bond in side chain position and a hydrophilic group (where appropriate, this polymer compound is referred to below as the special polymer binder). This functions as a binder for the image-forming layer. It is used in the image-forming layer mainly for the purpose of forming a continuous layer. A polymer compound that has a chain structure is more preferred from the standpoint of the nonimage area fine line reproducibility. A polymer compound that has a crosslinked structure is more preferred from the standpoints of the developability, fine line reproducibility, and prevention of scum attachment.

In particular, the presence of this special polymer binder results in an excellent on-press developability, an excellent gum developability, and an excellent nonimage area fine line reproducibility when printing is carried out using a UV ink.

The special polymer binder under consideration is obtained by the copolymerization, in a suitable solvent and using a known polymerization initiator, of a urea bond-containing polymerizable monomer and a hydrophilic group-containing polymerizable monomer.

Compounds represented by general formula (I) are preferably used as a suitable polymerizable monomer that contains the urea bond in the molecule.

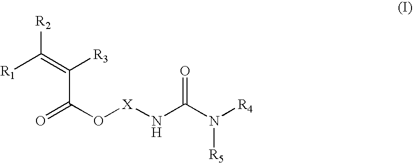

In formula (I), R₁ and R₂ each represent the hydrogen atom, a halogen atom, alkyl, aryl, a heterocyclic group, or the carboxyl group or a salt thereof; R₃ represents the hydrogen atom, a halogen atom, alkyl, or aryl; R₄ and R₅ each independently represent the hydrogen atom, alkyl, aryl, or a heterocyclic group; and X represents a divalent linking group.

The halogen atom represented by R₁ and R₂ is exemplified by the fluorine atom, chlorine atom, bromine atom, and iodine atom, wherein the fluorine atom, chlorine atom, and bromine atom are preferred and the chlorine atom is particularly preferred.

C₁₋₂₀ straight chain alkyl, C₁₋₂₀ branched alkyl, and C₁₋₂₀ cyclic alkyl are preferred examples of the alkyl represented by R₁ and R₂. More preferred thereamong are C₁₋₁₂ straight chain alkyl, C₃₋₁₂ branched alkyl, and C₅₋₁₀ cyclic alkyl. Specific examples are methyl, ethyl, propyl, butyl, pentyl, hexyl, heptyl, octyl, nonyl, decyl, undecyl, dodecyl, tridecyl, hexadecyl, octadecyl, eicosyl, isopropyl, isobutyl, s-butyl, t-butyl, isopentyl, neopentyl, 1-methylbutyl, isohexyl, 2-ethylhexyl, 2-methylhexyl, cyclohexyl, cyclopentyl, and 2-norbornyl.

The aryl represented by R₁ and R₂ is preferably C₅₋₂₀, more preferably C₆₋₁₈, and particularly preferably C₆₋₁₂ substituted or unsubstituted aryl.

Preferred examples are phenyl, 4-methylphenyl, 4-methoxyphenyl, 4-chlorophenyl, 4-(dimethylamino)-1-naphthyl, 2-naphthyl, biphenyl, xylyl, mesityl, cumenyl, bromophenyl, chloromethylphenyl, hydroxyphenyl, methoxyphenyl, ethoxyphenyl, phenoxyphenyl, acetoxyphenyl, benzoyloxyphenyl, methylthiophenyl, phenylthiophenyl, methylaminophenyl, dimethylaminophenyl, acetylaminophenyl, carboxyphenyl, methoxycarbonylphenyl, ethoxyphenylcarbonyl, phenoxycarbonylphenyl, N-phenylcarbamoylphenyl, cyanophenyl, sulfophenyl, sulfonatophenyl, phosphonophenyl, and phosphonatophenyl.

The heterocyclic group represented by R₁ and R₂ is preferably a 3- to 8-membered ring, more preferably a 3- to 6-membered ring, and particularly preferably a 5- or 6-membered ring. The type of heteroatom constituting the heterocycle preferably includes the nitrogen atom, oxygen atom, or sulfur atom. The heterocyclic group represented by R₁ and R₂ may bear a substituent.

Preferred examples are the pyrrole ring, furan ring, thiophene ring, benzopyrrole ring, benzofuran ring, benzothiophene ring, pyrazole ring, isoxazole ring, isothiazole ring, indazole ring, benzoisoxazole ring, benzoisothiazole ring, imidazole ring, oxazole ring, thiazole ring, benzimidazole ring, benzoxazole ring, benzothiazole ring, pyridine ring, quinoline ring, isoquinoline ring, pyridazine ring, pyrimidine ring, pyrazine ring, phthalazine ring, quinazoline ring, quinoxaline ring, aziridine ring, phenanthridine ring, carbazole ring, purine ring, pyran ring, piperidine ring, piperazine ring, morpholine ring, indole ring, indolizine ring, chromene ring, cinnoline ring, acridine ring, phenothiazine ring, tetrazole ring, triazine ring, and so forth.

The halogen atom, alkyl, and aryl represented by R₃ are defined as for the halogen, alkyl, and aryl represented by R₁ and R₂.

The alkyl, aryl, and heterocyclic group represented by R₄ and R₅ are defined as for the alkyl, aryl, and heterocyclic group represented by R₁ and R₂.

X, which represents a divalent linking group, is exemplified by possibly substituted C₁₋₁₂ alkylene and possibly substituted phenylene.

The polymerizable monomer that contains the urea bond in the molecule can be produced, for example, by the following method.

A polymerizable monomer having at least one urea bond and at least one polymerizable unsaturated bond in each molecule can be obtained by reacting the isocyanate compound shown by the following general formula (III) with the amine compound shown by the following general formula (IV)

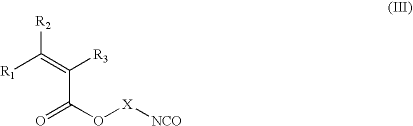

(in the formula, R₁ and R₂ each independently represent the hydrogen atom, a halogen atom, alkyl, aryl, or the carboxyl group or a salt thereof; R₃ represents the hydrogen atom, a halogen atom, alkyl, or aryl; and X represents a divalent linking group)

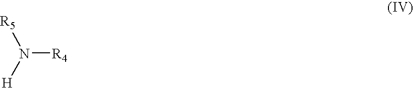

(in the formula, R₄ and R₅ each independently represent the hydrogen atom, alkyl, aryl, or a heterocyclic group).

R₄ is preferably a possibly substituted phenylene group or a possibly substituted naphthylene group. The presence of the hydroxyl group or the carboxyl group or sulfonamide group as a substituent is particularly preferred. The presence of the sulfonamide group is most preferred. R₅ is preferably the hydrogen atom or a possibly substituted alkyl group.

With regard to the execution of this reaction, solvents lacking active hydrogen are suitably used from among the known common organic solvents described below. With regard to the reaction time, the reaction should be run until the isocyanate group disappears and the amount of the urea bond reaches a constant level. The reaction time is generally 15 minutes to 24 hours.

The reaction mixture obtained by proceeding in the above-described manner can be directly used as the monomer with general formula (I). However, the high-purity monomer with general formula (I) may also be obtained by carrying out the following in order to remove the by-products and the unreacted starting material when the reaction was run in a system containing excess compound with general formula (IV): conversion of the compound with general formula (IV) to the salt by neutralization with an acidic compound, for example, dilute hydrochloric acid, followed by a water wash, filtration, and drying under a vacuum.

The monomer with general formula (I) obtained in the described manner has a characteristic absorption based on the urea bond at 1600 to 1700 cm⁻¹ in the infrared absorption spectrum, and the corresponding measurement can thus be used to identify this compound. It can also be identified through the boiling point, proton NMR, and so forth.

Examples of this polymerizable monomer are as follows: acrylate derivatives such as 1-(N′-(4-hydroxyphenyl)ureido)methyl acrylate, 1-(N′-(3-hydroxyphenyl)ureido)methyl acrylate, 1-(N′-(2-hydroxyphenyl)ureido)methyl acrylate, 1-(N′-(3-hydroxy-4-methylphenyl)ureido)methyl acrylate, 1-(N′-(2-hydroxy-5-methylphenyl)ureido)methyl acrylate, 1-(N′-(5-hydroxynaphthyl)ureido)methyl acrylate, 1-(N′-(2-hydroxy-5-phenylphenyl)ureido)methyl acrylate, 2-(N′-(4-hydroxyphenyl)ureido)ethyl acrylate, 2-(N′-(3-hydroxyphenyl)ureido)ethyl acrylate, 2-(N′-(2-hydroxyphenyl)ureido)ethyl acrylate, 2-(N′-(3-hydroxy-4-methylphenyl)ureido)ethyl acrylate, 2-(N′-(2-hydroxy-5-methylphenyl)ureido)ethyl acrylate, 2-(N′-(5-hydroxynaphthyl)ureido)ethyl acrylate, 2-(N′-(2-hydroxy-5-phenylphenyl)ureido)ethyl acrylate, 4-(N′-(4-hydroxyphenyl)ureido)butyl acrylate, 4-(N′-(3-hydroxyphenyl)ureido)butyl acrylate, 4-(N′-(2-hydroxyphenyl)ureido)butyl acrylate, 4-(N′-(3-hydroxy-4-methylphenyl)ureido)butyl acrylate, 4-(N′-(2-hydroxy-5-methylphenyl)ureido)butyl acrylate, 4-(N′-(5-hydroxynaphthyl)ureido)butyl acrylate, and 4-(N′-(2-hydroxy-5-phenylphenyl)ureido)butyl acrylate, and methacrylate derivatives such as 1-(N′-(4-hydroxyphenyl)ureido)methyl methacrylate, 1-(N′-(3-hydroxyphenyl)ureido)methyl methacrylate, 1-(N′-(2-hydroxyphenyl)ureido)methyl methacrylate, 1-(N′-(3-hydroxy-4-methylphenyl)ureido)methyl methacrylate, 1-(N′-(2-hydroxy-5-methylphenyl)ureido)methyl methacrylate, 1-(N′-(5-hydroxynaphthyl)ureido)methyl methacrylate, 1-(N′-(2-hydroxy-5-phenylphenyl)ureido)methyl methacrylate, 2-(N′-(4-hydroxyphenyl)ureido)ethyl methacrylate, 2-(N′-(3-hydroxyphenyl)ureido)ethyl methacrylate, 2-(N′-(2-hydroxyphenyl)ureido)ethyl methacrylate, 2-(N′-(3-hydroxy-4-methylphenyl)ureido)ethyl methacrylate, 2-(N′-(2-hydroxy-5-methylphenyl)ureido)ethyl methacrylate, 2-(N′-(5-hydroxynaphthyl)ureido)ethyl methacrylate, 2-(N′-(2-hydroxy-5-phenylphenyl)ureido)ethyl methacrylate, 4-(N′-(4-hydroxyphenyl)ureido)butyl methacrylate, 4-(N′-(3-hydroxyphenyl)ureido)butyl methacrylate, 4-(N′-(2-hydroxyphenyl)ureido)butyl methacrylate, 4-(N′-(3-hydroxy-4-methylphenyl)ureido)butyl methacrylate, 4-(N′-(2-hydroxy-5-methylphenyl)ureido)butyl methacrylate, 4-(N′-(5-hydroxynaphthyl)ureido)butyl methacrylate, and 4-(N′-(2-hydroxy-5-phenylphenyl)ureido)butyl methacrylate.

For example, 2-(N′-(4-hydroxyphenyl)ureido)ethyl methacrylate can be identified through its boiling point of 131 to 133° C. and its absorption in the IR spectrum based on the urea bond as noted above and the hydroxyl group.

The following are other examples of polymerizable monomers containing a polymerizable unsaturated bond and the urea bond that are suitable for use to produce the special polymer binder used by the present invention: acid group-containing acrylates such as 2-(N′-(4-carboxyphenyl)ureido)ethyl acrylate, 2-(N′-(4-sulfamoylphenyl)ureido)ethyl acrylate, 2-(N′-(4-sulfophenyl)ureido)ethyl acrylate, and 2-(N′-(4-phosphonophenyl)ureido)ethyl acrylate; acid group-containing methacrylates such as 2-(N′-(4-carboxyphenyl)ureido)ethyl methacrylate, 2-(N′-(4-sulfamoylphenyl)ureido)ethyl methacrylate, 2-(N′-(4-sulfophenyl)ureido)ethyl methacrylate, and 2-(N′-(4-phosphonophenylureido)ethyl methacrylate; acrylates that lack an acidic group, such as 2-(N′-methylureido)ethyl acrylate, 2-(N′-propylureido)ethyl acrylate, 2-(N′-phenylureido)ethyl acrylate, 2-(N′-(4-methylphenyl)ureido)ethyl acrylate, 2-(N′-(2-methylphenyl)ureido)ethyl acrylate, 2-(N′-naphthylureido)ethyl acrylate, and 2-(N′-(2-phenylphenyl)ureido)ethyl acrylate; and methacrylates that lack an acidic group, such as 2-(N′-methylureido)ethyl methacrylate, 2-(N′-propylureido)ethyl methacrylate, 2-(N′-phenylureido)ethyl methacrylate, 2-(N′-(4-methylphenyl)ureido)ethyl methacrylate, 2-(N′-(2-methylphenyl)ureido)ethyl methacrylate, 2-(N′-naphthylureido)ethyl methacrylate, and 2-(N′-(2-phenylphenyl)ureido)ethyl methacrylate For example, 2-(N′-(4-carboxyphenyl)ureido)ethyl methacrylate can be identified through its decomposition temperature of 220° C. and its absorption in the IR spectrum based on the urea bond as noted above and the carboxyl group.

Only a single urea bond-containing structural unit may be used in the special polymer binder used by the present invention, or two or more urea bond-containing structural units may be present in the special polymer binder used by the present invention. Viewed in particular from the perspective of the fine line reproducibility, the special polymer binder contains preferably 1 to 80 mol %, more preferably 5 to 80 mol %, and most preferably 10 to 50 mol % urea bond-containing structural unit.

The special binder polymer used by the present invention also contains a hydrophilic group. This hydrophilic group speeds up the on-press developability of the photopolymerizable layer and also speeds up the developability by the water-soluble resin-containing aqueous solution; in addition, it acts to lessen the problems of impaired press maintainability and impaired printing quality that are caused when components of the on-press-developed photopolymerizable layer form a scum on the dampening roller and ink roller.

This hydrophilic group can be exemplified by the hydroxyl group, carboxyl group, carboxylate group, hydroxyethyl group, alkylene oxide structures, hydroxypropyl group, polyoxyethyl group, polyoxypropyl group, amino group, aminoethyl group, aminopropyl group, ammonium group, amide group, carboxymethyl group, sulfonic acid group, phosphoric acid group, and so forth, wherein preferred examples are the amide group, hydroxyl group, polyoxyethyl group, and alkylene oxide structures. Alkylene oxide structures given by the following general formula (II) are the most preferred. The special binder polymer preferably has this alkylene oxide structure in side chain position.

This alkylene oxide structure exhibits a suitable hydrophilicity while lacking an ionic group, and for this reason provides an excellent balance between image area durability and on-press developability or gum developability as the case may be. Moreover, because it also exhibits flexibility due to its straight chain structure, it additionally provides an excellent behavior in terms of not inhibiting microfine-sizing and dispersion of the on-press development scum produced on the rollers in the press.

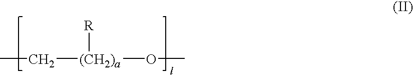

In formula (II), R represents the hydrogen atom or methyl; a is 1, 3, or 5; and I represents an integer from 1 to 9. I is an integer preferably from 1 to 8, more preferably from 1 to 7, even more preferably from 1 to 6, and most preferably from 2 to 4.

The following are specific examples of monomers for introducing a hydrophilic group as described above into the special polymer binder: acrylamide, methacrylamide, N,N-dimethylacrylamide, N-isopropylacrylamide, N-vinylpyrrolidone, N-vinylacetamide, N-acryloylmorpholine, 2-hydroxyethyl acrylate, 2-hydroxyethyl methacrylate, polyoxyethylene monomethacrylate, polyoxyethylene monoacrylate, polyoxypropylene monomethacrylate, and polyoxypropylene monoacrylate. A single one of these or two or more may be used. The content of the hydrophilic group-containing structural unit in the special polymer binder is preferably 1 to 70 mol %, more preferably 10 to 60 mol %, and most preferably 20 to 50 mol %. When too little is present, a satisfactory developability and a satisfactory fine line reproducibility are not obtained; when too much is present, the special polymer binder becomes overly flexible and the printing durability may be unsatisfactory.

The carboxyl group is particularly preferred for the hydrophilic group in those instances in which the gum developing bath used with the present invention is weakly alkaline. The develop ability is improved and scum production is inhibited by the introduction of the carboxyl group into the special polymer compound.

In order to improve various properties, such as the image strength, and insofar as the effects of the present invention are not impaired, in another preferred embodiment at least one other radically polymerizable monomer is copolymerized into the special polymer binder used by the present invention in addition to the substituent-bearing monomer already described in the preceding. Monomer that can be copolymerized into the special polymer binder in the present invention can be exemplified by monomer selected from acrylate esters, methacrylate esters, N,N-disubstituted-acrylamides, N,N-disubstituted-methacrylamides, styrenes, acrylonitriles, and methacrylonitriles.

Specific examples are as follows: acrylate esters such as alkyl acrylates (the alkyl preferably has from 1 to 20 carbons) and so forth, as specifically exemplified by methyl acrylate, ethyl acrylate, propyl acrylate, butyl acrylate, amyl acrylate, ethylhexyl acrylate, octyl acrylate, t-octyl acrylate, chloroethyl acrylate, 2,2-dimethylhydroxypropyl acrylate, 5-hydroxypentyl acrylate, trimethylolpropane monoacrylate, pentaerythritol monoacrylate, glycidyl acrylate, benzyl acrylate, methoxybenzyl acrylate, furfuryl acrylate, tetrahydrofurfuryl acrylate, and so forth, as well as aryl acrylates such as phenyl acrylate and so forth; methacrylate esters such as alkyl methacrylates (the alkyl preferably has from 1 to 20 carbons) and so forth, for example, methyl methacrylate, ethyl methacrylate, propyl methacrylate, isopropyl methacrylate, amyl methacrylate, hexyl methacrylate, cyclohexyl methacrylate, benzyl methacrylate, chlorobenzyl methacrylate, octyl methacrylate, 4-hydroxybutyl methacrylate, 5-hydroxypentyl methacrylate, 2,2-cdimethyl-3-hydroxypropyl methacrylate, trimethylolpropane monomethacrylate, pentaerythritol monomethacrylate, glycidyl methacrylate, furfuryl methacrylate, tetrahydrofurfuryl methacrylate, and so forth, as well as aryl methacrylates such as phenyl methacrylate, cresyl methacrylate, naphthyl methacrylate, and so forth; styrenes such as styrene, alkylstyrenes, and so forth, for example, methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, acetoxymethylstyrene, and so forth, and also alkoxystyrenes such as methoxystyrene, 4-methoxy-3-methylstyrene, dimethoxystyrene, and so forth, as well as halostyrenes such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene; acrylonitrile; and methacrylonitrile.

The special polymer binder used by the present invention may also contain an ester group with the following formula (V) or an amide group with the following formula (VI) in the molecule.

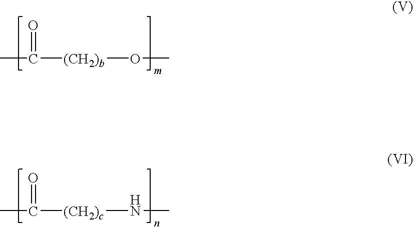

In the preceding formulas, b is an integer from 2 to 5; c is an integer from 2 to 7; and m and n each independently represent integers from 1 to 100.

Preferred for use among the preceding radically polymerizable monomers are the acrylate esters, methacrylate esters, and styrenes. One or two or more of these can be used, and a suitable content for these copolymerization components is 0 to 95 mol % and particularly preferably 20 to 90 mol %.

The special polymer binder used in the present invention may be a block copolymer, random copolymer, or graft copolymer.

In order to improve the film properties of the photopolymerizable layer and improve the on-press developabihty and gum developability, in another preferred embodiment in the present invention at least one ethylenically unsaturated bond is present in side chain position on the binder resin. Accordingly, the special polymer binder used by the present invention preferably has in side chain position at least one group having an ethylenically unsaturated bond, for example, a group represented by general formulas (1) to (3) below. In the image areas, these ethylenically unsaturated bond-containing structures, through their reaction with other polymerizable compounds (e.g., monomer present in the photopolymerizable layer), serve to ensure a satisfactory chemical resistance and printing durability. On the other hand, in the nonimage areas, the flexibility is increased due to their presence in side chain position, which enables an improved on-press developability and gum developability for the unexposed areas.

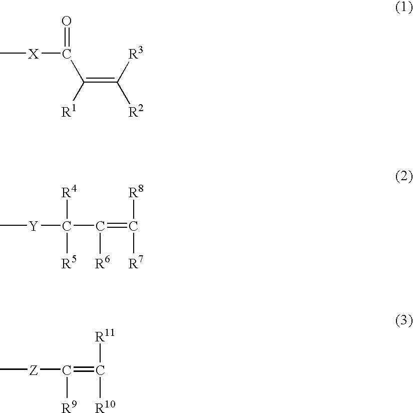

(In the formulas, X and Y each independently represent the oxygen atom, sulfur atom, or —N(R¹²)—. Z represents the oxygen atom, sulfur atom, —N(R¹²)—, or phenylene. R¹ to R¹² each independently represent a monovalent substituent.)

R¹ to R³ in general formula (1) each independently represent a monovalent substituent. For example, R¹ can be the hydrogen atom or a monovalent organic group, for example, a possibly substituted alkyl group, whereamong the hydrogen atom, methyl group, methylalkoxy groups, and methyl ester groups are preferred. R² and R³ are each independently, for example, the hydrogen atom, a halogen atom, the amino group, dialkylamino, the carboxyl group, alkoxycarbonyl, the sulfo group, the nitro group, the cyano group, possibly substituted alkyl, possibly substituted aryl, possibly substituted alkoxy, possibly substituted aryloxy, possibly substituted alkylamino, possibly substituted arylamino, possibly substituted alkylsulfonyl, and possibly substituted arylsulfonyl; preferred thereamong are the hydrogen atom, the carboxyl group, alkoxycarbonyl, possibly substituted alkyl, and possibly substituted aryl. In the case of substitution, the substituents that can be introduced here can be exemplified by methoxycarbonyl, ethoxycarbonyl, isopropyloxycarbonyl, methyl, ethyl, phenyl, and so forth. X represents the oxygen atom, sulfur atom, or —N(R¹²)—, and R¹² can be, for example, possibly substituted alkyl.

R⁴ to R⁸ in general formula (2) each independently represent a monovalent substituent, for example, the hydrogen atom, a halogen atom, the amino group, dialkylamino, the carboxyl group, alkoxycarbonyl, the sulfo group, the nitro group, the cyano group, possibly substituted alkyl, possibly substituted aryl, possibly substituted alkoxy, possibly substituted aryloxy, possibly substituted alkylamino, possibly substituted arylamino, possibly substituted alkylsulfonyl, possibly substituted arylsulfonyl, and so forth. Preferred thereamong are the hydrogen atom, the carboxyl group, alkoxycarbonyl, possibly substituted alkyl, possibly and substituted aryl. In the case of substitution, the substituents that can be introduced are exemplified by those provided for general formula (1). Y represents the oxygen atom, sulfur atom, or —N(R¹²)—. R¹² can be as described for general formula (1).

R⁹ to R¹¹ in general formula (3) each independently represent a monovalent substituent, for example, the hydrogen atom, a halogen atom, the amino group, dialkylamino, the carboxyl group, alkoxycarbonyl, the sulfo group, the nitro group, the cyano group, possibly substituted alkyl, possibly substituted aryl, possibly substituted alkoxy, possibly substituted aryloxy, possibly substituted alkylamino, possibly substituted arylamino, possibly substituted alkylsulfonyl, and possibly substituted arylsulfonyl, whereamong the hydrogen atom, carboxyl group, alkoxycarbonyl, possibly substituted alkyl, and possibly substituted aryl are preferred. In the case of substitution, the substituents here are exemplified by those provided for general formula (1). Z represents the oxygen atom, sulfur atom, —N(R¹²)—, or phenylene. R¹² can be as described for general formula (1).

The methacryloyloxy group represented by general formula (1) is preferred among the preceding.

In those instances in which an ethylenically unsaturated bond-containing structural unit as described above is introduced into the special polymer binder, its content according to iodine titration (measurement of the content of radically polymerizable unsaturated double bonds) is preferably 0.1 to 10.0 mmol, more preferably 1.0 to 7.0 mmol, and most preferably 2.0 to 5.5 mmol, in each case per 1 g of the special polymer binder. An excellent sensitivity and an excellent storage stability are obtained in the cited range.

The solvent used in the synthesis of the special polymer binder used by the present invention can be exemplified by ethylene dichloride, cyclohexanone, methyl ethyl ketone, acetone, methanol, ethanol, propanol, butanol, ethylene glycol monomethyl ether, ethylene glycol monoethyl ether, 2-methoxyethy acetate, 1-methoxy-2-propanol, 1-methoxy-2-propyl acetate, N,N-dimethylformamide, N,N-dimethylacetamide, dimethyl sulfoxide, toluene, ethyl acetate, methyl lactate, ethyl lactate, and so forth. A single one of these solvents or a mixture of two or more may be used.

The mass-average molecular weight Mw of the special polymer binder used by the present invention is preferably at least 2,000 and more preferably is in the range of 5,000 to 300,000. The range of 20,000 to 300,000 is even more preferred from the standpoint of the chemical resistance, while the range of 20,000 to 100,000 is most preferred from the standpoint of the on-press developability In addition, the special polymer binder according to the present invention may contain unreacted monomer. The proportion of the monomer in the special polymer binder in such a case is desirably no more than 15 mass %.

The content of the special polymer binder present in the photopolymerizable layer in the negative-working lithographic printing plate precursor of the present invention is preferably 5 to 80 mass % as the solids fraction, more preferably 5 to 50 mass % as the solids fractions, and most preferably 5 to 30 mass % as the solids fractions. An excellent image area strength and an excellent image formability are obtained in the cited range Specific examples of the special polymer binder used by the present invention are shown below, but this polymer compound used by the present invention is not limited to the following examples, and use can be made of appropriate changes in the structure and quantity of addition brought about by the combination with the components of the coating fluid for producing the printing plate precursor.

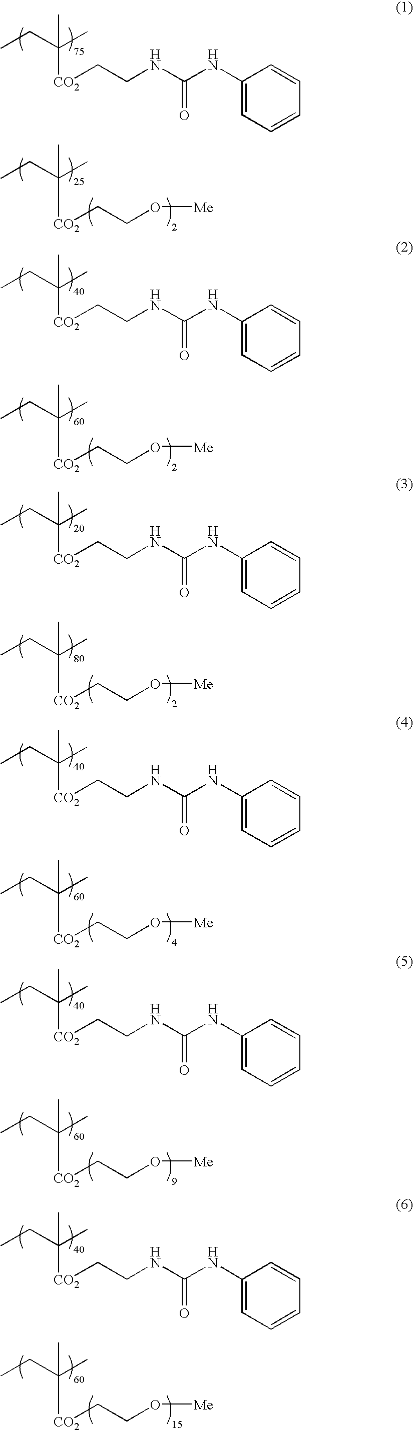

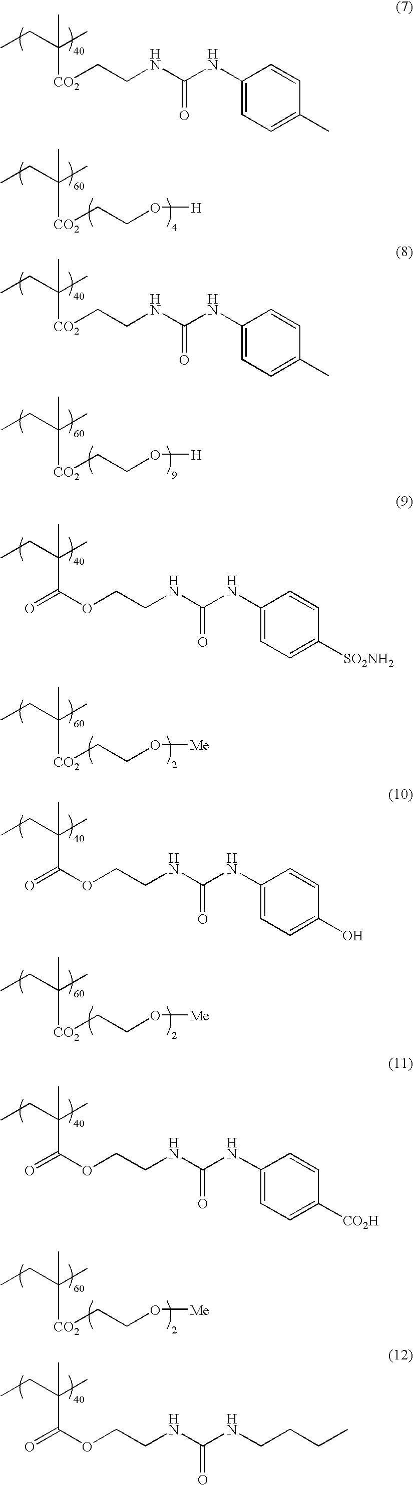

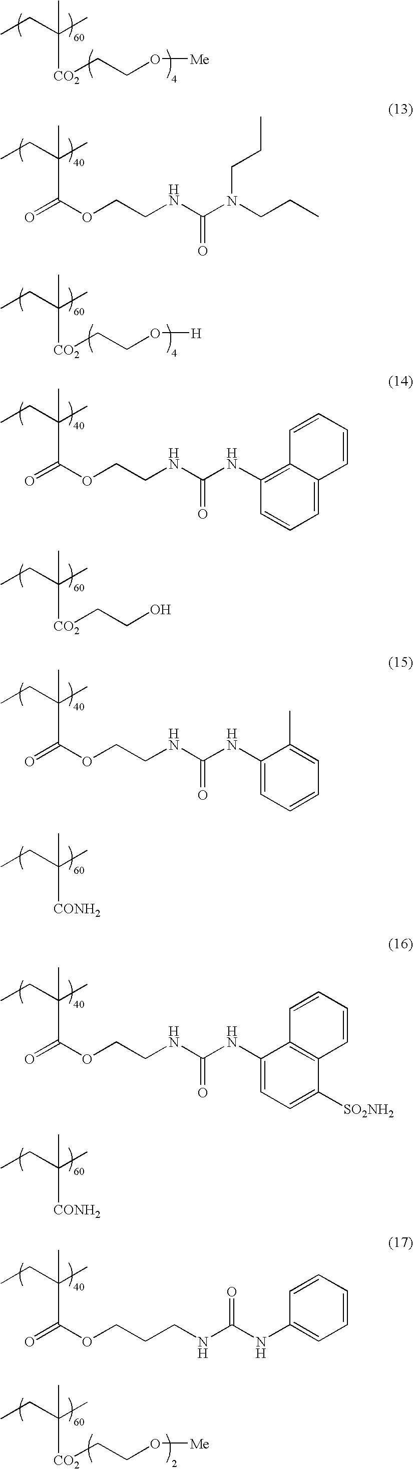

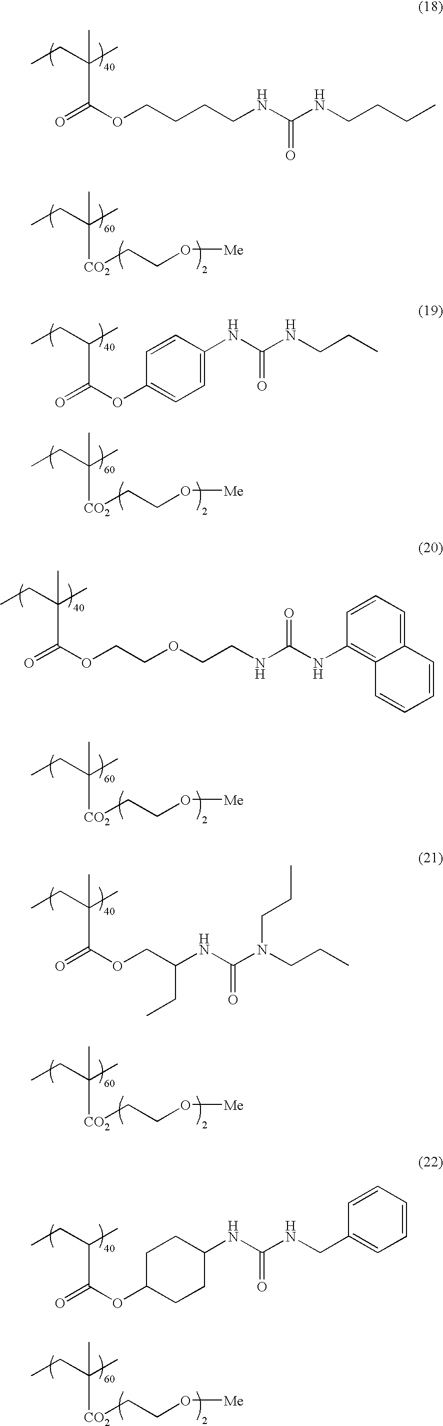

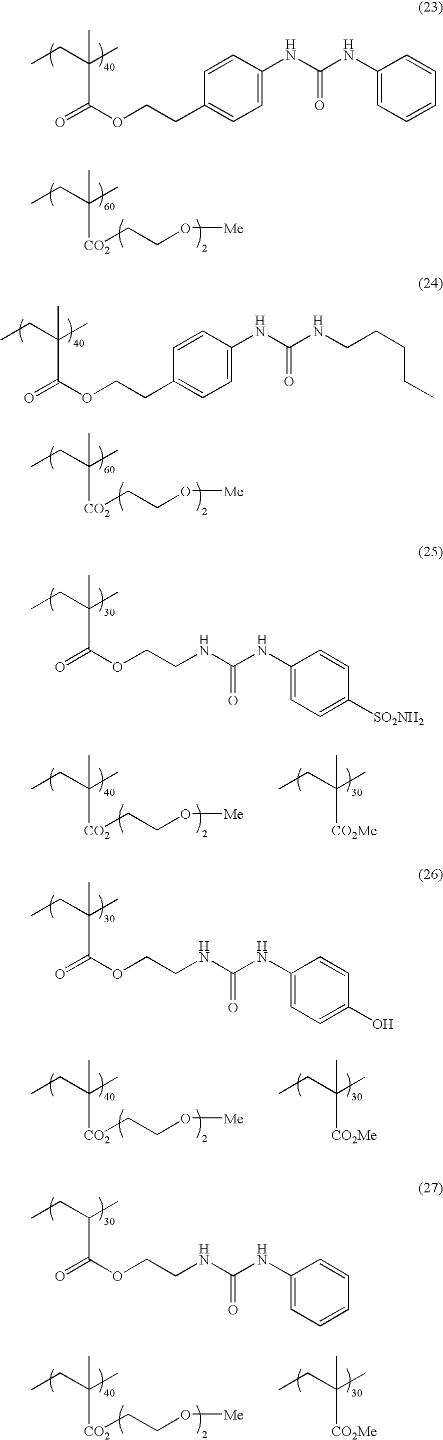

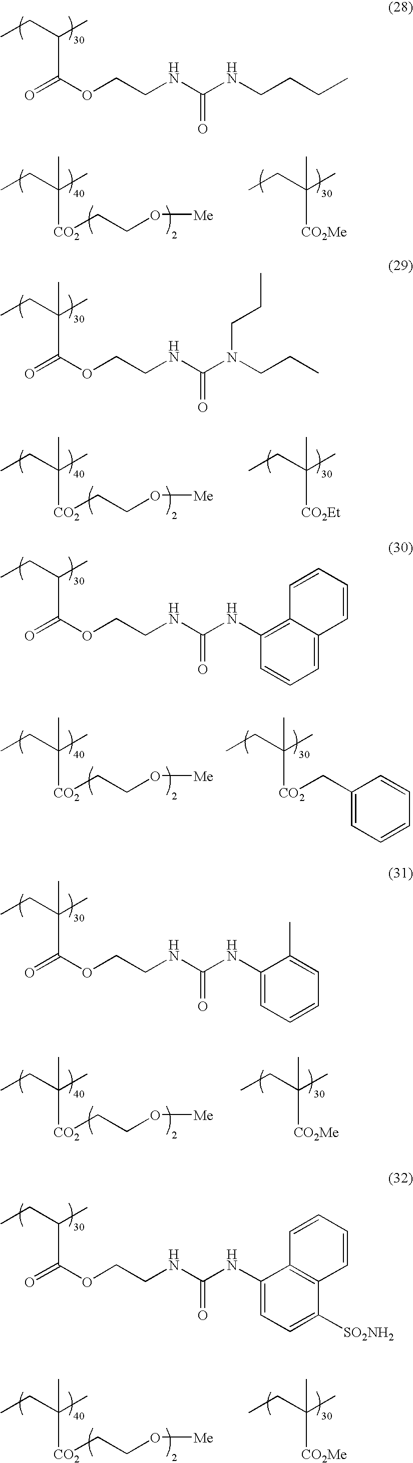

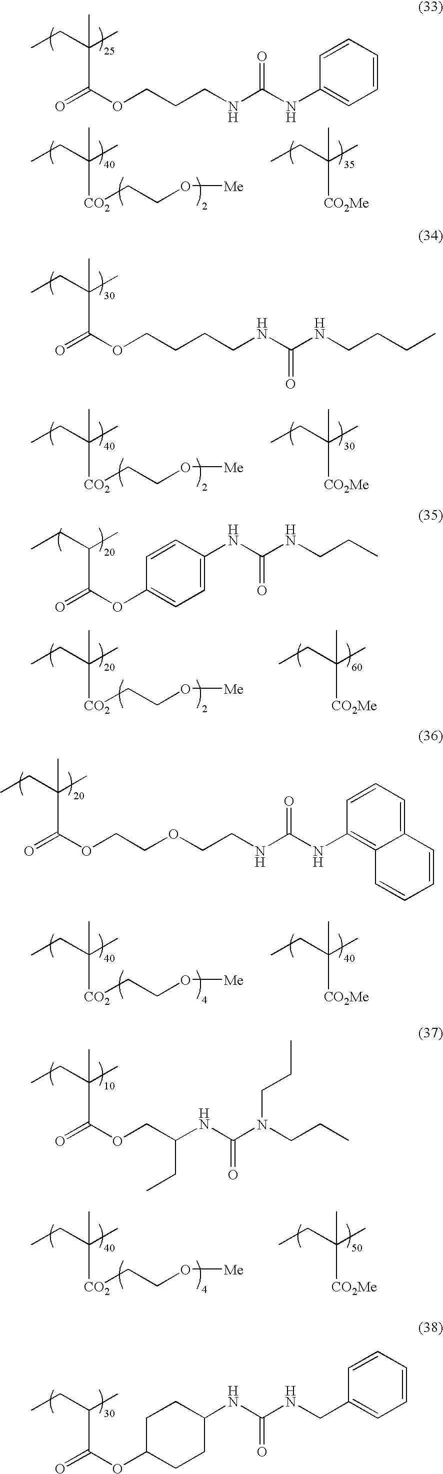

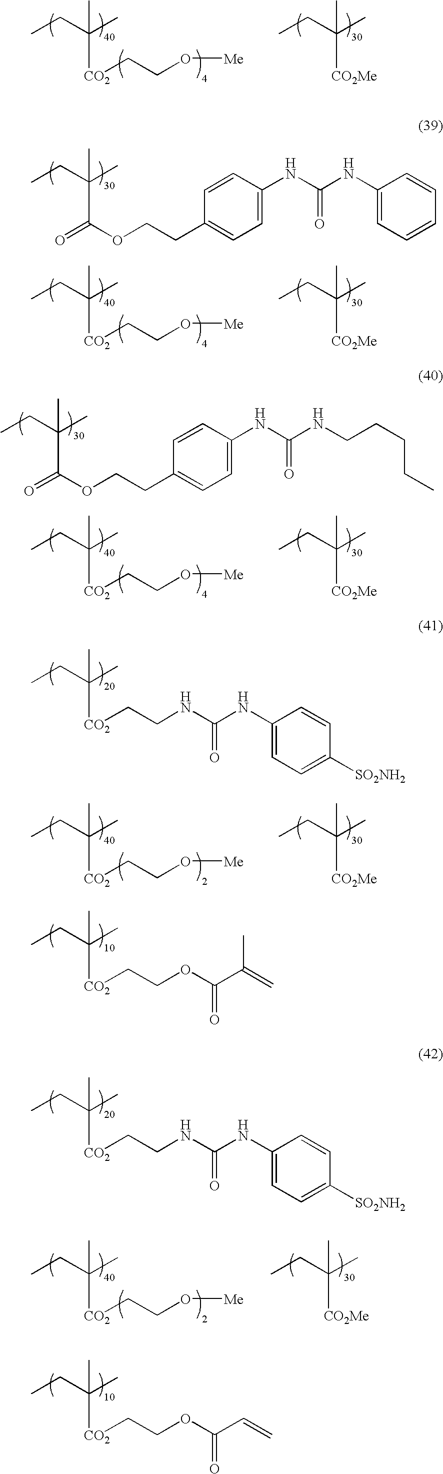

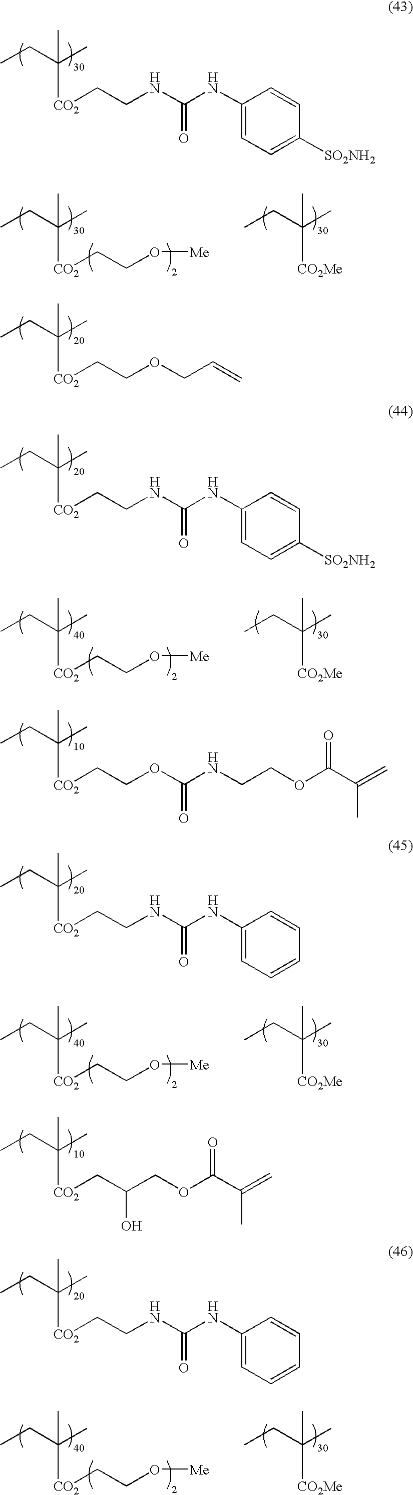

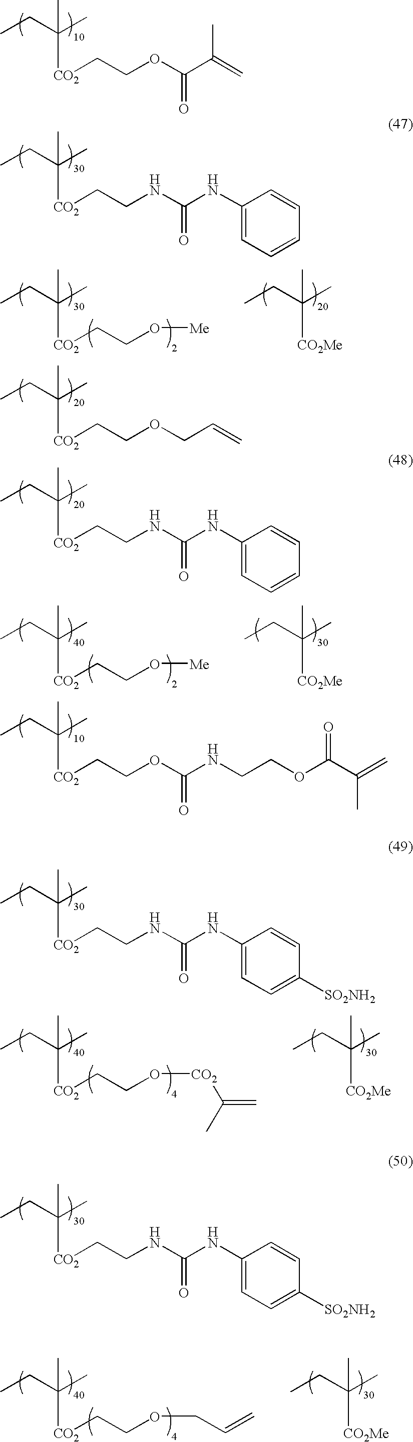

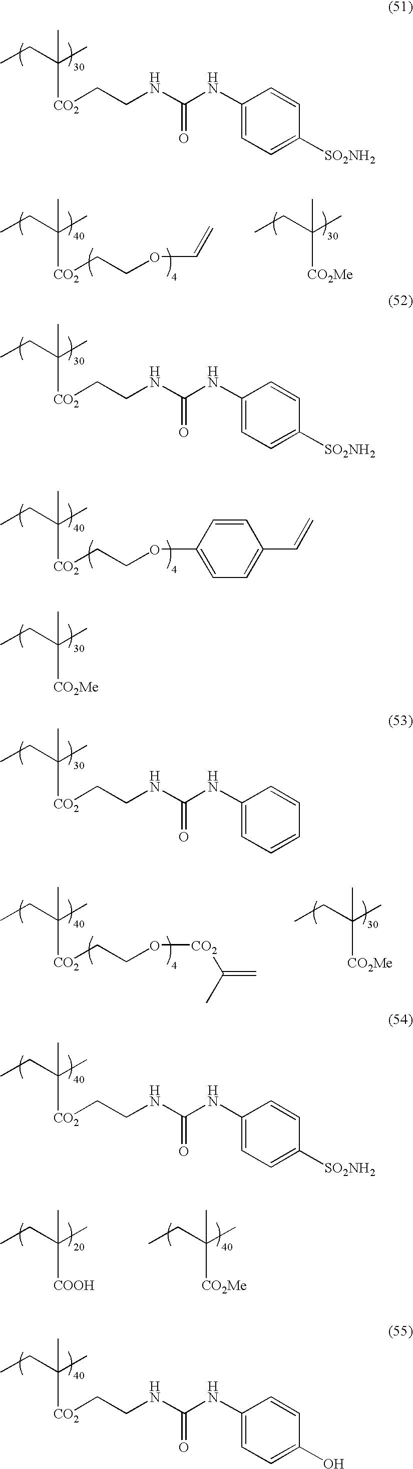

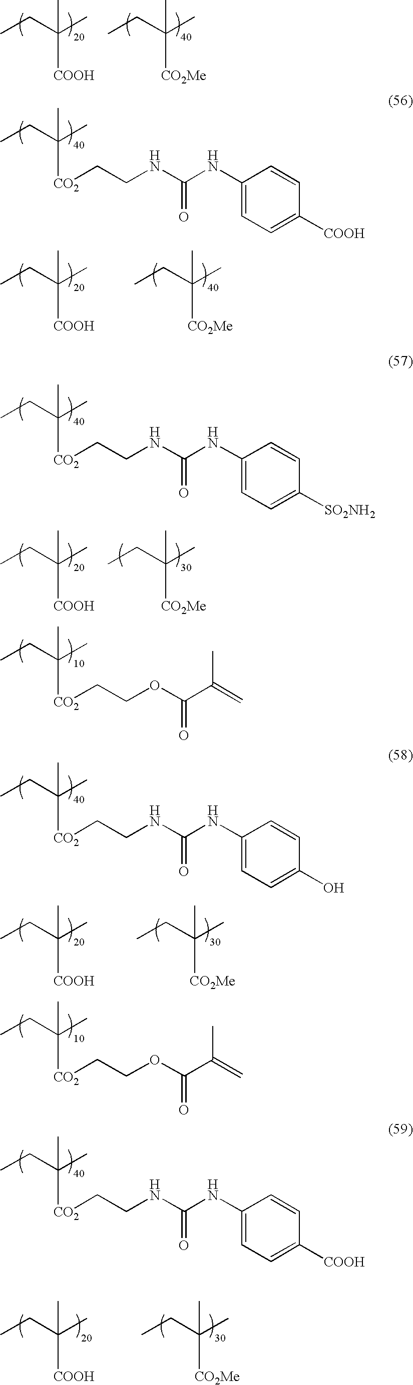

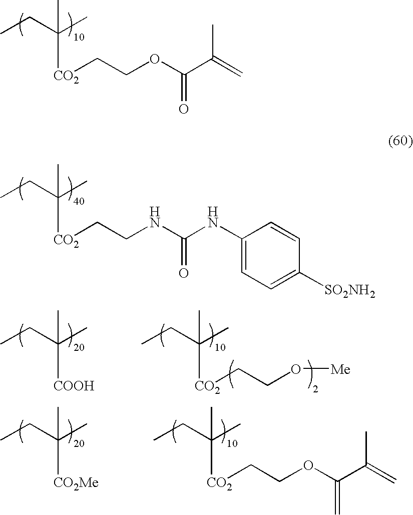

### [Other Binder Polymers]

Along with the special polymer binder described in the preceding, heretofore known binder polymers may be used without limitation in the negative-working lithographic printing plate precursor of the present invention, whereamong chain-form organic polymers having a film-forming capacity are preferred. Examples of such binder polymers are acrylic resins, polyvinyl acetal resins, polyurethane resins, polyurea resins, polyimide resins, polyamide resins, epoxy resins, methacrylic resins, polystyrene resins, novolac-type phenolic resins, polyester resins, synthetic rubbers, and natural rubbers.

The binder polymer may be crosslinkable in order to improve the film strength of the image areas. A crosslinkable functional group, e.g., an ethylenically unsaturated bond, may be introduced into the main chain of the polymer or in side chain position on the polymer in order to impart crosslinkability to the binder polymer. The crosslinkable functional group may be introduced through copolymerization.

Examples of polymers that have ethylenically unsaturated bonds in the molecular main chain are poly-1,4-butadiene, poly-1,4-isoprene, and so forth.

Examples of polymers that have ethylenically unsaturated bonds in side chain position on the molecule are polymers of an ester or amide of acrylic acid or methacrylic acid wherein the ester or amide residue (R in —COOR or CONHR) contains an ethylenically unsaturated bond.

Examples of the ethylenically unsaturated bond-containing residue (the R cited above) are as follows: CR¹═CR²R³, —(CH₂)ₙCR¹═CR²R³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, —(CH₂)ₙ—O—CO—CR¹═CR²R³, and (CH₂CH₂O)₂—X (in these formulas, R¹ to R³ each represent the hydrogen atom, a halogen atom, or C₁₋₂₀ alkyl, aryl, alkoxy, or aryloxy; R¹ may be bonded with R² or R³ to form a ring; n is an integer from 1 to 10; and X is the dicyclopentadienyl residue).

The following are specific examples of the ester residue: —CH═CH₂, —C(CH₃)═CH₂, —CH₂CH═CH₂ (described in Japanese Patent Publication No. Hei 7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂, and CH₂CH₂O—X (X in the formula represents the dicyclopentadienyl residue).

The following are specific examples of the amide residue: —CH═CH₂, —C(CH₃)═CH₂, —CH₂CH═CH₂, —CH₂CH2—Y (Y in the formula represents the cyclohexene residue), and —CH₂CH₂—OCO—CH═CH₂.

For example, a free radical (polymerization-initiating radical or the propagating radical in the polymerization process based on the polymerizable monomer) adds to the crosslinkable functional group in the crosslinkable binder polymer; addition polymerization occurs between polymers, either directly or through a polymer chain from the polymerizable monomer; and curing occurs through the formation of crosslinks between the polymer molecules. Alternatively, an atom in the polymer (for example, a hydrogen atom on a carbon atom adjacent to the functional crosslinking group) is abstracted by a free radical to produce polymer radicals and these bond to each other to bring about curing by the formation of crosslinks between polymer molecules.

The crosslinkable group content in the binder polymer (content of the radically polymerizable unsaturated double bonds as determined by iodine titration) is preferably 0.1 to 10.0 mmol, more preferably 1.0 to 7.0 mmol, and most preferably 2.0 to 5.5 mmol, in each case per 1 g of the binder polymer. An excellent sensitivity and an excellent storage stability are obtained in the cited range.

Viewed from the perspective of improving the on-press developability, the binder polymer preferably has a high solubility or dispersibility in the ink and/or fountain solution.

The binder polymer is preferably oleophilic in order to improve the solubility or dispersibility in inks, and is preferably hydrophilic in order to improve the solubility or dispersibility in fountain solutions. Due to this, the combined used of an oleophilic binder polymer and a hydrophilic binder polymer is also effective in the present invention.

Suitable examples of hydrophilic binder polymers are binder polymers that contain a hydrophilic group such as the hydroxyl group, the carboxyl group, a carboxylate group, hydroxyethyl, polyoxyethyl, hydroxypropyl, polyoxypropyl, the amino group, aminoethyl, aminopropyl, the ammonium group, an amide group, carboxymethyl, the sulfo group, a phosphate group, and so forth.

The following are specific examples: gum arabic, casein, gelatin, starch derivatives, carboxymethyl cellulose and its sodium salt, cellulose acetate, sodium alginate, vinyl acetate-maleic acid copolymers, styrene-maleic acid copolymers, polyacrylic acids and their salts, polymethacrylic acids and their salts, homopolymers and copolymers of hydroxyethyl methacrylate, homopolymers and copolymers of hydroxyethyl acrylate, homopolymers and copolymers of hydroxypropyl methacrylate, homopolymers and copolymers of hydroxypropyl acrylate, homopolymers and copolymers of hydroxybutyl methacrylate, homopolymers and copolymers of hydroxybutyl acrylate, polyethylene glycols, hydroxypropylene polymers, polyvinyl alcohols, hydrolyzed polyvinyl acetate that has a degree of hydrolysis of at least 60 mol % and preferably at least 80 mol %, polyvinyl formal, polyvinyl butyral, polyvinylpyrrolidone, homopolymers and copolymers of acrylamide, homopolymers and copolymers of methacrylamide, homopolymers and copolymers of N-methylolacrylamide, polyvinylpyrrolidone, alcohol-soluble nylon, polyethers between 2,2-bis(4-hydroxyphenyl)propane and epichlorohydrin, and so forth.

The binder polymer has a mass-average molecular weight preferably of at least 5000 and more preferably from 10,000 to 300,000 and a number-average molecular weight preferably of at least 1000 and more preferably from 2000 to 250,000. The polydispersity (mass-average molecular weight/number-average molecular weight) is preferably 1.1 to 10.

The binder polymer may be a random polymer or a block polymer, wherein random polymers are preferred. A single binder polymer may be used, or two or more may be used in combination.

The binder polymer can be acquired as a commercial product or can be acquired by synthesis by known methods. The solvent used during this synthesis can be exemplified by tetrahydrofuran, ethylene dichloride, cyclohexanone, methyl ethyl ketone, acetone, methanol, ethanol, ethylene glycol monomethyl ether, ethylene glycol monoethyl ether, 2-methoxyethyl acetate, diethylene glycol dimethyl ether, 1-methoxy-2-propanol, 1-methoxy-2-propyl acetate, N,N-dimethylformamide, N,N-dimethylacetamide, toluene, ethyl acetate, methyl lactate, ethyl lactate, dimethyl sulfoxide, and water. A single one of these may be used or a mixture of two or more may be used.

Known compounds, such as azo-type initiators, peroxide initiators, and so forth, can be used as the radical polymerization initiator used for synthesis of the binder polymer.

In those instances in the present invention where an additional binder polymer is used in conjunction with the previously described special polymer binder, the content of this binder polymer is 0 to 80 mass %, preferably 0 to 50 mass %, and more preferably 0 to 30 mass %, in each case with reference to the total solids fraction in the photopolymerizable layer. An excellent image area strength and an excellent image formability are obtained in the cited range.

### [The Sensitizing Dye]

A sensitizing dye may be added to the photopolymerizable layer in the lithographic printing plate precursor used by the present invention. This sensitizing dye preferably has an absorption peak at from 300 nm to 850 nm and more preferably has an absorption peak at 300 to 600 nm. Such sensitizing dyes can be exemplified by spectral-sensitizing dyes and dyes or pigments that absorb light from the light source and interact with a photopolymerization initiator.

The following are preferred examples of spectral-sensitizing dyes: polycyclic aromatic compounds (for example, pyrene, perylene, triphenylene), xanthenes (for example, fluorescein, eosine, erythrosin, Rhodamine B, Rose Bengal), cyanines (for example, thiacarbocyanine, oxacarbocyanine), merocyanines (for example, merocyanine, carbomerocyanine), thiazines (for example, thionine, methylene blue, toluidine blue), acridines (or example, acridine orange, chloroflavine, acriflavine), phthalocyanines (for example, phthalocyanine, metallophthalocyanine), porphyrins (for example, tetraphenylporphyrin, center metal-substituted porphyrin), chlorophylls (for example, chlorophyll, chlorophyllin, center metal-substituted chlorophyll), metal complexes, anthraquinones (for example, anthraquinone), and squaliums (for example, squalium).

Examples of spectral-sensitizing dyes that are more preferred are as follows: styryl dyes as described in Japanese Patent Publication No. Sho 37-13034; cationic dyes as described in Japanese Patent Application Publication No. Sho 62-143044; quinoxalinium salts as described in Japanese Patent Publication No. Sho 59-24147; the novel methylene blue compounds described in Japanese Patent Application Publication No. Sho 64-33104; anthraquinones as described in Japanese Patent Application Publication No. Sho 64-56767; benzoxanthene dyes as described in Japanese Patent Application Publication No. Hei 2-1714; acridines as described in Japanese Patent Application Publication Nos. Hei 2-226148 and Hei 2-226149; pyrylium salts as described in Japanese Patent Publication No. Sho 40-28499; cyanines as described in Japanese Patent Publication No. Sho 46-42363; benzofuran dyes as described in Japanese Patent Application Publication No. Hei 2-63053; conjugated ketone dyes as described in Japanese Patent Application Publication Nos. Hei 2-85858 and Hei 2-216154; the dyes described in Japanese Patent Application Publication No. Sho 57-10605; azocinnamylidene derivatives as described in Japanese Patent Publication No. Hei 2-30321; cyanine dyes as described in Japanese Patent Application Publication No. Hei 1-287105; xanthene dyes as described in Japanese Patent Application Publication Nos. Sho 62-31844, Sho 62-31848, and Sho 62-143043; aminostyryl ketones as described in Japanese Patent Publication No. Sho 59-28325; merocyanine dyes as described in Japanese Patent Publication No. Sho 61-9621; the dyes described in Japanese Patent Application Publication No. Hei 2-179643; merocyanine dyes as described in Japanese Patent Application Publication No. Hei 2-244050; merocyanine dyes as described in Japanese Patent Publication No. Sho 59-28326; merocyanine dyes as described in Japanese Patent Application Publication No. Sho 59-89803; merocyanine dyes as described in Japanese Patent Application Publication No. Hei 8-129257; and benzopyran dyes as described in Japanese Patent Application Publication No. Hei 8-334897.

The spectral-sensitizing dye given by the following general formula (12) is even more preferred for the spectral-sensitizing dye used in the present invention.

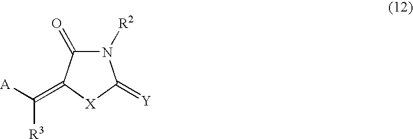

In general formula (12), A represents a possibly substituted aromatic ring or heterocycle; X represents the oxygen atom, sulfur atom, or —N(R¹)—; and Y represents the oxygen atom or —N(R¹)—. R¹, R², and R³ each independently represent the hydrogen atom or a monovalent nonmetal atomic group, and A may be bonded to R¹, R², or R³ with the formation of an aliphatic or aromatic ring.

Here, R¹ preferably represents substituted or unsubstituted alkyl or aryl in those instances in which R¹ represents a monovalent nonmetal atomic group; R² preferably represents substituted or unsubstituted alkyl or aryl in those instances in which R² represents a monovalent nonmetal atomic group; and R³ preferably represents substituted or unsubstituted alkyl or aryl in those instances in which R³ represents a monovalent nonmetal atomic group.

Preferred specific examples of R¹, R², and R³ are provided in the following. Preferred examples of the alkyl are C₁₋₂₀ straight chain alkyl, branched alkyl, and cyclic alkyl, wherein specific examples thereof are methyl, ethyl, propyl, butyl, pentyl, hexyl, heptyl, octyl, nonyl, decyl, undecyl, dodecyl, tridecyl, hexadecyl, octadecyl, eicosyl, isopropyl, isobutyl, s-butyl, t-butyl, isopentyl, neopentyl, 1-methylbutyl, isohexyl, 2-ethylhexyl, 2-methylhexyl, cyclohexyl, cyclopentyl, and 2-norbornyl. More preferred thereamong are C₁₋₁₂ straight chain alkyl, C₃₋₁₂ branched alkyl, and C₅₋₁₀ cyclic alkyl.

A monovalent nonmetal atomic group, excluding hydrogen, can be used for the substituent on the substituted alkyl, and preferred examples of this substituent are as follows: halogen atoms (—F, —Br, —Cl, —I), the hydroxyl group, alkoxy, aryloxy, the mercapto group, alkylthio, arylthio, alkyldithio, aryldithio, the amino group, N-alkylamino, N,N-dialkylamino, N-arylamino, N,N-diarylamino, N-alkyl-N-arylamino, acyloxy, carbamoyloxy, N-alkylcarbamoyloxy, N-arylcarbamoyloxy, N,N-dialkylcarbamoyloxy, N,N-diarylcarbamoyloxy, N-alkyl-N-arylcarbamoyloxy, alkylsulfoxy, arylsulfoxy, acyloxy, acylthio, acylamino, N-alkylacylamino, N-arylacylamino, the ureido group, N′-alkylureido, N′,N′-dialkylureido, N′-arylureido, N′,N′-diarylureido, N′-alkyl-N′-arylureido, N-alkylureido, N-arylureido, N′-alkyl-N-alkylureido, N′-alkyl-N-arylureido, N′,N′-dialkyl-N-alkylureido, N′,N′-dialkyl-N-arylureido, N′-aryl-N-alkylureido, N′-aryl-N-arylureido, N′,N′-diaryl-N-alkylureido, N′,N′-diaryl-N-arylureido, N′-alkyl-N′-aryl-N-alkylureido, N′-alkyl-N′-aryl-N-arylureido, alkoxycarbonylamino, aryloxycarbonylamino, N- alkyl-N - alkoxycarbonylamino, N- alkyl-N-aryloxycarbonylamino, N-aryl-N-alkoxycarbonylamino, N-aryl-N-aryloxycarbonylamino, the formyl group, acyl, the carboxyl group, alkoxycarbonyl, aryloxycarbonyl, the carbamoyl group, N-alkylcarbamoyl, N,N-dialkylcarbamoyl, N-arylcarbamoyl, N,N-diarylcarbamoyl, N-alkyl-N-arylcarbamoyl, alkylsufinyl, arylsulfinyl, alkylsulfonyl, arylsulfonyl, the sulfo group (—SO₃H) and its conjugate base (referred to below as the sulfonato group), alkoxysulfonyl, aryloxysulfonyl, sulfinamoyl, N-alkylsulfinamoyl, N,N-dialkylsulfinamoyl, N-arylsulfinamoyl, N,N-diarylsulfinamoyl, N-alkyl-N-arylsulfinamoyl, sulfamoyl, N-alkylsulfamoyl, N,N-dialkylsulfamoyl, N-arylsulfamoyl, N,N-diarylsulfamoyl, N-alkyl-N-arylsulfamoyl, the phosphono group (—PO₃H₂) and its conjugate base (referred to below as the phosphonato group), dialkylphosphono (—PO₃(alkyl)₂), diarylphosphono (—PO3(aryl)₂), alkylarylphosphono (—PO₃(alkyl)(aryl)), monoalkylphosphono (—PO₃H(alkyl)) and its conjugate base (referred to below as the alkylphosphonato group), monoarylphosphono (—PO₃H(aryl)) and its conjugate base (referred to below as the arylphosphonato group), phosphonooxy (—OPO₃H₂) and its conjugate base (referred to below as the phosphonatooxy group), dialkylphosphonooxy (—OPO₃(alkyl)₂), diarylphosphonooxy (—OPO₃(aryl)₂), alkylarylphosphonooxy (—OPO₃(alkyl)(aryl)), monoalkylphosphonooxy (—OPO₃H(alkyl)) and its conjugate base (referred to below as the alkylphosphonatooxy group), monoarylphosphonooxy (—OPO₃H(aryl)) and its conjugate base (referred to below as the arylphosphonatooxy group), the cyano group, the nitro group, aryl, heteroaryl groups, alkenyl, alkynyl, and silyl.

The alkyl moiety in these substituents is specifically exemplified by the previously described alkyl, and this alkyl may itself also be substituted.

The following are specific examples of the aryl: phenyl, biphenyl, naphthyl, tolyl, xylyl, mesityl, cumenyl, chlorophenyl, bromophenyl, chloromethylphenyl, hydroxyphenyl, methoxyphenyl, ethoxyphenyl, phenoxyphenyl, acetoxyphenyl, benzoyloxyphenyl, methylthiophenyl, phenylthiophenyl, methylaminophenyl, dimethylaminophenyl, acetylaminophenyl, carboxyphenyl, methoxycarbonylphenyl, ethoxyphenylcarbonyl, phenoxycarbonylphenyl, N-phenylcarbamoylphenyl, phenyl, cyanophenyl, sulfophenyl, sulfonatophenyl, phosphonophenyl, phosphonatophenyl, and so forth.

The heteroaryl group is a group derived from a monocyclic or polycyclic aromatic ring system that contains at least one selection from the nitrogen atom, oxygen atom, and sulfur atom, and particularly preferred examples of heteroaryl rings among the heteroaryl groups are as follows: thiophene, thianthrene, furan, pyran, isobenzofuran, chromene, xanthene, phenoxazine, pyrrole, pyrazole, isothiazole, isoxazole, pyrazine, pyrimidine, pyridazine, indolizine, isoindolizine, indole, indazole, purine, quinolizine, isoquinoline, phthalazine, naphthyridine, quinazoline, cinnoline, pteridine, carbazole, carboline, phenanthrene, acridine, perimidine, phenanthroline, phthalazine, phenarsazine, phenoxazine, furazan, and so forth. These groups may additionally be a condensed ring system with benzene or may bear a substituent.

The alkenyl is exemplified by vinyl, 1-propenyl, 1-butenyl, cinnamyl, 2-chloro-1-ethenyl, and so forth. The alkynyl is exemplified by ethynyl, 1-propynyl, 1-butynyl, trimethylsilylethynyl, and so forth. G¹ in the acyl group (G¹CO—) can be exemplified by the hydrogen atom and the preciously described alkyl and aryl. More preferred among these substituents are halogen atoms (—F, —Br, —Cl, —I), alkoxy, aryloxy, alkylthio, arylthio, N-alkylamino, N,N-dialkylamino, acyloxy, N-alkylcarbamoyloxy, N-arylcarbamoyloxy, acylamino, formyl, acyl, the carboxyl group, alkoxycarbonyl, aryloxycarbonyl, carbamoyl, N-alkylcarbamoyl, N,N-dialkylcarbamoyl, N-arylcarbamoyl, N-alkyl-N-arylcarbamoyl, the sulfo group, sulfonato, sulfamoyl, N-alkylsulfamoyl, N,N-dialkylsulfamoyl, N-arylsulfamoyl, N-alkyl-N-arylsulfamoyl, phosphono, phosphonato, dialkylphosphono, diarylphosphono, monoalkylphosphono, alkylphosphonato, monoarylphosphono, arylphosphonato, phosphonooxy, phosphonatooxy, aryl, alkenyl, and alkylidene (e.g., methylene and so forth).

The alkylene moiety in the substituted alkyl is, for example, the divalent organic residue obtained by removing any one of the hydrogen atoms on the C₁₋₂₀ alkyl described above, and preferred examples thereof are C₁₋₁₂ straight chain alkylene, C₃₋₁₂ branched alkylene, and C₅₋₁₀ cyclic alkylene.

The following are specific examples of substituted alkyl preferred for R¹, R², and R³ and obtained by combining alkylene with a substituent as described above: chloromethyl, bromomethyl, 2-chloroethyl, trifluoromethyl, methoxymethyl, methoxyethoxyethyl, allyloxymethyl, phenoxymethyl, methylthiomethyl, tolylthiomethyl, ethylaminoethyl, diethylaminopropyl, morpholinopropyl, acetyloxymethyl, benzoyloxymethyl, N-cyclohexylcarbamoyloxyethyl, N-phenylcarbamoyloxyethyl, acetylaminoethyl, N-methylbenzoylaminopropyl, 2-oxoethyl, 2-oxopropyl, carboxypropyl, methoxycarbonylethyl, allyloxycarbonylbutyl, chlorophenoxycarbonylmethyl, carbamoylmethyl, N-methylcarbamoylethyl, N,N-dipropylcarbamoylmethyl, N-(methoxyphenyl)carbamoylethyl, N-methyl-N-(sulfophenyl)carbamoylmethyl, sulfobutyl, sulfonatopropyl, sulfonatobutyl, sulfamoylbutyl, N-ethylsulfamoylmethyl, N,N-dipropylsulfamoylpropyl, N-tolylsulfamoylpropyl, N-methyl-N-(phosphonophenyl)sulfamoyloctyl, phosphonobutyl, phosphonatohexyl, diethylphosphonobutyl, diphenylphosphonopropyl, methylphosphonobutyl, methylphosphonatobutyl, tolylphosphonohexyl, tolylphosphonatohexyl, phosphonooxypropyl, phosphonatooxybutyl, benzyl, phenethyl, α-methylbenzyl, 1-methyl-1-phenylethyl, p-methylbenzyl, cinnamyl, allyl, 1-propenylmethyl, 2-butenyl, 2-methylallyl, 2-methylpropenylmethyl, 2-propynyl, 2-butynyl, 3-butynyl, and so forth.

Specific examples of aryl groups preferred for R¹, R², and R³ are aryl groups in which from one to three benzene rings form a condensed ring system and aryl groups in which a benzene ring forms a condensed ring system with a 5-membered heterocycle. Specific examples here are phenyl, naphthyl, anthryl, phenanthryl, indenyl, acenaphthenyl, and fluorenyl, wherein phenyl and naphthyl are more preferred thereamong.

Specific examples of substituted aryl groups preferred for R¹, R², and R³ are substituted aryl groups that have a monovalent nonmetal atomic group (excluding the hydrogen atom) as a substituent on a ring-forming carbon atom present in an aryl group as described above. Examples of preferred substituents are the previously described alkyl and substituted alkyl and the substituents previously cited for the substituted alkyl. Preferred examples of the substituted aryl are as follows: biphenyl, tolyl, xylyl, mesityl, cumenyl, chlorophenyl, bromophenyl, fluorophenyl, chloromethylphenyl, trifluoromethylphenyl, hydroxyphenyl, methoxyphenyl, methoxyethoxyphenyl, allyloxyphenyl, phenoxyphenyl, methylthiophenyl, tolylthiophenyl, ethylaminophenyl, diethylaminophenyl, morpholinophenyl, acetyloxyphenyl, benzyloxyphenyl, N-cyclohexylcarbamoyloxyphenyl, N-phenylcarbamoyloxyphenyl, acetylaminophenyl, N-methylbenzoylaminophenyl, carboxyphenyl, methoxycarbonylphenyl, allyloxycarbonylphenyl, chlorophenoxycarbonylphenyl, carbamoylphenyl, N-methylcarbamoylphenyl, N,N-dipropylcarbamoylphenyl, N-(methoxyphenyl)carbamoylphenyl, N-methyl-N-(sulfophenyl)carbamoylphenyl, sulfophenyl, sulfonatophenyl, sulfamoylphenyl, N-ethylsulfamoylphenyl, N,N-dipropylsulfamoylphenyl, N-tolylsulfamoylphenyl, N-methyl-N-(phosphonophenyl)sulfamoylphenyl, phosphonophenyl, phosphonatophenyl, diethylphosphonophenyl, diphenylphosphonophenyl, methylphosphonophenyl, methylphosphonatophenyl, tolylphosphonophenyl, tolylphosphonatophenyl, allylphenyl, 1-propenylmethylphenyl, 2-butenylphenyl, 2-methylallylphenyl, 2-methylpropenylphenyl, 2-propynylphenyl, 2-butynylphenyl, 3-butynylphenyl, and so forth.

Substituted alkyl and unsubstituted alkyl are examples that are more preferred for R² and R³. Substituted aryl and unsubstituted aryl are examples that are more preferred for R¹. Although the reason for this is unclear, it is hypothesized that the presence of these substituents results in a particularly large interaction between the initiating compound and the excited electronic state produced by the absorption of light, resulting in an improved efficiency for the generation of radicals, acid, or base by the initiating compound.

The A in general formula (12) is will not be described. This A represents a possibly substituted aromatic ring or heterocycle, wherein this possibly substituted aromatic ring or heterocycle can be specifically exemplified by the same specific examples as provided above in the description of R¹, R², and R³ in general formula (12).

Preferred for A thereamong is aryl bearing an alkoxy, thioalkyl, or amino group, and aryl bearing an amino group is a particularly preferred A.

The Y in general formula (12) will now be described. This Y represents a nonmetal atomic group as required, in cooperation with the adjacent carbon atom and the previously described A, to form a heterocycle. This heterocycle can be, for example, a 5-, 6-, or 7-membered nitrogen-containing or sulfur-containing heterocycle, possibly having a condensed ring, wherein 5- and 6-membered heterocycles are preferred.

Nitrogen-containing heterocycles suitable for use can be exemplified by any known nitrogen-containing heterocycle that can constitute the basic nucleus in merocyanine dyes as described in, e.g., L. G. Brooker et al., J. Am. Chem. Soc., Volume 73, pp. 5326-5358 (1951) and the references cited therein.

Specific examples are thiazoles (such as thiazole, 4-methylthiazole, 4-phenylthiazole, 5-methylthiazole, 5-phenylthiazole, 4,5-dimethylthiazole, 4,5-diphenylthiazole, 4,5-di(p-methoxyphenylthiazole), 4-(2-thienyl)thiazole, 4,5-di(2-furyl)thiazole, and so forth), benzothiazoles (such as benzothiazole, 4-chlorobenzothiazole, 5-chlorobenzothiazole, 6-chlorobenzothiazole, 7-chlorobenzothiazole, 4-methylbenzothiazole, 5-methylbenzothiazole, 6-methylbenzothiazole, 5-bromobenzothiazole, 4-phenylbenzothiazole, 5-phenylbenzothiazole, 4-methoxybenzothiazole, 5-methoxybenzothiazole, 6-methoxy-benzothiazole, 5-iodobenzothiazole, 6-iodobenzothiazole, 4-ethoxybenzothiazole, 5-ethoxybenzothiazole, tetrahydrobenzothiazole, 5,6-dimethoxybenzothiazole, 5,6-dioxymethylenebenzothiazole, 5-hydroxybenzothiazole, 6-hydroxybenzothiazole, 6-dimethylaminobenzothiazole, 5-ethoxycarbonylbenzothiazole, and so forth), naphthothiazoles (such as naphtho[1,2]thiazole, naphtho[2,1]thiazole, 5-methoxynaphtho[2,1]thiazole, 5-ethoxynaphtho[2,1]thiazole, 8-methoxynaphtho[1,2]thiazole, 7-methoxynaphtho[1,2]thiazole, and so forth), thianaphtheno-7′,6′,4,5-thiazoles (such as 4′-methoxythianaphtheno-7′,6′,4,5-thiazole and so forth), oxazoles (such as 4-methyloxazole, 5-methyloxazole, 4-phenyloxazole, 4,5-diphenyloxazole, 4-ethyloxazole, 4,5-dimethyloxazole, 5-phenyloxazole, and so forth), benzoxazoles (such as benzoxazole, 5-chlorobenzoxazole, 5-methylbenzoxazole, 5-phenylbenzoxazole, 6-methylbenzoxazole, 5,6-dimethylbenzoxazole, 4,6-dimethylbenzoxazole, 6-methoxybenzoxazole, 5-methoxybenzoxazole, 4-ethoxybenzoxazole, 5-chlorobenzoxazole, 6-methoxybenzoxazole, 5-hydroxybenzoxazole, 6-hydroxybenzoxazole, and so forth), naphthoxazoles (such as naphtho[1,2]oxazole, naphtho[2,1]oxazole, and so forth), selenazoles (such as 4-methylselenazole, 4-phenylselenazole, and so forth), benzoselenazoles (such as benzoselenazole, 5-chlorobenzoselenazole, 5-methoxybenzoselenazole, 5-hydroxybenzoselenazole, tetrahydrobenzoselenazole, and so forth), naphthoselenazoles (such as naphtho[1,2]selenazole, naphtho[2,1]selenazole, and so forth), thiazolines (such as thiazoline, 4-methylthiazoline, 4,5-dimethylthiazoline, 4-phenylthiazoline, 4,5-di(2-furyl)thiazoline, 4,5-diphenylthiazoline, 4,5-di(p-methoxyphenyl)thiazoline, and so forth), 2-quinolines (such as quinoline, 3-methylquinohne, 5-methylquinoline, 7-methylquinoline, 8-methylquinoline, 6-chloroquinoline, 8-chloroquinohne, 6-methoxyquinoline, 6-ethoxyquinoline, 6-hydroxyquinohne, 8-hydroxyquinoline, and so forth), 4-quinohnes (such as quinoline, 6-methoxyquinolne, 7-methylquinoline, 8-methylquinoline, and so forth), 1-isoquinolines (such as isoquinoline, 3,4-dihydroisoquinoline, and so forth), 3-isoquinolines (such as isoquinoline and so forth), benzimidazoles (such as 1,3-dimethylbenzimidazole, 1,3-diethylbenzimidazole, 1-ethyl-3-phenylbenzimidazole, and so forth), 3,3-dialkylindolenines (such as 3,3-dimethylindolenine, 3,3,5-trimethylindolenine, 3,3,7-trimethylindolenine, and so forth), 2-pyridines (such as pyridine, 5-methylpyridine, and so forth), 4-pyridines (such as pyridine and so forth), and so forth. In addition, the substituents on these rings may be bonded to each other to form a ring.

The sulfur-containing heterocycles can be exemplified by the dithiol substructures in the dyes in, for example, Japanese Patent Application Publication No. Hei 3-296759.

Specific examples are benzodithiols (such as benzodithiol, 5-t-butylbenzodithiol, 5-methylbenzodithiol, and so forth), naphthodithiols (such as naphtho[1,2]dithiol, naphtho[2,1]dithiol, and so forth), dithiols (such as 4,5-dimethyldithiols, 4-phenyldithiols, 4-methoxycarbonyldithiols, 4,5-dimethoxycarbonyldithiols, 4,5-diethoxycarbonyldithiols, 4,5-ditrifluoromethyldithiol, 4,5-dicyanodithiol, 4-methoxycarbonylmethyldithiol, 4-carboxymethyldithiol, and so forth), and so forth.

Among the examples for the aforementioned general formula (12) of nitrogen-containing (or sulfur-containing) heterocycles formed by Y in cooperation with the aforementioned A and the adjacent carbon atom, dyes having a structure represented by the substructural motif in the following general formula (13) are particularly preferred because they have a high sensitizing performance and also provide a photosensitive composition that exhibits a very good storage stability.

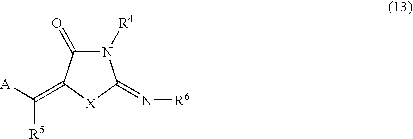

The A in general formula (13) represents a possibly substituted aromatic ring or heterocycle, while X represents an oxygen atom or sulfur atom or —N(R¹)—. R¹, R⁴, R5, and R⁶ each independently represent the hydrogen atom or a monovalent nonmetal atomic group, wherein A may be bonded with any selection from R¹, R⁴, R⁵, and R⁶ with the formation of an aliphatic or aromatic ring in each case.

The A and R¹ in general formula (13) are defined as for A and R¹ in general formula (12); R⁴ in general formula (13) is defined as for R² in general formula (12); R⁵ in general formula (13) is defined as for R³ in general formula (12); and R⁶ in general formula (13) is defined as for R¹ in general formula (12).

The compound represented by general formula (12) is more preferably a compound represented by the following general formula (14).

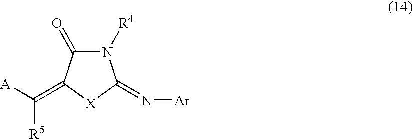

The A in general formula (14) represents a possibly substituted aromatic ring or heterocycle, while X represents the oxygen atom or sulfur atom or —N(R¹)—. R¹, R⁴, and R⁵ are each independently the hydrogen atom or a monovalent nonmetal atomic group, wherein A may be bonded with any selection from R¹, R⁴, and R⁵ with the formation of an aliphatic or aromatic ring in each case. Ar represents a substituted aromatic ring or heterocycle, with the proviso that the sum total of the Hammett values for the substituents on the Ar skeleton must be greater than 0. Here, a sum total for the Hammett values of greater than o denotes the following: when a single substituent is present, the Hammett value of this substituent is greater than 0; when a plurality of substituents are present, the sum total of the Hammett values for these substituents is greater than 0.

The A and R¹ in general formula (14) are defined as for A and R¹ in general formula (12); R⁴ in general formula (14) is defined as for R² in general formula (12); and R⁵ in general formula (14) is defined as for R³ in general formula (12). In addition, Ar represents a substituted aromatic ring or heterocycle and can be specifically exemplified by the specific examples of substituted aromatic rings and heterocycles provided among the specific examples previously cited in the description of A for general formula (12). However, governing the substituents that can be introduced into Ar in general formula (14) is the requirement that the sum total of their Hammett values be greater than 0. Substituents of this nature can be exemplified by the trifluoromethyl group, carbonyl group, ester group, halogen atoms, nitro group, cyano group, sulfoxide group, amide group, and carboxyl group. The Hammett values for these substituents are as follows: trifluoromethyl group (—CF₃, m:0.43, p:0.54), carbonyl group (for example, —COH, m:0.36, p:0.43), ester group (—COOCH₃, m:0.37, p:0.45), halogen (for example, Cl, m:0.37, p:0.23), cyano group (—CN, m:0.56, p:0.66), sulfoxide group (for example, —SOCH₃, m:0.52, p:0.45), amide group (for example, —NHCOCH₃, m:0.21, p:0.00), and carboxyl group (—COOH, m:0.37, p:0.45). With regard to the position of introduction for these substituents on the aryl skeleton and the indication of their Hammett values, (m:0.50) shows that the Hammett value is 0.50 when the particular substituent has been introduced at the meta position. Among the preceding, substituted phenyl is a preferred example of Ar, and the ester group and cyano group are preferred substituents on the Ar skeleton. The position of substitution is particularly preferably at the ortho position on the Ar skeleton.

Preferred specific examples of the sensitizing dyes represented by general formula (12) are provided below (exemplary compound D1 to exemplary compound D57), but the present invention is not limited to these. Among these exemplary compounds, the following correspond to compounds represented by general formula (13): exemplary compounds D2, D6, D10, D18, D21, D28, D31, D33, D35, D38, D41, and D45 to D57.

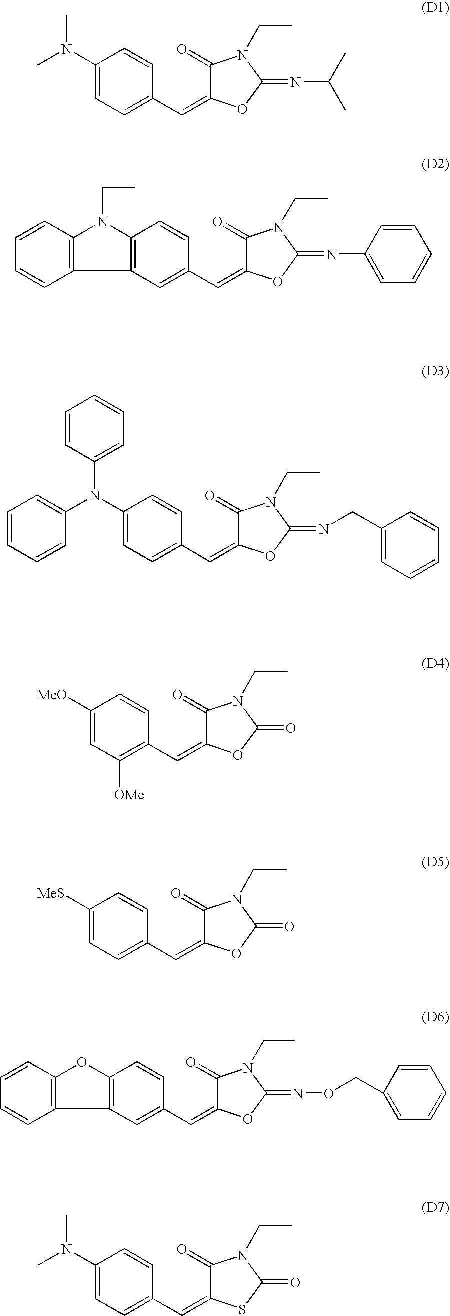

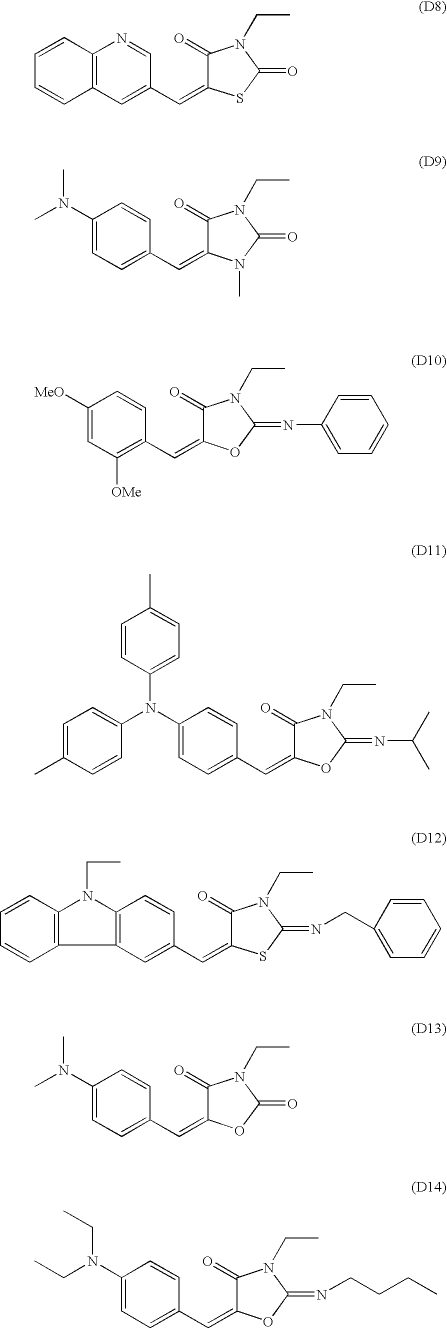

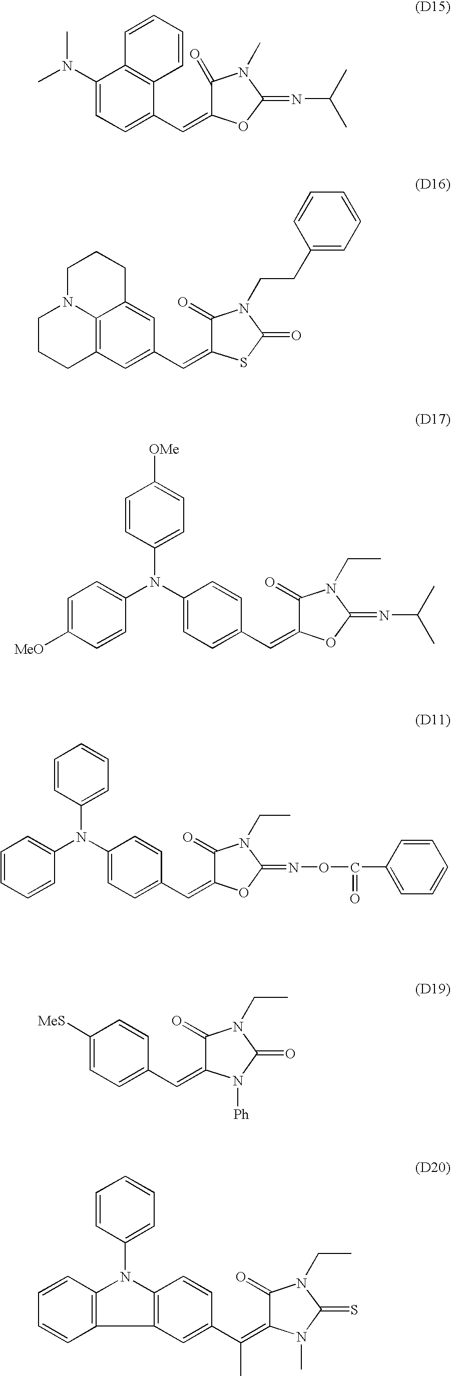

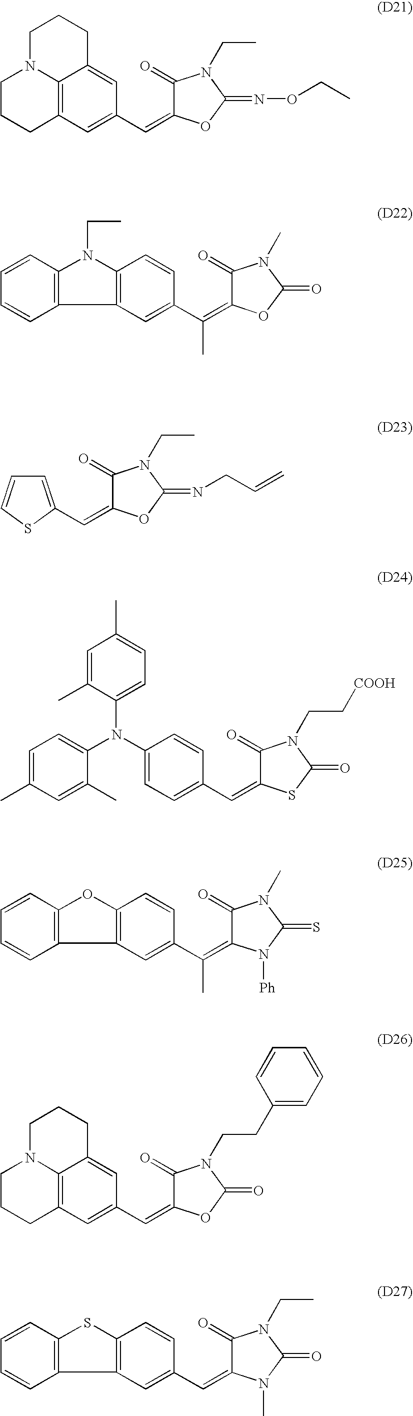

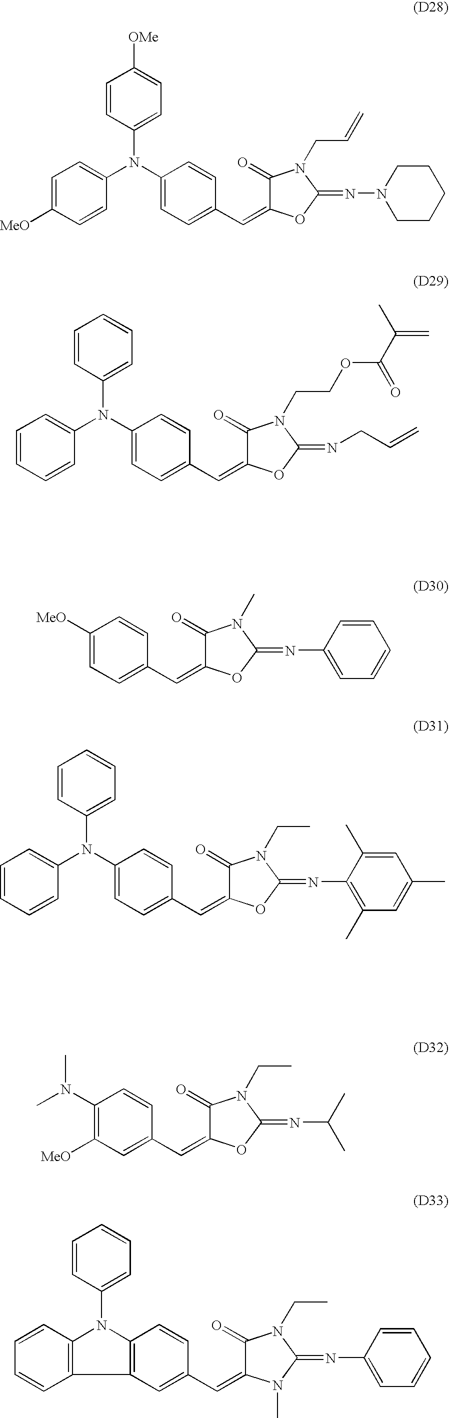

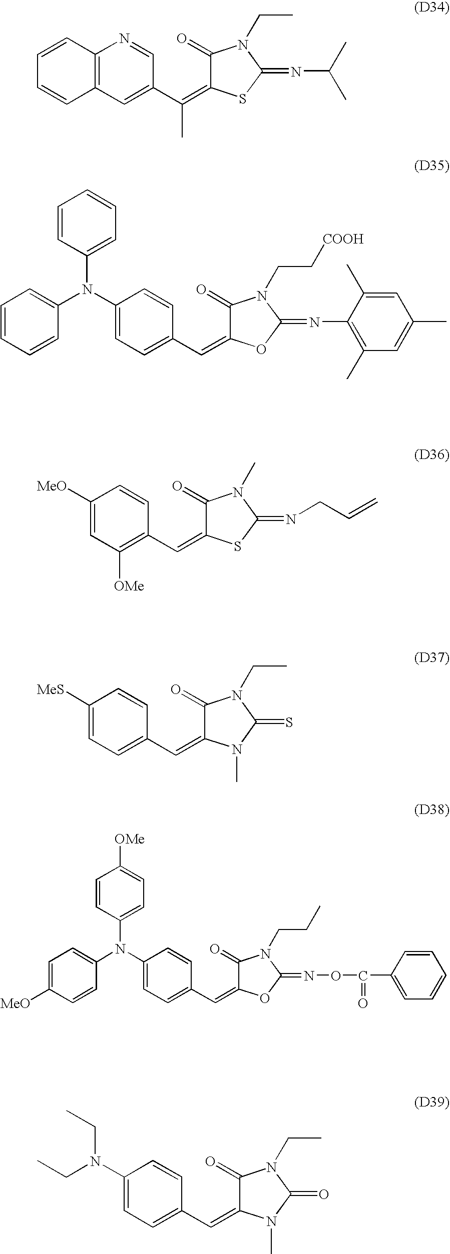

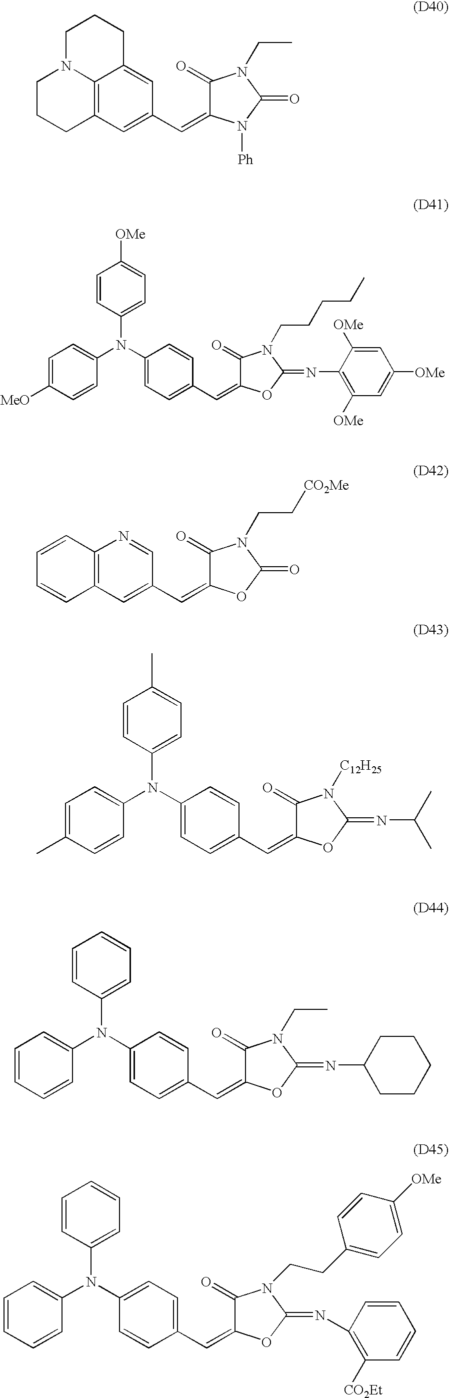

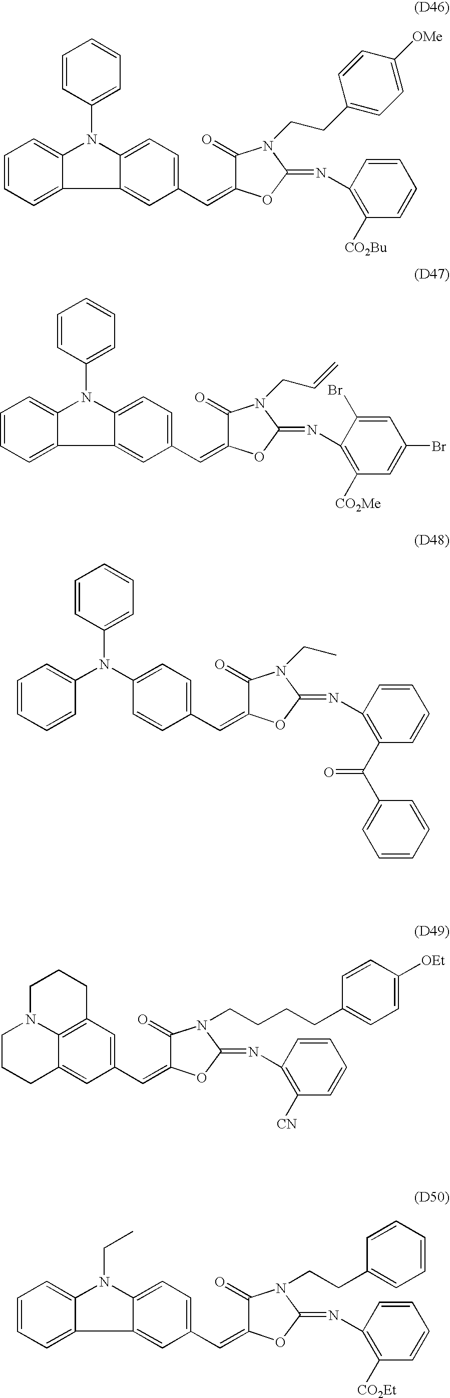

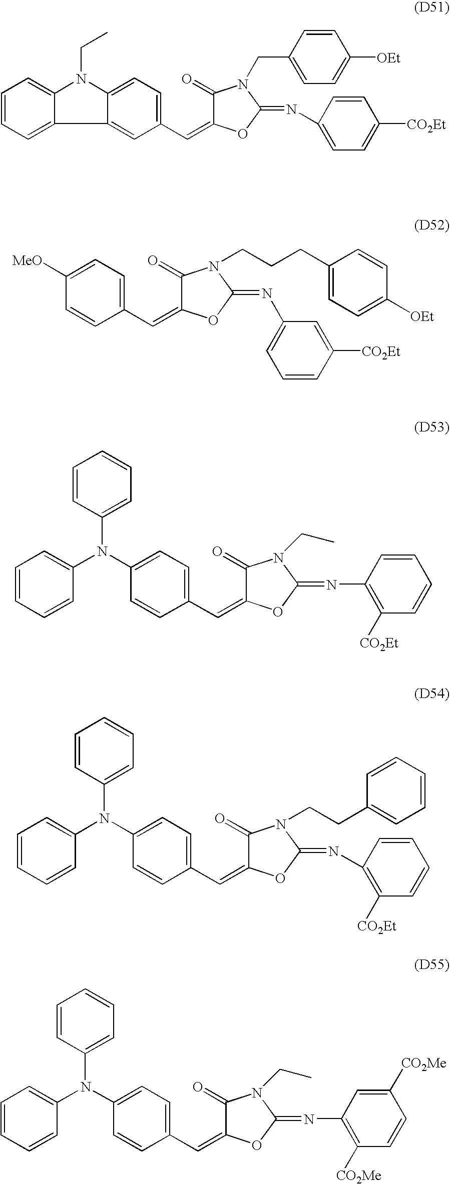

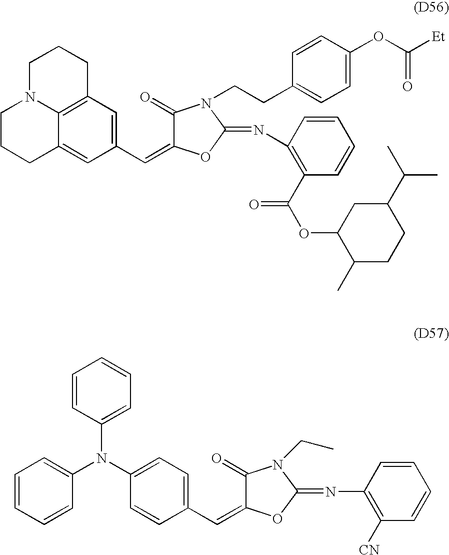

Methods for synthesizing these compounds represented by general formula (12) will now be described.

Compounds with general formula (12) can generally be obtained by a condensation reaction between an acidic nucleus that has an active methylene group and a substituted or unsubstituted aromatic ring or heterocycle and can be synthesized with reference to Japanese Patent Publication No. Sho 59-28329. For example, the following reaction scheme (1) shows a method of synthesis that utilizes a condensation reaction between a compound having an acidic nucleus and a reagent having a basic nucleus wherein aldehyde or carbonyl is present on a heterocycle. The condensation reaction may as necessary be carried out in the presence of a base. The base can be the usual bases in general use; for example, the following can be used without limitation: amines and pyridines (trialkylamines, dimethylaminopyridine, diazabicycloundecene (DBU), and so forth), metal amides (lithium diisopropylamide and so forth), metal alkoxides (sodium methoxide, potassium t-butoxide, and so forth), and metal hydrides (sodium hydride, potassium hydride, and so forth).

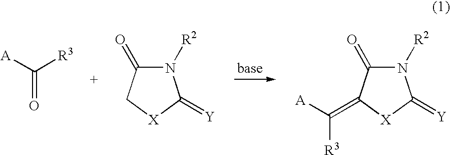

Another preferred method of synthesis is shown by reaction scheme (2) below. Here, reaction scheme (1) is carried out in order to synthesize a dye precursor, but the condensation reaction is run using, as the starting compound having an acidic nucleus in reaction scheme (1), a compound having an acidic nucleus in which Y is the sulfur atom and using the reagent having a basic nucleus wherein aldehyde or carbonyl is present on a heterocycle. This is followed in reaction scheme (2) by a reaction in which this dye precursor is acted upon by a metal salt that has the ability to form a metal sulfide by chemical interaction with the sulfur atom and by reaction with water or primary amine (R—NH₂: this R represents a monovalent nonmetal atomic group).

Between these reactions, the reaction given by reaction scheme (2) offers high yields in the individual reactions and is particularly preferred from the standpoint of synthesis efficiency; moreover, the reaction given by reaction scheme (2) is useful for the synthesis of compounds with general formula (13).

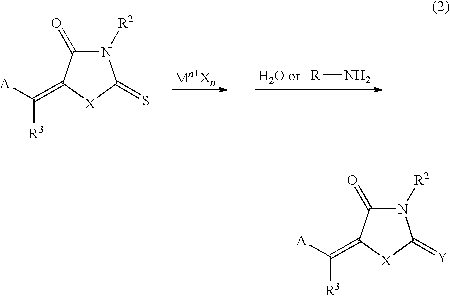

Mⁿ⁺Xₙ in reaction scheme (2) represents a metal salt that has the ability to form a metal sulfide by chemical interaction with the sulfur atom in the thiocarbonyl group. Specific examples of this compound are compounds in which M is Al, Au, Ag, Hg, Cu, Zn, Fe, Cd, Cr, Co, Ce, Bi, Mn, Mo, Ga, Ni, Pd, Pt, Ru, Rh, Sc, Sb, Sr, Mg, Ti, and so forth and in which X is F, Cl, Br, I, NO₃, SO₄, NO₂, PO₄, CH₃CO₂, and so forth, such as AgBr, AgI, AgF, AgO, AgCl, Ag₂O, Ag(NO₃), AgSO₄, AgNO₂, Ag₂CrO₄, Ag₃PO₄, Hg₂(NO₃)₂, HgBr₂, Hg₂Br₂, HgO, HgI₂, Hg(NO₃)₂, Hg(NO₂)₂, HgBr₂, HgSO₄, Hg₂I₂, Hg₂SO₄, Hg(CH₃CO₂)₂, AuBr, AuBr₃, AuI, AuI₃, AuF₃, Au₂O₃, AuCl, AuCl₃, CuCl, CuI, CuI₂, CuF₂, CuO, CuO₂, Cu(NO₃)₂, CuSO₄, and Cu₃(PO₄)₂. Among these, the use of a silver salt as the metal salt is most preferred from the standpoint of the ease of interaction with the sulfur atom.

The sensitizing dye with general formula (12) that is used by the present invention may also be subjected to different types of chemical modification in order to improve the characteristics of the photopolymerizable layer. For example, the sensitizing dye can be bonded, for example, by a covalent bond, ionic bond, hydrogen bond, and so forth, with an addition-polymerizable compound structure (for example, acryloyl group, methacryloyl group) in order to raise the strength of the lithographic film and prevent unwanted precipitation of the dye from the film after photoexposure.

In addition, the photosensitivity can in particular be substantially increased at a low concentration for the initiation system by bonding the sensitizing dye with a radical-generating substructure (for example, reductive decomposition sites such as halogenated alkyl, onium, peroxide, biimidazole, and so forth; oxidative decomposition sites such as borate, amine, trimethylsilylmethyl, carboxymethyl, carbonyl, imine, and so forth) in the initiator compound.

In addition, the introduction of a hydrophilic site (polar or acid groups such as the carboxyl group and its esters, the sulfonic acid group and its esters, the ethylene oxide group, and so forth) into the sensitizing dye is effective for raising the suitability for processing in an alkaline or water-based developing fluid. In particular, ester-type hydrophilic groups are characterized by an excellent compatibility in the photopolymerizable layer because they have a relatively hydrophobic structure, while in the developing fluid they produce an acid group by decomposition and thereby raise the hydrophilicity.

As another example, a suitable substituent can be introduced in order to improve the compatibility in the photopolymerizable layer and inhibit the precipitation of crystals. For example, in some photosensitive systems an aryl group or an unsaturated bond (e.g., allyl group) may be very effective for improving the compatibility. Otherwise, the precipitation of crystals can be substantially inhibited by the introduction of steric hindrance between π planes in the dye by, for example, the introduction of a branched alkyl structure. The adhesiveness to inorganics (e.g., metals, metal oxides, and so forth) can be improved by the introduction of the phosphonic acid group, epoxy group, trialkoxysilyl group, and so forth. Other useful methods that may be implemented as necessary include elaboration of the sensitizing dye as a polymer.

The use of at least one sensitizing dye with general formula (12) as the sensitizing dye used by the present invention is preferred. As long as general formula (12) is adopted, the details of the method of implementation—for example, any modification as previously cited, the particular dye structure used, whether a single dye is used or two more dyes are used in combination, the particular quantity of addition—can be established as appropriate in conformity with the properties designed for the final sensitive material For example, the use of two or more sensitizing dyes in combination can increase the compatibility in the photopolymerizable layer.

In addition to the photosensitivity, the molar extinction coefficient at the wavelengths generated by the light source used is an important factor. The use of a dye having a large molar extinction coefficient makes it possible to employ a relatively small quantity of dye addition, and is thus economical and also offers advantages from the perspective of the film properties of the photopolymerizable layer.

The present invention is not limited to only sensitizing dyes with general formula (12) and can also use other, general-purpose sensitizing dyes insofar as the effects of the present invention are not impaired.

The photosensitivity and resolution of the photopolymerizable layer and the properties of the lithographic film are significantly affected by the absorbance at the wavelengths generated by the light source, and an appropriate selection of the quantity of sensitizing dye addition is made considering these parameters. For example, the sensitivity is reduced in the low absorbance region of less than or equal 0.1. The influence of halation also results in a lower resolution. However, with regard, for example, to the goal of bringing about the cure of a film with a thickness of 5 μm or greater, such a low absorbance may on the contrary increase the degree of cure. In the region of a high absorbance of 3 or more, most of the light is absorbed at the surface of the photosensitive layer and curing is then inhibited in the more interior regions, and, for the example of use as a printing plate, the film strength and adhesiveness to substrate become unsatisfactory.

Taking as an example the use in the photopolymerizable layer of a lithographic printing plate precursor that employs a relatively thin film thickness, the quantity of sensitizing dye addition is preferably established in such a manner that the absorbance of the photopolymerizable layer is in the range from 0.1 to 1.5 and preferably in the range from 0.25 to 1. Since the absorbance is determined by the quantity of sensitizing dye addition and the thickness of the photopolymerizable layer, a prescribed absorbance is obtained by manipulating these two conditions. Measurement can be carried out, for example, by forming the photopolymerizable layer—in a thickness determined as appropriate in the range required of the post-drying coating rate for lithographic printing plates—on a transparent or white support and carrying out measurement with a transmission-type optical densitometer. In another example of the measurement method, the recording layer is formed on a reflective support, e.g., aluminum, and the reflection density is measured.

The quantity of sensitizing dye addition to the photopolymerizable layer of the lithographic printing plate precursor is generally 0.05 to 30 mass parts, preferably 0.1 to 20 mass parts, and more preferably 0.2 to 10 mass parts, in each case per 100 mass parts of the total solids fraction comprising the photopolymerizable layer.

### [The Infrared Absorber]

In instances where image formation is carried out using a laser light source that emits infrared radiation at, for example, 760 to 1200 nm, the photopolymerizable layer of the lithographic printing plate precursor of the present invention preferably contains an infrared absorber. The infrared absorber functions to convert the absorbed infrared radiation to heat. The heat thereby produced causes thermal degradation of the polymerization initiator (radical generator), vide infra, with the production of a radical. The infrared absorber used in the present invention can be a dye or pigment that presents an absorption maximum at a wavelength of 760 to 1200 nm.

The dye can be exemplified by commercially available dyes and by known dyes described in the literature (for example, Dye Handbook, edited by The Society of Synthetic Organic Chemistry, Japan, 1970). Specific examples are dyes such as azo dyes, metal complex salt azo dyes, pyrazolone azo dyes, naphthoquinone dyes, anthraquinone dyes, pbthalocyanine dyes, carbonium dyes, quinoneimine dyes, methine dyes, cyanine dyes, squarylium dyes, pyrylium salts, metal thiolate complexes, and so forth.

Preferred dyes can be exemplified by the cyanine dyes described in Japanese Patent Application Publication Nos. Sho 58-125246, Sho 59-84356, and Sho 60-78787; the methine dyes described in Japanese Patent Application Publication Nos. Sho 58-173696, Sho 58-181690, and Sho 58-194595; the naphthoquinone dyes described in Japanese Patent Application Publication Nos. Sho 58-112793, Sho 58-224793, Sho 59-48187, Sho 59-73996, Sho 60-52940, and Sho 60-63744; the squarylium dyes described in Japanese Patent Application Publication No. Sho 58-112792; and the cyanine dyes described in British Patent 434,875.

The use is also preferred of the near infrared absorbers/sensitizers described in U.S. Pat. No. 5,156,938; the substituted arylbenzo(thio)pyrylium salts described in U.S. Pat. No. 3,881,924; the trimethine thiapyrylium salts described in Japanese Patent Application Publication No. Sho 57-142645 (U.S. Pat. No. 4,327,169); the pyrylium compounds described in Japanese Patent Application Publication Nos. Sho 58-181051, Sho 58-220143, Sho 59-41363, Sho 59-84248, Sho 59-84249, Sho 59-146063, and Sho 59-146061; the cyanine dyes described in Japanese Patent Application Publication No. Sho 59-216146; the pentamethine thiopyrylium salts described in U.S. Pat. No. 4,283,475; and the pyrylium compounds described in Japanese Patent Publication Nos. Hei 5-13514 and Hei 5-19702. Other preferred dye examples are the near infrared-absorbing dyes represented by formulas (I) and (II) in U.S. Pat. 4,756,993.

Other preferred examples of the infrared-absorbing dyes for the present invention are the special indolenine cyanine dyes described in Japanese Patent Application Publication No. 2002-278057, as exemplified below.

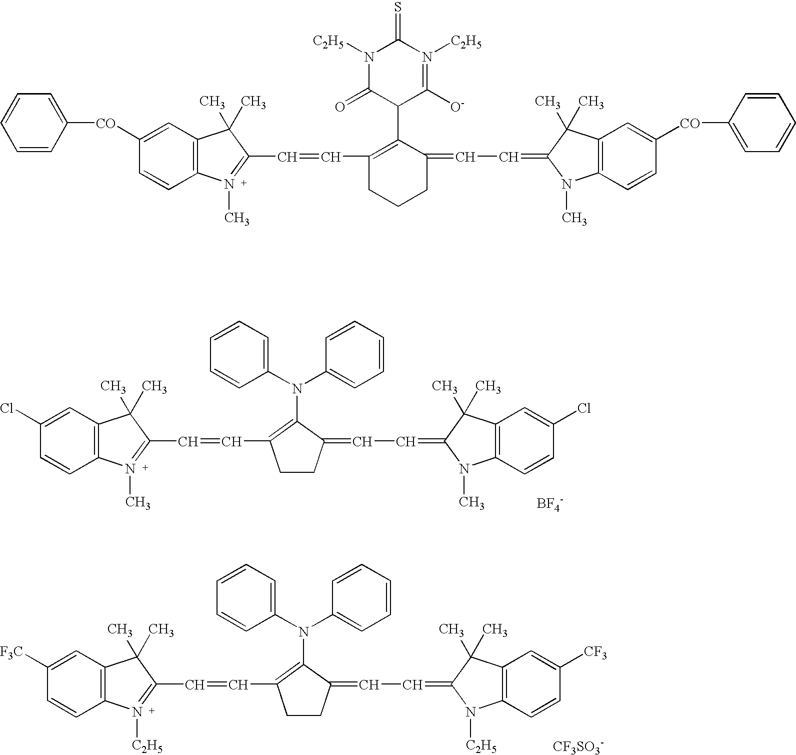

The following are particularly preferred among the dyes cited above: cyanine dyes, squarylium dyes, pyrylium dyes, nickel thiolate complexes, and indolenine cyanine dyes. The cyanine dyes and indolenine cyanine dyes are more preferred, while the cyanine dyes given by the following general formula (i) are a particularly preferred example.

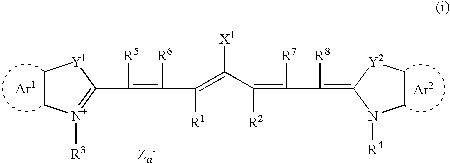

X¹ in general formula (i) represents the hydrogen atom, a halogen atom, —NPh₂, X²—L¹, or the group depicted below.

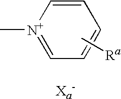

X² represents an oxygen atom, nitrogen atom, or sulfur atom; L¹ represents C₁₋₁₂ hydrocarbyl, a heteroatom-containing aromatic ring, or heteroatom-containing C₁₋₁₂ hydrocarbyl. This heteroatom represents N, S, O, a halogen atom, or Se.

Xₐ— has the same definition as the Zₐ- described below, while R^{a} represents a substituent selected from the hydrogen atom, alkyl, aryl, substituted and unsubstituted amino, and halogen atoms.

R¹ and R² in general formula (i) each independently represent C₁₋₁₂ hydrocarbyl. Based on a consideration of the storage stability of the coating fluid for forming the recording layer, R¹ and R² are preferably hydrocarbyl that contains at least two carbon atoms and are particularly preferably bonded to each other to form a 5-membered ring or 6-membered ring.

Ar¹ and Ar² each independently represent possibly substituted aromatic hydrocarbyl. The benzene ring and naphthalene ring are preferred for the aromatic hydrocarbyl. Preferred substituents in the case of substitution are hydrocarbyl containing no more than 12 carbons, halogen atoms, and alkoxy groups containing no more than 12 carbons. Y¹ and Y² each independently represent the sulfur atom or a dialkylmethylene group that has no more than 12 carbons. R³ and R⁴ each independently represent possibly substituted hydrocarbyl having no more than 20 carbons. Preferred substituents in the case of substitution are alkoxy groups having no more than 12 carbons, the carboxyl group, and the sulfo group. R⁵, R⁶, R⁷, and R⁸ each independently represent the hydrogen atom or hydrocarbyl having no more than 12 carbons. The hydrogen atom is preferred based on the ease of starting material acquisition. Zₐ- represents a counteranion. However, Zₐ- is not required when the cyanine dye with general formula (i) has an anionic substituent within its structure and charge neutralization is then not required. Based on a consideration of the storage stability of the coating fluid for forming the recording layer, Zₐ- is preferably a halogen ion, the perchlorate ion, the tetrafluoroborate ion, the hexafluorophosphate ion, or a sulfonate ion and particularly preferably is the perchlorate ion, the hexafluorophosphate ion, or an arylsulfonate ion.

Specific examples of cyanine dyes with general formula (i) that can be suitably used in the present invention are, for example, the dyes described in paragraphs from 0017 to 0019 of Japanese Patent Application Publication No. 2001-133969.

Additional, particularly preferred examples are the special indolenine cyanine dyes described in the previously mentioned Japanese Patent Application Publication No. 2002-278057.

The pigment used in the present invention may be a commercially available pigment or a pigment as described in the Colour Index (C. I.) database, The Handbook of Modern Pigments (Edited by the Japan Association of Pigment Technology, 1977), Modern Pigment Applications Technology (CMC, 1986), or Printing Ink Technology (CMC, 1984).

With regard to type, the pigment can be, for example, a black pigment, yellow pigment, orange pigment, brown pigment, red pigment, purple pigment, blue pigment, green pigment, fluorescent pigment, metal powder pigment, or polymer-bonded dye. Specific examples are insoluble azo pigments, azo lake pigments, condensed azo pigments, chelate azo pigments, phthalocyanine-based pigments, anthraquinone-based pigments, perylene-based pigments, perinone-based pigments, thioindigo-based pigments, quinacridone-based pigments, dioxazine-based pigments, isoindolinone-based pigments, quinophthalone-based pigments, dyed lake pigments, azine pigments, nitroso pigments, nitro pigments, natural pigments, fluorescent pigments, inorganic pigments, carbon black, and so forth. Carbon black is preferred among these pigments.

These pigments may be used without a surface treatment or may be used after a surface treatment. Examples of the surface treatment method include coating the surface with a resin or wax, attaching a surfactant, and bonding a reactive material (e.g., silane coupling agent, epoxy compound, polyisocyanate) to the surface of the pigment. These surface treatment methods are described in Properties and Applications of Metal Soaps (Saiwai Shobo), Printing Ink Technology (CMC, 1984), and Modern Pigment Applications Technology (CMC, 1986).

The particle diameter of the pigment is preferably from 0.01 μm to 10 μm, more preferably from 0.05 μm to 1 μm, and particularly preferably from 0.1 μm to 1 μm. Good stability by the pigment dispersion in the coating fluid for forming the photopolymerizable layer and good uniformity on the part of the photopolymerizable layer are obtained in the cited range.

The known dispersion technologies used, for example, for ink production or toner production, can be used as the method of dispersing the pigment. The dispersing apparatus can be exemplified by ultrasonic dispersers, sand mills, attritors, pearl mills, super mills, ball mills, impellers, dispersers, KD mills, colloid mills, dynatrons, three-roll mills, and pressure kneaders. The details are described in Modern Pigment Applications Technology (CMC, 1986).

The infrared absorber may be incorporated in the same layer as other components or may be incorporated in a separately disposed layer. The infrared absorber is incorporated during production of the negative-working lithographic printing plate precursor in such a manner that the absorbance of the photopolymerizable layer at the wavelength of maximum absorption in the wavelength range of 760 to 1200 nm is in the range from 0.3 to 1.2 as measured by a reflection method. The range from 0.4 to 1.1 is preferred. An excellent film strength by the image areas and an excellent adhesion to the support are obtained in the cited range, as is the development of a uniform polymerization reaction across the thickness of the photopolymerizable layer.

The absorbance of the photopolymerizable layer can be adjusted through the quantity of infrared absorber addition to the photopolymerizable layer and through the thickness of the photopolymerizable layer. The absorbance can be measured by the usual methods. Measurement can be carried out, for example, by the following methods: the photopolymerizable layer is formed on a reflective support, e.g., aluminum, in a thickness determined as appropriate in the range required of the post-drying coating rate for lithographic printing plates, and the reflection density is then measured with an optical densitometer or measurement is carried out using a spectrophotometer by reflection using an integrating sphere.

### [The Polymerization Initiator]

A polymerization initiator can be used in the photopolymerizable layer of the present invention. The polymerization initiator used here is a compound that generates radicals under the action of thermal energy or light energy or both and that thereby initiates and promotes the polymerization of compounds that contain a polymerizable unsaturated bond. The polymerization initiator can be selected as appropriate, in view of the wavelength of the light source used, from the various polymerization initiators known from, for example, patents and the literature, or a combined system of two or more polymerization initiators (polymerization initiation system) can be selected as appropriate.

The radical-generating compounds can be exemplified by organic halides, carbonyl compounds, organoperoxides, azo-type polymerization initiators, azide compounds, metallocene compounds, hexaarylbiimidazole compounds, organoboric acid compounds, disulfone compounds, oxime ester compounds, and onium salt compounds.

The organic halides can be specifically exemplified by the compounds described in Wakabayashi et al., Bull. Chem. Soc. Japan, 42, 2924 (1969); U.S. Pat. No. 3,905,815; Japanese Patent Publication No. Sho 46-4605; Japanese Patent Application Publication Nos. Sho 48-36281, Sho 55-32070, Sho 60-239736, Sho 61-169835, Sho 61-169837, Sho 62-58241, Sho 62-212401, Sho 63-70243, and Sho 63-298339; and M. P. Hutt, Journal of Heterocyclic Chemistry, 1, No. 3 (1970). Trihalomethyl-substituted oxazole compounds and s-triazine compounds are particularly preferred.

s-triazine derivatives having at least one mono-, di-, or tri-halogen-substituted methyl group bonded to the s-triazine ring are more preferred, and specific examples are 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl-4,6-bis(trichloromethyl)-s-triazine, 2-(p-isopropyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, and so forth.

The aforementioned carbonyl compounds can be exemplified by benzophenone derivatives, e.g., benzophenone, Michler's ketone, 2-methylbenzophenone, 3-methylbenzophenone, 4-methylbenzophenone, 2-chlorobenzophenone, 4-bromobenzophenone, 2-carboxybenzophenone, and so forth; acetophenone derivatives, e.g., 2,2-dimethoxy-2-phenylacetophenone, 2,2-diethoxyacetophenone, 1-hydroxycyclohexyl phenyl ketone, a-hydroxy-2-methylphenylpropanone, 1-hydroxy-1-methylethyl (p-isopropylphenyl) ketone, 1-hydroxy-1-(p-dodecylphenyl) ketone, 2-methyl-(4′-(methylthio)phenyl)-2-morpholino-1-propanone, 1,1,1-trichloromethyl (p-butylphenyl) ketone, and so forth; thioxanthone derivatives, e.g., thioxanthone, 2-ethylthioxanthone, 2-isopropylthioxanthone, 2-chlorothioxanthone, 2,4-dimethylthioxanthone, 2,4-diethylthioxanthone, 2,4-diisopropylthioxanthone, and so forth; and benzoic acid ester derivatives, e.g., ethyl p-dimethylaminobenzoate, ethyl p-diethylaminobenzoate, and so forth.

The aforementioned azo compounds can be exemplified, inter alia, by the azo compounds described in Japanese Patent Application Publication No. Hei 8-108621.

The aforementioned organoperoxides can be exemplified by trimethylcyclohexanone peroxide, acetylacetone peroxide, 1,1-bis(tert-butylperoxy)-3,3,5-trimethylcyclohexane, 1,1-bis(tert-butylperoxy)cyclohexane, 2,2-bis(tert-butylperoxy)butane, tert-butyl hydroperoxide, cumene hydroperoxide, diisopropylbenzene hydroperoxide, 2,5-dimethylhexane-2,5-dihydroperoxide, 1,1,3,3-tetramethylbutyl hydroperoxide, tert-butylcumyl peroxide, dicumyl peroxide, 2,5-dimethyl-2,5-di(tert-butylperoxy)hexane, 2,5-oxanoyl peroxide, succinic peroxide, benzoyl peroxide, 2,4-dichlorobenzoyl peroxide, diisopropylperoxy dicarbonate, di-2-ethylhexylperoxy dicarbonate, di-2-ethoxyethylperoxy dicarbonate, dimethoxyisopropylperoxy dicarbonate, di(3-methyl-3-methoxybutyl)peroxy dicarbonate, tert-butylperoxy acetate, tert-butylperoxy pivalate, tert-butylperoxy neodecanoate, tert-butylperoxy octanoate, tert-butylperoxy laurate, 3,3′,4,4′-tetra(tert-butylperoxycarbonyl)benzophenone, 3,3′,4,4′-tetra(tert-hexylperoxycarbonyl)benzophenone, 3,3′,4,4′-tetra(p-isopropylcumylperoxycarbonyl)benzophenone, carbonyl di(tert-butylperoxydihydrogen diphthalate), carbonyl di(tert-hexylperoxydihydrogen diphthalate), and so forth.

The aforementioned metallocene compounds can be exemplified by the titanocene compounds described in Japanese Patent Application Publication Nos.

Sho 59-152396, Sho 61-151197, Sho 63-41484, Hei 2-249, Hei 2-4705, and Hei 5-83588, for example, dicyclopentadienyl-Ti-bisphenyl, dicyclopentadienyl-Ti-bis-2,6 -difluorophen -1-yl, dicyclopentadienyl-Ti-bis-2,4-difluorophen-1-yl, dicyclopentadienyl-Ti-bis-2,4,6-trifluorophen-1-yl, dicyclopentadienyl-Ti-bis-2,3,5,6-tetrafluorophen-1-yl, dicyclopentadienyl-Ti-bis-2,3,4,5,6-pentafluorophen-1-yl, dimethylcyclopentadienyl-Ti-bis-2,6-cdifluorophen-1-yl, dimethylcyclopentadienyl-Ti-bis-2,4,6-triafluorophen-1-yl, dimethylcyclopentadienyl-Ti-bis-2,3,5,6-tetrafluorophen-1-yl, and dimethylcyclopentadienyl-Ti-bis-2,3,4,5,6-pentafluorophen-1-yl; additional examples are the iron-arene complexes described in Japanese Patent Application Publication Nos. Hei 1-304453 and Hei 1-152109.

The aforementioned hexaarylbiimidazole compounds can be exemplified by the compounds described in Japanese Patent Publication No. Hei 6-29285 and U.S. Pat. Nos. 3,479,185, 4,311,783, and 4,622,286, and specifically 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluorophenyl)-4,4′,5,5′-tetraphenylbiimidazole, and so forth.

The aforementioned organoborate salt compounds can be specifically exemplified by the organoborate salts described in Japanese Patent Application Publication Nos. Sho 62-143044, Sho 62-150242, Hei 9-188685, Hei 9-188686, Hei 9-188710, 2000-131837, and 2002-107916, Japanese Patent No. 2,764,769, Japanese Patent Application Publication No. 2002-116539, and Martin Kunz, RadTech '98 Proceedings, Apr. 19-22, 1998, Chicago; the organoboron sulfonium complexes and organoboron oxosulfonium complexes described in Japanese Patent Application Publication Nos. Hei 6-157623, Hei 6-175564, and Hei 6-175561; the organoboron iodonium complexes described in Japanese Patent Application Publication Nos. Hei 6-175554 and Hei 6-175553; the organoboron phosphonium complexes described in Japanese Patent Application Publication No. Hei 9-188710; and the organoboron transition metal coordination complexes described in Japanese Patent Application Publication Nos. Hei 6-348011, Hei 7-128785, Hei 7-140589, Hei 7-306527, and Hei 7-292014.

The aforementioned disulfone compounds can be exemplified by the compounds described in Japanese Patent Application Publication Nos. Sho 61-166544 and 2003-328465.

The aforementioned oxime ester compounds can be exemplified by the compounds described in J. C. S. Perkin II, 1653-1660 (1979), J. C. S. Perkin II, 156-162 (1979), Journal of Photopolymer Science and Technology, 202-232 (1995), and Japanese Patent Application Publication No. 2000-66385; by the compounds described in Japanese Patent Application Publication No. 2000-80068; and specifically by the compounds given by the structural formulas provided below.

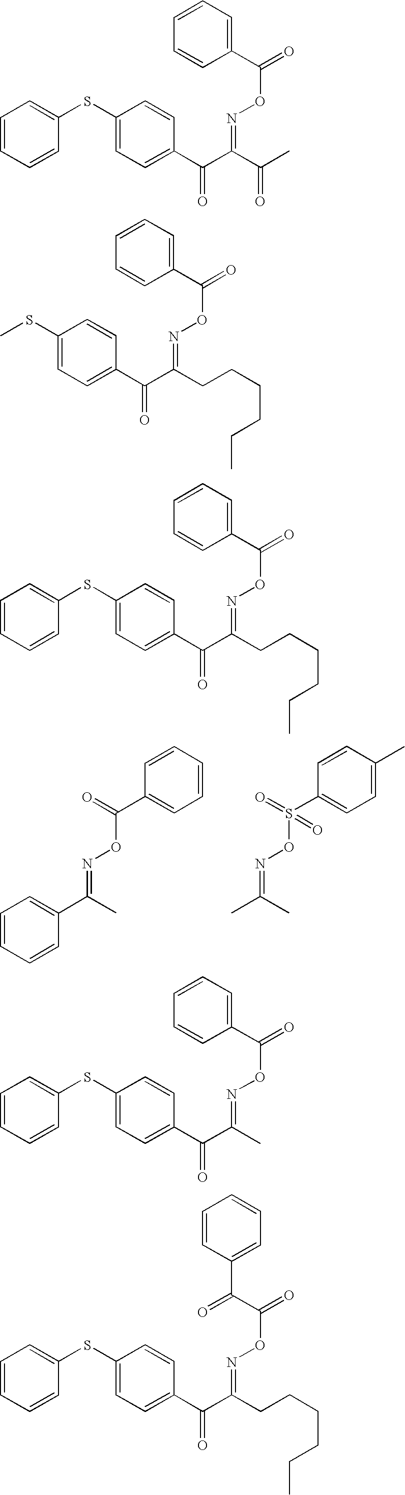

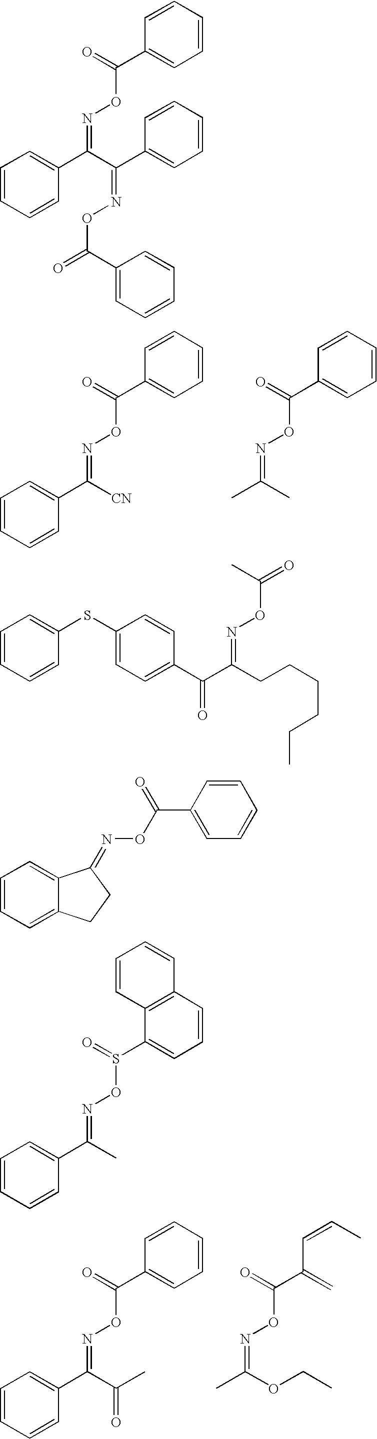

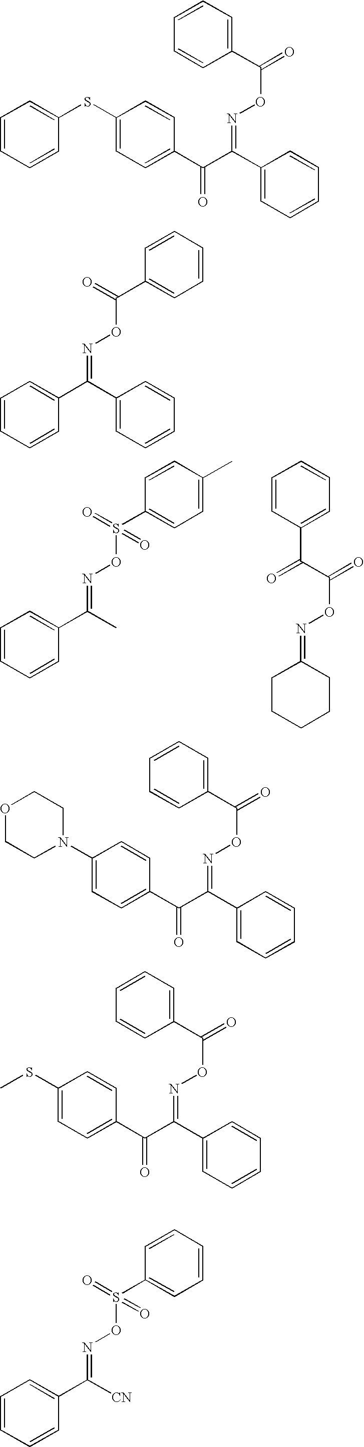

The aforementioned onium salt compounds can be exemplified by onium salts such as the diazonium salts described in S. I. Schlesinger, Photogr. Sci. Eng., 18, 387 (1974) and T. S. Bal et al., Polymer, 21, 423 (1980); the ammonium salts described in U.S. Pat. No. 4,069,055 and Japanese Patent Application Publication No. Hei 4-365049; the phosphonium salts described in U.S. Pat. Nos. 4,069,055 and 4,069,056; the iodonium salts described in European Patent No. 104,143, and Japanese Patent Application Publication Nos. Hei 2-150848 and 2-296514; the sulfonium salts described in European Patent Nos. 370,693, 390,214, 233,567, 297,443, and 297,442, U.S. Pat. Nos. 4,933,377, 4,760,013, 4,734,444, and 2,833,827, and German Patent Nos. 2,904,626, 3,604,580 and 3,604,581;

the selenonium salts described in J. V. Crivello et al., Macromolecules, 10(6), 1307 (1977) and J. V. Crivello et al., J. Polymer Sci., Polymer Chem. Ed, 17, 1047 (1979); and the arsonium salts described in C. S. Wen et al., The Proc. Conf Rad. Curing. ASIA, p. 478, Tokyo, October (1988).

Viewed from the standpoints of reactivity and stability, the aforementioned oxime ester compounds and diazonium salts, iodonium salts, sulfonium salts, and ammonium salts are particularly preferred examples. These onium salts function in the present invention not as an acid generator, but rather as an ionic radical polymerization initiator.

The onium salts represented by the following general formulas (RI-I) to (RI-IV) are onium salts that are well suited for use in the present invention.

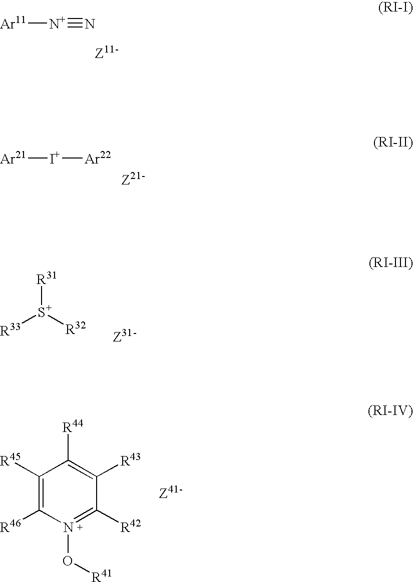

Ar¹¹ in formula (RI-I) represents an aryl group that has 20 or fewer carbons and that may have from 1 to 6 substituents. Preferred substituents can be exemplified by alkyl having from 1 to 12 carbons, alkenyl having from 1 to 12 carbons, alkynyl having from 1 to 12 carbons, aryl having from 1 to 12 carbons, alkoxy having from 1 to 12 carbons, aryloxy having from 1 to 12 carbons, halogen, alkylamino having from 1 to 12 carbons, dialkylamino having from 1 to 12 carbons, alkylamide or arylamide having from 1 to 12 carbons, a carbonyl group, the carboxyl group, the cyano group, a sulfonyl group, thioalkyl having from 1 to 12 carbons, and thioaryl having from 1 to 12 carbons. Z¹¹⁻ represents a monovalent anion and is a halogen ion, perchlorate ion, hexafluorophosphate ion, tetrafluoroborate ion, sulfonate ion, sulfinate ion, thiosulfonate ion, or sulfate ion. Viewed from the perspective of stability and the inspectability of the printed out image, the perchlorate ion, hexafluorophosphate ion, tetrafluoroborate ion, sulfonate ion, and sulfinate ion are preferred.

Ar²¹ and Ar²² in formula (RI-II) each independently represent an aryl group that has 20 or fewer carbons and that may have from 1 to 6 substituents. Preferred substituents can be exemplified by alkyl having from 1 to 12 carbons, alkenyl having from 1 to 12 carbons, alkynyl having from 1 to 12 carbons, aryl having from 1 to 12 carbons, alkoxy having from 1 to 12 carbons, aryloxy having from 1 to 12 carbons, halogen, alkylamino having from 1 to 12 carbons, dialkylamino having from 1 to 12 carbons, alkylamide or arylamide having from 1 to 12 carbons, a carbonyl group, the carboxyl group, the cyano group, a sulfonyl group, thioalkyl having from 1 to 12 carbons, and thioaryl having from 1 to 12 carbons. Z²¹⁻ represents a monovalent anion and is a halogen ion, perchlorate ion, hexafluorophosphate ion, tetrafluoroborate ion, sulfonate ion, sulfinate ion, thiosulfonate ion, or sulfate ion. Viewed from the perspective of stability, the perchlorate ion, hexafluorophosphate ion, tetrafluoroborate ion, sulfonate ion, sulfinate ion, and carboxylate ion are preferred.

R³¹, R³², and R³³ in formula (RI-III) each independently represent alkyl, alkenyl, or alkynyl or an aryl group that has 20 or fewer carbons and that may have from 1 to 6 substituents, wherein aryl is preferred from the standpoints of reactivity and stability. Preferred substituents can be exemplified by alkyl having from 1 to 12 carbons, alkenyl having from 1 to 12 carbons, alkynyl having from 1 to 12 carbons, aryl having from 1 to 12 carbons, alkoxy having from 1 to 12 carbons, aryloxy having from 1 to 12 carbons, halogen, alkylamino having from 1 to 12 carbons, dialkylamino having from 1 to 12 carbons, alkylamide or arylamide having from 1 to 12 carbons, a carbonyl group, the carboxyl group, the cyano group, a sulfonyl group, thioalkyl having from 1 to 12 carbons, and thioaryl having from 1 to 12 carbons. Z³¹⁻ represents a monovalent anion and is a halogen ion, perchlorate ion, hexafluorophosphate ion, tetrafluoroborate ion, sulfonate ion, sulfinate ion, thiosulfonate ion, or sulfate ion. Viewed from the perspective of stability and the printed-out image inspectability, the perchlorate ion, hexafluorophosphate ion, tetrafluoroborate ion, sulfonate ion, sulfinate ion, and carboxylate ion are preferred, while the carboxylate ion described in Japanese Patent Application Publication No. 2001-343742 is more preferred and the carboxylate ion described in Japanese Patent Application Publication No. 2002-148790 is particularly preferred.

R⁴¹ in formula (RI-IV) represents possibly substituted C₁₋₂₀ alkyl. R⁴², R⁴³, R⁴⁴, R⁴⁵, and R⁴⁶ each independently represent alkyl, alkenyl, or alkynyl or an aryl group that has 20 or fewer carbons and that may have from 1 to 6 substituents, wherein aryl is preferred from the standpoints of reactivity and stability. Preferred substituents can be exemplified by alkyl having from 1 to 12 carbons, alkenyl having from 1 to 12 carbons, alkynyl having from 1 to 12 carbons, aryl having from 1 to 12 carbons, alkoxy having from 1 to 12 carbons, aryloxy having from 1 to 12 carbons, halogen, alkylamino having from 1 to 12 carbons, dialkylamino having from 1 to 12 carbons, alkylamide or arylamide having from 1 to 12 carbons, a carbonyl group, the carboxyl group, the cyano group, a sulfonyl group, thioalkyl having from 1 to 12 carbons, and thioaryl having from 1 to 12 carbons. R⁴¹ may be connected to R⁴³ to form a ring; R⁴² may be connected to R⁴³ to form a ring; R⁴³ may be connected to R⁴⁴ to form a ring; R⁴⁴ may be connected to R⁴⁵ to form a ring; and R⁴⁵ may be connected to R⁴⁶ to form a ring. Z41− represents a monovalent anion and is a halogen ion, perchlorate ion, hexafluorophosphate ion, tetrafluoroborate ion, sulfonate ion, sulfinate ion, thiosulfonate ion, or sulfate ion. Viewed from the perspective of stability and the printed-out image inspectability, the perchlorate ion, hexafluorophosphate ion, tetrafluoroborate ion, sulfonate ion, sulfinate ion, and carboxylate ion are preferred.

Examples are provided below of onium salts suitable for use as a polymerization initiator in the present invention, but the present invention is not limited to these.

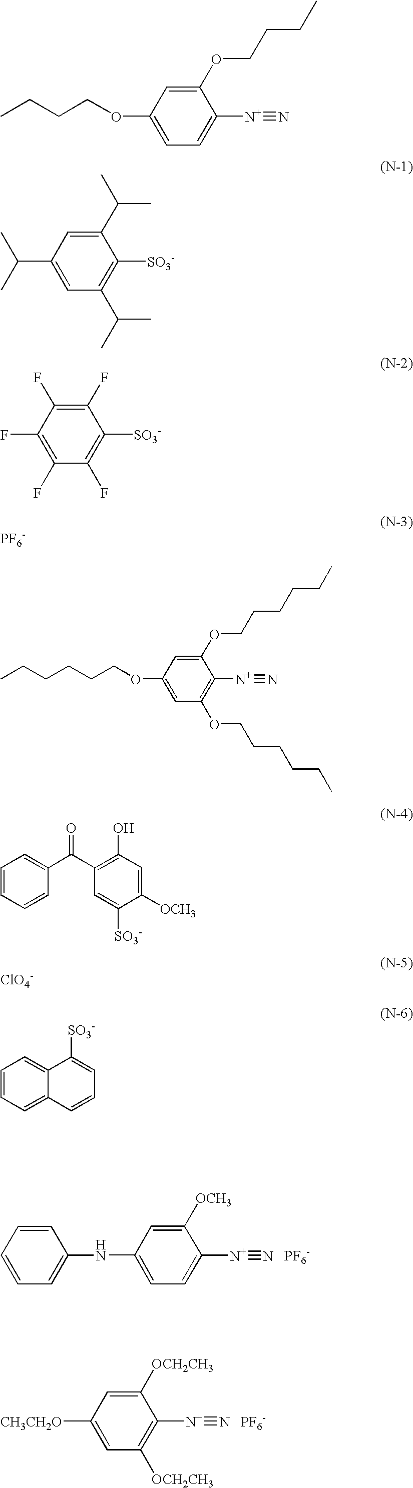

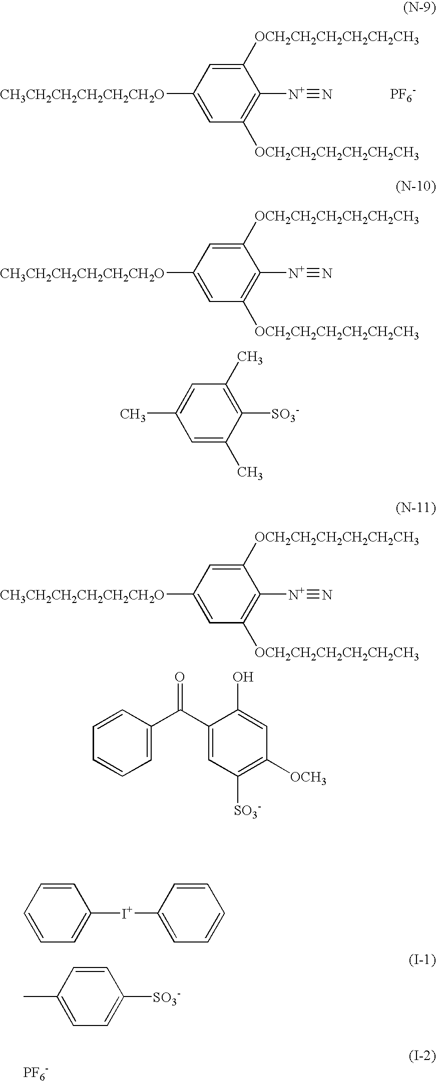

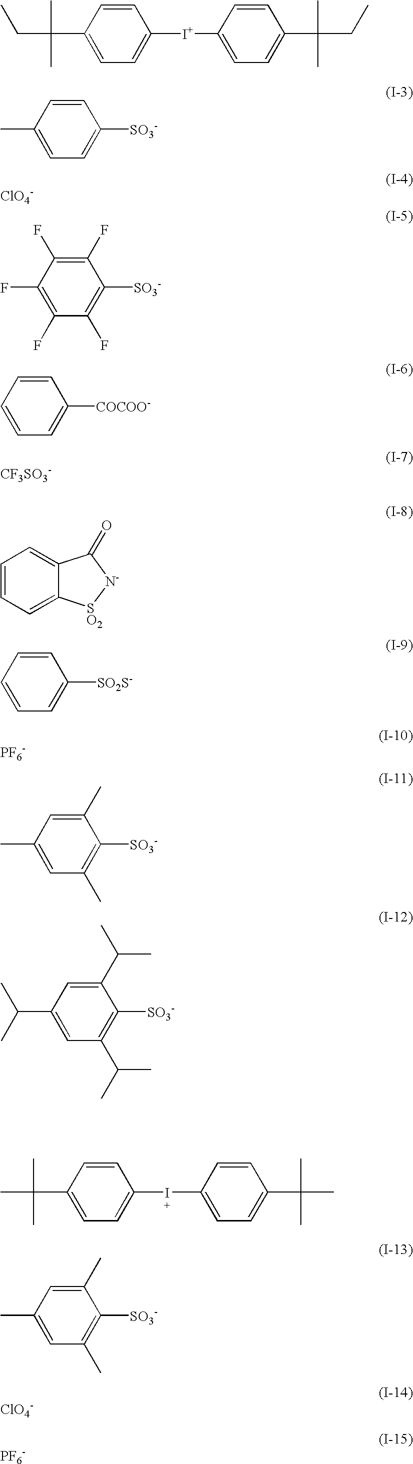

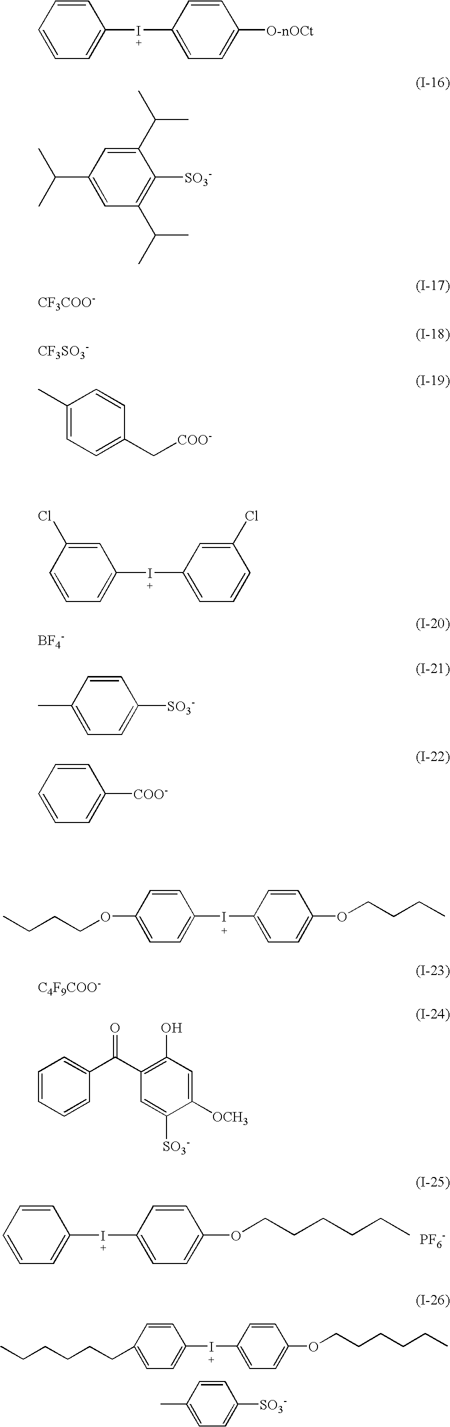

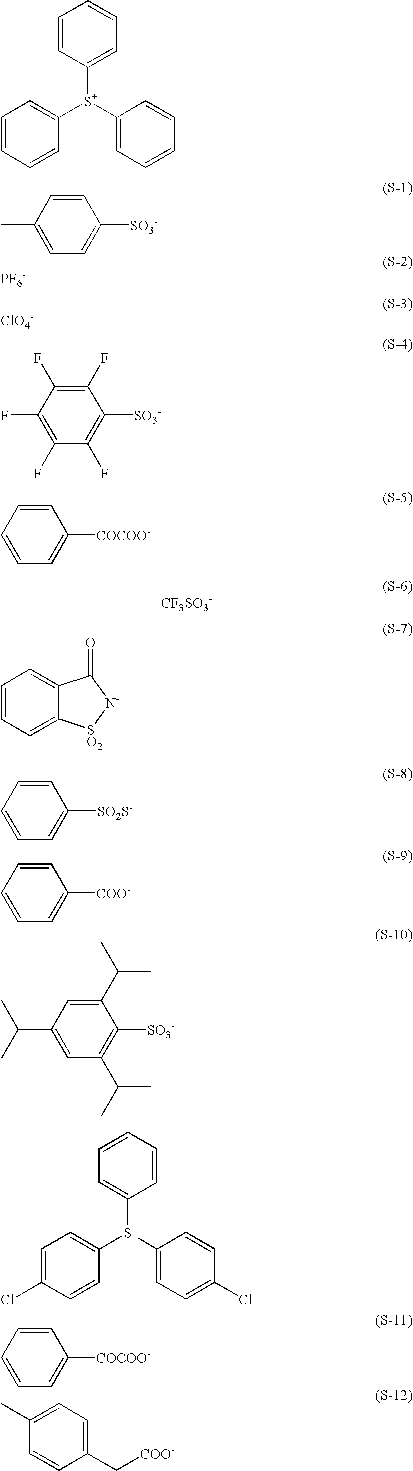

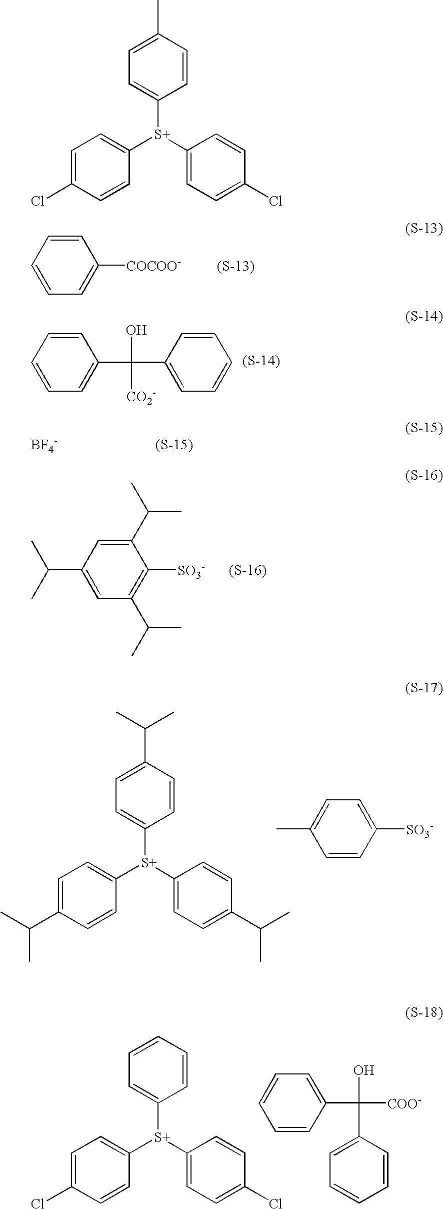

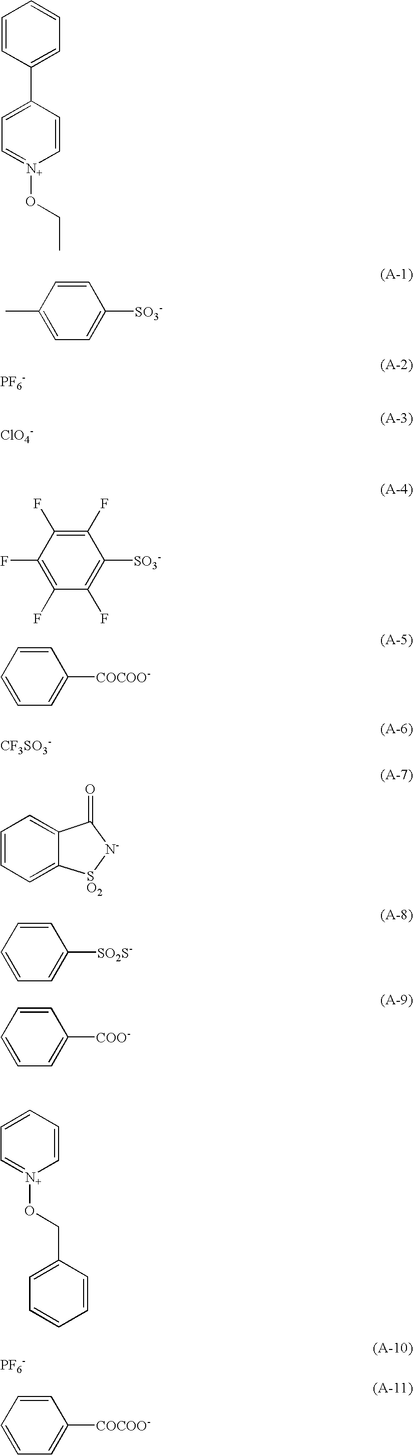

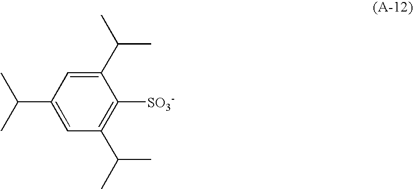

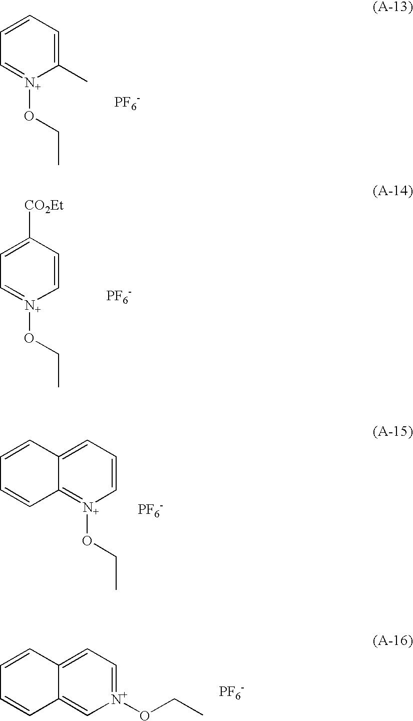

Among the polymerization initiators considered hereabove, onium salts having an inorganic anion as the counterion, for example, PF₆— or BF₄—, are preferred from the standpoint of improving the inspectability of the printed out image. Diaryliodonium and ammonium are preferred as the onium moiety due to the excellent printing durability this provides.

These polymerization initiators can be added at 0.1 to 50 mass %, preferably 0.5 to 30 mass %, and particularly preferably 1 to 20 mass %, in each case based on the total solids fraction comprising the photopolymerizable layer. An excellent sensitivity and an excellent resistance to scumming in the nonimage areas during printing are obtained in the cited range. A single one of these polymerization initiators may be used or two or more may be used in combination. The polymerization initiator may be incorporated in the same layer with other components or may be incorporated in a separately disposed layer.

### [Polymerizable Monomer]

The photopolymerizable layer in the present invention preferably contains a polymerizable monomer in order to efficiently carry out the curing reaction. Polymerizable monomers that can be used by the present invention are addition-polymerizable compounds that have at least one ethylenically unsaturated double bond and are selected from compounds that have at least one and preferably at least two ethylenically unsaturated bonds in terminal position. This group of compounds is widely known in the pertinent industrial field, and these can be used in the present invention without particular limitation. These compounds have, for example, the following chemical configurations: monomer, prepolymer (i.e., dimer, trimer, and oligomer), mixtures of the preceding, copolymers of the preceding, and so forth. Examples of the monomers and their copolymers are unsaturated carboxylic acids (for example, acrylic acid, methacrylic acid, itaconic acid, crotonic acid, isocrotonic acid, maleic acid, and so forth) and their esters and amides, preferably esters between an unsaturated carboxylic acid and an aliphatic polyhydric alcohol compound and amides between an unsaturated carboxylic acid and an aliphatic polyvalent amine compound. Also suitable for use are the addition reaction products from a monofunctional or multifunctional isocyanate or epoxide and an unsaturated carboxylic acid ester or amide that has a nucleophilic substituent such as, for example, the hydroxyl group, amino group, mercapto group, and so forth, and the dehydration condensation reaction products from a monofunctional or multifunctional carboxylic acid and an unsaturated carboxylic acid ester or amide that has a nucleophilic substituent such as, for example, the hydroxyl group, amino group, mercapto group, and so forth. Also suitable are the addition reaction products from a monofunctional or multifunctional alcohol, amine, or thiol and an unsaturated carboxylic acid ester or amide that has an electrophilic substituent such as, for example, the isocyanate group, epoxy group, and so forth, and substitution reaction products from a monofunctional or multifunctional alcohol, amine, or thiol and an unsaturated carboxylic acid ester or amide that has a leaving group such as, for example, a halogen group, tosyloxy group, and so forth. Another set of usable examples is provided by the group of compounds generated by replacing the unsaturated carboxylic acid cited above with, for example, an unsaturated phosphonic acid, styrene, vinyl ether, and so forth.

The following are specific examples of monomers that are esters between an aliphatic polyhydric alcohol compound and an unsaturated carboxylic acid: acrylate esters such as ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl) ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, polyester acrylate oligomer, and so forth;

Methacrylate esters such as tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, bis [p-(methacryloxyethoxy)phenyl]dimethylmethane, tri(methacryloyloxyethyl)isocyanurate, and so forth;

Itaconate esters such as ethylene glycol diitaconate, propylene glycol diitaconate, 1,3-butanediol diitaconate, 1,4-butanediol diitaconate, tetramethylene glycol diitaconate, pentaerythritol diitaconate, sorbitol tetraitaconate, and so forth; crotonate esters such as ethylene glycol dicrotonate, tetramethylene glycol dicrotonate, pentaerythritol dicrotonate, sorbitol tetracrotonate, and so forth; isocrotonate esters such as ethylene glycol diisocrotonate, pentaerythritol diisocrotonate, sorbitol tetraisocrotonate, and so forth; and maleate esters such as ethylene glycol dimaleate, triethylene glycol dimaleate, pentaerythritol dimaleate, sorbitol tetramaleate, and so forth.

Examples of other suitable esters are the aliphatic alcohol-based esters described in Japanese Patent Publication No. Sho 51-47334 and Japanese Patent Application Publication No. Sho 57-196231; esters having an aromatic skeleton as described in Japanese Patent Application Publication Nos. Sho 59-5240, Sho 59-5241, and Hei 2-226149; and the amino group-containing esters described in Japanese Patent Application Publication No. Hei 1-165613. In addition, the above described ester monomers can also be used in the form of mixtures.

The following are specific examples of monomers that are amides between an aliphatic polyvalent amine compound and an unsaturated carboxylic acid: methylenebisacrylamide, methylenebismethacrylamide, 1,6-hexamethylenebisacrylamide, 1,6-hexamethylenebismethacrylamide, diethylenetriamine trisacrylamide, xylylenebisacrylamide, xylylenebismethacrylamide, and so forth. Other examples of preferred amide-type monomers are those having a cyclohexylene structure as described in Japanese Patent Publication No. Sho 54-21726.

Also suitable are urethane-type addition-polymerizable compounds produced using the addition reaction between isocyanate and the hydroxyl group; a specific example here is the vinyl urethane compound containing at least two polymerizable vinyl groups in each molecule, as described in Japanese Patent Publication No. Sho 48-41708, that is generated by the addition of hydroxyl-functional vinyl monomer represented by general formula (ii) below to a polyisocyanate compound that contains at least two isocyanate groups in each molecule

CH₂═C(R⁴)COOCH₂CH(R⁵)OH (ii)

(wherein R⁴ and R⁵ represent H or CH₃).

The following are also suitable; the urethane acrylates as described in Japanese Patent Application Publication No. Sho 51-37193 and Japanese Patent Publication Nos. Hei 2-32293 and Hei 2-16765 and the urethane compounds having an ethylene oxide-type skeleton as described in Japanese Patent Publication Nos. Sho 58-49860, Sho 56-17654, Sho 62-39417, and Sho 62-39418. In addition, a photopolymerizable composition that exhibits a very good photosensitive speed can be obtained by using the addition-polymerizable compounds having an amino structure or sulfide structure in the molecule that are described in Japanese Patent Application Publication Nos. Sho 63-277653, Sho 63-260909, and Hei 1- 105238.

Other examples are the polyester acrylates as described in each of Japanese Patent Application Publication No. Sho 48-64183 and Japanese Patent Publication Nos. Sho 49-43191 and Sho 52-30490, as well as multifunctional acrylates and methacrylates such as epoxy acrylates as yielded by the reaction of epoxy resin with acrylic acid or methacrylic acid. Other examples are the special unsaturated compounds described in Japanese Patent Publication Nos. Sho 46-43946, Hei 1-40337, and Hei 1-40336 and the vinylphosphonic acid-type compounds described in Japanese Patent Application Publication No. Hei 2-25493. Structures containing a perfluoroalkyl group as described in Japanese Patent Application Publication No. Sho 61-22048 are suitably used in some cases. Also usable are the compounds introduced as photocurable monomers and oligomers in the Journal of the Adhesion Society of Japan, Volume 20, Number 7, pages 300 to 308 (1984).

The specifics of how these addition-polymerizable monomers are used, for example, their structure, whether a single such monomer or a combination of these monomers is used, the quantity of addition, and so forth, can be freely established in conformity with the properties designed for the final lithographic printing plate precursor. Selection can be made, for example, based on the following considerations.

Based on a consideration of the sensitivity, a structure is preferred that has a large unsaturated group content per molecule, and difunctional and above is preferred in many cases. In addition, trifunctional and above is preferred for the purpose of raising the strength of the image areas, that is, the cured film. It may also be effective to adjust both the sensitivity and strength by using combinations of monomers that have different numbers of functionalities different polymerizable groups (for example, acrylate esters, methacrylate esters, styrenic compounds, vinyl ether-type compounds). The selection of the addition-polymerizable compound and its method of use are also important factors for the compatibility and dispersibility with respect to the other components (for example, binder polymer, initiator, colorant, and so forth) in the photopolymerizable layer. For example, it may be possible to improve the compatibility by the use of two or more compounds in combination and/or by the use of a low-purity compound. Moreover, it may be possible to select a particular structure with the goal of improving the adhesiveness with, inter alia, a protective layer, infra, and/or the substrate.

The polymerizable monomer is used preferably at 5 to 80 mass % and more preferably 25 to 75 mass %, in each case with reference to the nonvolatile components in the photopolymerizable layer. A single polymerizable compound may be used or two or more may be used in combination. In addition to the preceding, within the context of the use strategy for the polymerizable monomer, a suitable structure, composition, and quantity of addition can be freely selected based on a consideration of, for example, the magnitude of polymerization inhibition by oxygen, the resolution, the fogging behavior, the change in refractive index, the surface tackiness, and so forth. Depending on the circumstances, a layer structure coating method such as undercoating and/or overcoating may also be implemented.

The polymerizable monomer is used in the photopolymerizable layer preferably in an amount that provides a binder polymer/polymerizable monomer mass ratio of 4/1 to 1/3, more preferably in an amount that provides a binder polymer/polymerizable monomer mass ratio of 3/1 to 1/3, and most preferably in an amount that provides a binder polymer/polymerizable monomer mass ratio of 3/2 to 1/3. This binder polymer is either the above-described special polymer binder by itself, or, when an additional binder polymer is used in combination with the special polymer binder, refers to the sum of the special polymer binder and the additional binder polymer.

### [Microcapsules—Microgel]

Various embodiments can be used for the method of incorporating the previously described photopolymerizable layer constituent components and the other components, infra, into the photopolymerizable layer. One embodiment is, for example, a molecular dispersion-type photopolymerizable layer obtained by dissolving the constituent components in an appropriate solvent and carrying out coating, as described in Japanese Patent Application Publication No. 2002-287334. Another embodiment is, for example, a microcapsule-type photopolymerizable layer in which all or a portion of the constituent components are present in the photopolymerizable layer incorporated in microcapsules, as described in Japanese Patent Application Publication Nos. 2001-277740 and 2001-277742. The constituent components can also be present in a microcapsule-type photopolymerizable layer outside the microcapsules. In a preferred embodiment of the microcapsule-type photopolymerizable layer, the hydrophobic constituent components are incorporated in microcapsules while the hydrophilic constituent components are present outside the microcapsules. In another embodiment, the photopolymerizable layer contains crosslinked resin particles, i.e., a microgel. This microgel can contain a portion of the constituent components within the microgel and/or on its surface. In particular, an embodiment that employs a microgel made reactive by disposing polymerizable monomer on its surface is particularly preferred from the standpoints of the image-forming sensitivity and printing durability.

The photopolymerizable layer preferably contains microcapsules or a microgel in order to obtain a photopolymerizable layer that is removable by printing ink and/or fountain solution (i.e., is on-press developable) or that is gum developable.

Known methods can be employed to microcapsulate the constituent components of the photopolymerizable layer or to formulate these components as a microgel.

The microcapsule production method can be exemplified by the following, but is not limited to the following: the use of coacervation as described in U.S. Pat. Nos. 2,800,457 and 2,800,458; interfacial polymerization as described in U.S. Pat. No. 3,287,154 and Japanese Patent Publication Nos. Sho 38-19574 and Sho 42-446; polymer precipitation as described in U.S. Pat. Nos. 3,418,250 and 3,660,304; the use of an isocyanate polyol wall material as described in U.S. Pat. No. 3,796,669; the use of an isocyanate wall material as described in U.S. Pat. No. 3,914,511; the use of a urea/formaldehyde-type or urea/formaldehyde/resorcinol-type wall-forming material as described in U.S. Pat. Nos. 4,001,140, 4,087,376, and 4,089,802; the use of a melamine-formaldehyde resin or hydroxycellulose wall material as described in U.S. Pat. No. 4,025,445; in situ polymerization of monomer as described in Japanese Patent Publication Nos. Sho 36-9163 and Sho 51-9079; spray drying as described in GB Patent No. 930422 and U.S. Pat. No. 3,111,407; and electrolytic dispersion and cooling as described in GB Patent Nos. 952807 and 967074.

A preferred microcapsule wall for use in the present invention has 3-dimensional crosslinking and is solvent swellable. From this standpoint, the microcapsule wall material is preferably polyurea, polyurethane, polyester, polycarbonate, polyamide, or a mixture of the preceding, with polyurea and polyurethane being particularly preferred. In addition, a compound having a crosslinkable functional group (e.g., an ethylenically unsaturated bond) capable of introduction into the binder polymer may be introduced into the microcapsule wall.

The microgel production method can be the interfacial polymerization-based granulation described in Japanese Patent Publication Nos. Sho 38-19574 and Sho 42-446 or granulation based on nonaqueous dispersion polymerization as described in Japanese Patent Application Publication No. Hei 5-61214. However, there is no limitation to these methods.

The known microcapsule production methods described above can be used for the aforementioned interfacial polymerization-based method.

A preferred microgel for use in the present invention is granulated using interfacial polymerization and has 3-dimensional crosslinking. From this standpoint, the material used is preferably polyurea, polyurethane, polyester, polycarbonate, polyamide, or a mixture or the preceding, with polyurea and polyurethane being particularly preferred.

The average particle size of the microcapsule or microgel is preferably from 0.01 to 3.0 μm, more preferably from 0.05 to 2.0 μm, and particularly preferably from 0.10 to 1.0 μm. Good resolution and good timewise stability are obtained within the cited range.

### [Surfactant]

The use of surfactant in the photopolymerizable layer is preferred in the present invention in order to promote the on-press developability when printing is started and in order to improve the coating planarity. The surfactant can be a nonionic surfactant, anionic surfactant, cationic surfactant, amphoteric surfactant, or fluorosurfactant. A single surfactant may be used or two or more surfactants may be used in combination.

There are no particular limitations on the nonionic surfactant used in the present invention and the heretofore known nonionic surfactants may be employed. Examples are as follows: polyoxyethylene alkyl ethers, polyoxyethylene alkylphenyl ethers, polyoxyethylene polystyrylphenyl ethers, polyoxyethylene polyoxypropylene alkyl ethers, glycerol/fatty acid partial esters, sorbitan/fatty acid partial esters, pentaerythritol/fatty acid partial esters, propylene glycol/fatty acid monoesters, sucrose/fatty acid partial esters, polyoxyethylene sorbitan/fatty acid partial esters, polyoxyethylene sorbitol/fatty acid partial esters, polyethylene glycol/fatty acid esters, polyglycerol/fatty acid partial esters, polyoxyethylenated castor oil, polyoxyethylene glycerol/fatty acid partial esters, fatty acid diethanolamides, N,N-bis-2-hydroxyalkylamines, polyoxyethylenealkylamines, triethanolamine/fatty acid esters, trialkylamine oxides, polyethylene glycols, and polyethylene glycol/polypropylene glycol copolymers.

There are no particular limitations on the anionic surfactant used in the present invention and the heretofore known anionic surfactants may be employed. Examples are as follows: fatty acid salts, abietic acid salts, hydroxyalkanesulfonic acid salts, alkanesulfonic acid salts, dialkyl sulfosuccinate salts, straight-chain alkylbenzenesulfonate salts, branched alkylbenzenesulfonate salts, alkylnaphthalenesulfonate salts, alkylphenoxypolyoxyethylenepropylsulfonate salts, polyoxyethylene alkylsulfophenyl ether salts, sodium N-methyl-N-oleyltaurate, the disodium salt of N-alkylsulfosuccinic acid monoamide, salts of petroleum sulfonic acids, sulfated beef tallow oil, the salts of sulfate esters of the alkyl esters of fatty acids, the salts of alkyl sulfate esters, the salts of sulfate esters of polyoxyethylene alkyl ethers, the salts of sulfate esters of fatty acid monoglycerides, the salts of sulfate esters of polyoxyethylene alkylphenyl ethers, the salts of sulfate esters of polyoxyethylene styrylphenyl ethers, the salts of alkyl phosphate esters, the salts of polyoxyethylene alkyl ether phosphate esters, the salts of polyoxyethylene alkylphenyl ether phosphate esters, partially saponified styrene-maleic anhydride copolymers, partially saponified olefin-maleic anhydride copolymers, and the formaldehyde condensates of naphthalenesulfonates.

There are no particular limitations on the cationic surfactant used in the present invention and the heretofore known cationic surfactants may be employed. Examples are as follows: alkylamine salts, quaternary ammonium salts, polyoxyethylenealkylamine salts, and polyethylenepolyamine derivatives.

There are no particular limitations on the amphoteric surfactant used in the present invention and the heretofore known amphoteric surfactants may be employed. Examples are as follows: carboxybetaines, aminocarboxylic acids, sulfobetaines, amino sulfate esters, and imidazolines.

The polyoxyethylene employed in the surfactants listed above may be replaced with polyoxyalkylene (e.g., polyoxymethylene, polyoxypropylene, polyoxybutylene, and so forth), and the resulting surfactants may also be used in the present invention.

A fluorosurfactant that contains a perfluoroalkyl group in the molecule is a more preferred surfactant. Such fluorosurfactants can be exemplified by anionic fluorosurfactants such as perfluoroalkylcarboxylate salts, perfluoroalkylsulfonate salts, perfluoroalkyl phosphate esters, and so forth; amphoteric fluorosurfactants such as perfluoroalkylbetaines and so forth; cationic fluorosurfactants such as perfluoroalkyltrimethylammonium salts and so forth; and nonionic fluorosurfactants such as perfluoroalkylamine oxides, perfluoroalkyltethylene oxide adducts, oligomers that contain both a perfluoroalkyl group and a hydrophilic group, oligomers that contain both a perfluoroalkyl group and an oleophilic group, oligomers that contain a perfluoroalkyl group and a hydrophilic group and an oleophilic group, urethanes that contain both a perfluoroalkyl group and an oleophilic group, and so forth. Also suitable are the fluorosurfactants described in Japanese Patent Application Publication Nos. Sho 62-170950, Sho 62-226143, and Sho 60-168144.

A single surfactant may be used or a combination of two or more surfactants may be used.

The surfactant content is preferably 0.001 to 10 mass % and more preferably 0.01 to 7 mass %, in each case with reference to the total solids fraction in the photopolymerizable layer.

### [Colorant]

Various compounds other than those previously cited may also be added on an optional basis in the present invention. For example, a dye that absorbs strongly in the visible light region can be used as an image colorant. Specific examples are Oil Yellow #101, Oil Yellow #103, Oil Pink #312, Oil Green BG, Oil Blue BOS, Oil Blue #603, Oil Black BY, Oil Black BS, and Oil Black T-505 (the preceding are products of Orient Chemical Industries, Ltd.), as well as Victoria Pure Blue, Crystal Violet (CI 42555), Methyl Violet (CI 42535), Ethyl Violet, Rhodamine B (CI 145170B), Malachite Green (CI 42000), Methylene Blue (CI 52015), and the dyes described in Japanese Patent Application Publication No. Sho 62-293247. Also suitable for use are pigments such as phthalocyanine pigments, azo pigments, carbon black, titanium oxide, and so forth.

The addition of these colorants is preferred because their addition facilitates discrimination of the image areas from the nonimage areas after image formation. The quantity of addition is 0.01 to 10 mass % with reference to the total solids fraction of the image recording material.

### [Print-Out Agent]

A compound that changes color under the action of acid or radicals can be added to the photopolymerizable layer of the present invention in order to produce a print-out image. Various dyes, for example, diphenylmethane types, triphenylmethane types, thiazine types, oxazine types, xanthene types, anthraquinone types, iminoquinone types, azo types, and azomethine types, are effectively used as this compound.

Specific examples as follows: dyes such as Brilliant Green, Ethyl Violet, Methyl Green, Crystal Violet, Basic Fuchsine, Methyl Violet 2B, Quinaldine Red, Rose Bengal, Methanyl Yellow, Thymol Sulfophthalein, Xylenol Blue, Methyl Orange, Paramethyl Red, Congo Red, Benzopurpurin 4B, α-Naphthyl Red, Nile Blue 2B, Nile Blue A, Methyl Violet, Malachite Green, Parafuchsine, Victoria Pure Blue BOH (Hodogaya Chemical Co., Ltd.), Oil Blue #603 (Orient Chemical Industries, Ltd.), Oil Pink #312 (Orient Chemical Industries, Ltd.), Oil Red 5B (Orient Chemical Industries, Ltd.), Oil Scarlet #308 (Orient Chemical Industries, Ltd.), Oil Red OG (Orient Chemical Industries, Ltd.), Oil Red RR (Orient Chemical Industries, Ltd.), Oil Green #502 (Orient Chemical Industries, Ltd.), Spiron Red BEH Special (Hodogaya Chemical Co., Ltd.), m-Cresol Purple, Cresol Red, Rhodamine B, Rhodamine 6G, Sulforhodamine B, Auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl)aminophenyliminonaphthoquinone, 1-phenyl-3-methyl-4-p-diethylaminophenylimino-5-pyrazolone, and 1-, -naphthyl-4-p-diethylaminophenylimino-5-pyrazolone; also, leuco dyes such as p,p′,p″-hexamethyltriaminotriphenylmethane (Leuco Crystal Violet) and Pergascript Blue SRB (Ciba Geigy Ltd.).

In addition to the preceding, the leuco dyes known as materials for heat-sensitive paper and pressure-sensitive paper are suitably used. Specific examples are as follows: Crystal Violet lactone, Malachite Green lactone, benzoyl leuco Methylene Blue, 2-(N-phenyl-N-methylamino)-6-(N-p-tolyl-N-ethyl)aminofluoran, 2-anilino-3-methyl-6-(N-ethyl-p-tolidino)fluoran, 3,6-dimethoxyfluoran, 3-(N,N-diethylamino)-5-methyl-7-(N,N-dibenzylamino)fluoran, 3-(N-cyclohexyl-N-methylamino)-6-methyl-7-anilinofluoran, 3-(N-N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino)fluoran, 3-(N,N-diethylamino)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-azaphthalide, and 3-(4-diethylaminophenyl)-3 -(1-ethyl-2-methylindol-3-yl)phthalide.

A suitable quantity of addition for the dye that undergoes acid- or radical-induced color change is in each case 0.01 to 10 mass % with reference to the solids fraction in the photopolymerizable layer.

### [Polymerization Inhibitor]

A small amount of a thermal polymerization inhibitor is preferably added to the photopolymerizable layer of the present invention in order to prevent unwanted thermal polymerization of the polymerizable monomer during production or storage of the photopolymerizable layer.

Suitable examples of the thermal polymerization inhibitor are hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), and N-nitroso-N-phenylhydroxylamine/aluminum salt.

The quantity of addition for the thermal polymerization inhibitor is preferably approximately 0.01 mass % to approximately 5 mass % with reference to the total solids fraction of the photopolymerizable layer.

### [Higher Fatty Acid Derivatives and So Forth]

In order to prevent oxygen-mediated inhibition of the polymerization, for example, a higher fatty acid or derivative thereof, such as behenic acid or behenamide, may be added to the photopolymerizable layer of the present invention; this becomes partitioned to the surface of the photopolymerizable layer in the drying process that follows coating. The quantity of addition of the higher fatty acid derivative is preferably approximately 0.1 mass % to approximately 10 mass % with reference to the total solids fraction of the photopolymerizable layer.

### [Plasticizer]

The photopolymerizable layer of the present invention may contain a plasticizer in order to improve the on-press developability.

Suitable examples of the plasticizer are as follows: phthalate esters such as dimethyl phthalate, diethyl phthalate, dibutyl phthalate, diisobutyl phthalate, dioctyl phthalate, octyl capryl phthalate, dicyclohexyl phthalate, ditridecyl phthalate, butyl benzyl phthalate, diisodecyl phthalate, diallyl phthalate, and so forth; glycol esters such as dimethyl glycol phthalate, ethyl phthalyl ethyl glycolate, methyl phthalyl ethyl glycolate, butyl phthalyl butyl glycolate, triethylene glycol dicaprylate, and so forth; phosphate esters such as tricresyl phosphate, triphenyl phosphate, and so forth; esters of dibasic fatty acids such as diisobutyl adipate, dioctyl adipate, dimethyl sebacate, dibutyl sebacate, dioctyl azelate, dibutyl maleate, and so forth; and also polyglycidyl methacrylate, triethyl citrate, glycerol triacetate, and butyl laurate.

The plasticizer content is preferably no more than approximately 30 mass % with respect to the total solids fraction in the photopolymerizable layer.

### [Finely Divided Inorganic Particles]

The photopolymerizable layer of the present invention may contain finely divided inorganic particles in order to improve the cured film strength in the image areas and improve the on-press developability of the nonimage areas.

Suitable examples of the finely divided inorganic particles are silica, alumina, magnesium oxide, titanium oxide, magnesium carbonate, calcium alginate, and mixtures of the preceding. Even though these lack the ability to convert light to heat, they can be used to strengthen the film and, through surface roughening, to reinforce the interfacial adhesion.

The finely divided inorganic particles preferably have an average particle size of 5 nm to 10 μm and more preferably 0.5 to 3 μm. Within the cited range, the finely divided inorganic particles can be stably dispersed in the photopolymerizable layer and can satisfactorily maintain the film strength of the photopolymerizable layer and can also form nonimage areas that exhibit an excellent hydrophilicity and thus are resistant to scumming during printing.

The finely divided inorganic particles under consideration can be easily acquired as commercial products, e.g., as a colloidal dispersion of silica.

The content of the finely divided inorganic particles is preferably no more than 20 mass % and more preferably no more than 10 mass %, in each case with reference to the total solids fraction of the photopolymerizable layer.

### [Low Molecular Weight Hydrophilic Compound]

The photopolymerizable layer of the present invention may contain a low molecular weight hydrophilic compound in order to improve the on-press developability and improve the gum developability. The low molecular weight hydrophilic compound can be exemplified by water-soluble organic compounds, e.g., glycols such as ethylene glycol, diethylene glycol, triethylene glycol, propylene glycol, dipropylene glycol, tripropylene glycol, and so forth, as well as the ether and ester derivatives of the preceding; polyhydroxy compounds such as glycerol, pentaerythritol, and so forth; organic amines such as triethanolamine, diethanolamine, monoethanolamine, and so forth, as well as their salts; organosulfonic acids such as toluenesulfonic acid, benzenesulfonic acid, and so forth, as well as their salts; organophosphonic acids such as phenylphosphonic acid and so forth, as well as their salts; organic carboxylic acids such as tartaric acid, oxalic acid, citric acid, malic acid, lactic acid, gluconic acid, amino acids, and so forth, as well as their salts; and isocyanuric acid derivatives. Among the preceding, the isocyanuric acid derivatives can improve the on-press developability and the gum developability without degrading the printing durability and their use is therefore preferred.

### [Formation of the Photopolymerizable Layer]

The photopolymerizable layer of the present invention is formed by dissolving or dispersing the required components of the photosensitive composition as described above in solvent to form a coating fluid; coating this coating fluid on a support; and drying. The solvent used here can be exemplified by ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethyl sulfoxide, sulfolane, γ-butyrolactone, toluene, water, and so forth, but the solvent is not limited to the preceding. A single one of these solvents or a mixture of these solvents may be used. The solids concentration in the coating fluid is preferably 1 to 50 mass %.

The photopolymerizable layer of the present invention may also be formed by preparing a plurality of coating fluids in which the same or different components (=the components described above) are dispersed or dissolved in the same solvent or different solvents and by carrying out coating and drying a plurality of times.

The application rate (solids fraction) for the photopolymerizable layer on the support that is obtained after coating and drying will vary with the intended use, but 0.3 to 3.0 g/m² is generally preferred. An excellent sensitivity is obtained in the cited range, as are excellent film-formation properties for the photopolymerizable layer.

A variety of methods can be used for the coating method. Examples are bar coater coating, spin coating, spray coating, curtain coating, dip coating, air knife coating, blade coating, roll coating, and so forth.

### <The Support>

The support used for the lithographic printing plate precursor of the present invention is a dimensionally stable sheet or plate but is not otherwise particularly limited. The support can be exemplified by paper, plastic-laminated paper (the plastic can be exemplified by polyethylene, polypropylene, polystyrene, and so forth), metal plate or sheet (e.g., aluminum, zinc, copper, and so forth), plastic film (e.g., cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal, and so forth), and paper or plastic film on which any of the aforementioned metals has been laminated or vapor-deposited. The support is preferably a polyester film or an aluminum plate. Aluminum plate is preferred therebetween for its excellent dimensional stability and relatively low cost.

The aluminum plate is a pure aluminum plate, an alloy plate containing aluminum as its main component along with trace amounts of heteroelements, or plastic laminated with a thin film of aluminum or aluminum alloy. Heteroelements that may be present in the aluminum alloy can be exemplified by silicon, iron, manganese, copper, magnesium, chromium, zinc, bismuth, nickel, titanium, and so forth. The heteroelement content in the alloy is preferably no more than 10 mass %. Although a pure aluminum plate is preferred in the present invention, the production of absolutely pure aluminum is problematic from the standpoint of refining technology, and the aluminum plate may therefore contain trace amounts of heteroelements. The aluminum plate is not limited with regard to composition, and any aluminum plate of material in the public domain can be used as appropriate.

The thickness of the support is preferably from 0.1 to 0.6 mm, more preferably from 0.15 to 0.4 mm, and even more preferably from 0. 15 to 0.3 mm.

Prior to its use, the aluminum plate is preferably subjected to a surface treatment such as a roughening treatment or an anodic oxidation treatment. Securing adhesion between the photopolymerizable layer and the support and securing an improved hydrophilicity are facilitated by the implementation of a surface treatment. Prior to executing a roughening treatment on the aluminum plate, the aluminum plate may as desired be submitted to a degreasing treatment with, for example, surfactant, organic solvent, aqueous base solution, and so forth, in order to remove rolling oil from the surface.

Various methods can be employed to roughen the surface of the aluminum plate, for example, mechanical surface roughening, electrochemical surface roughening (roughening by electrochemical dissolution of the surface), and chemical surface roughening (roughening by selective chemical dissolution of the surface).

Known methods, such as ball grinding, brush grinding, blast grinding, and buff grinding, can be used as the method for carrying out mechanical surface roughening.

Electrochemical roughening can be carried out, for example, using alternating current or direct current in an electrolytic bath that contains an acid such as hydrochloric acid or nitric acid. Another example is a method that uses a mixed acid as described in Japanese Patent Application Publication No. Sho 54-63902.

The surface-roughened aluminum plate may optionally be subjected to an alkali etching treatment using an aqueous solution of potassium hydroxide, sodium hydroxide, and so forth, followed by neutralization and then as desired an anodic oxidation treatment in order to improve the abrasion resistance.

The various electrolytes that can bring about the formation of a porous oxide film can be used as the electrolyte employed for anodic oxidation of the aluminum plate. Sulfuric acid, hydrochloric acid, oxalic acid, chromic acid, or a mixed acid of the preceding is typically used. The concentration of these electrolytes is determined as appropriate in accordance with the type of electrolyte.

The anodic oxidation conditions vary as a function of the electrolyte used and thus cannot be unconditionally specified; however, the following are generally preferred: electrolyte concentration=1 to 80 mass % solution, bath temperature=5 to 70° C., current density=5 to 60 A/dm², voltage=1 to 100 V, electrolysis time=10 seconds to 5 minutes. The quantity of anodic-oxidation film formation is preferably from 1.0 to 5.0 g/m² and more preferably is from 1.5 to 4.0 g/m². An excellent printing durability and an excellent resistance to damage in the nonimage areas of the lithographic printing plate are obtained in the cited range.

As necessary, the surface of the aluminum plate may be subjected to a hydrophilization treatment after the anodic oxidation treatment has been completed. This hydrophilization treatment can employ, for example, the alkali metal silicate method described in U.S. Pat. Nos. 2,714,066, 3,181,461, 3,280,734, and 3,902,734. In this method, the support is treated, by immersion or electrolysis, in an aqueous solution of, for example, sodium silicate. Examples of other methods are treatment with potassium fluozirconate as described in Japanese Patent Publication No. Sho 36-22063 and treatment with polyvinylphosphonic acid as described in U.S. Pat. Nos. 3,276,868, 4,153,461, and 4,689,272.

The center-line average roughness of the support is preferably from 0.10 to 1.2 μm. A good adhesion to the photopolymerizable layer, good printing durability, and good scumming resistance are obtained in the cited range.

In addition, the support preferably has a color density of 0.15 to 0.65 expressed as the reflection density value. An excellent capacity to inspect the plate after development is obtained within the cited range, as are excellent image-forming characteristics due to the prevention of halation during imagewise photoexposure.

### <Backcoat Layer>

After surface treatment has been carried out on the support or after the undercoat layer has been formed on the support, a backcoat may as necessary be provided on the back side of the support.

Preferred examples of the backcoat are the coating layer comprising an organic polymer compound as described in Japanese Patent Application Publication No. Hei 5-45885, and the coating layer comprising a metal oxide obtained by the hydrolysis and polycondensation of an organometal compound or inorganic metal compound as described in Japanese Patent Application Publication No. Hei 6-35174. In particular, the use of alkoxy compounds of silicon, e.g., Si(OCH₃)₄, Si(OC₂H₅)₄, Si(OC₃H₇)₄, Si(OC₄H₉)₄, and so forth, is preferred because these starting material can be easily and inexpensively acquired.

### <Undercoat Layer>

The lithographic printing plate precursor of the present invention may as necessary be provided with an undercoat layer between the photopolymerizable layer and the support. This undercoat layer facilitates delamination of the photopolymerizable layer from the support in the unexposed areas and thereby improves the on-press developability in the case of the on-press-developable lithographic printing plate precursor. In addition, when photoexposure is carried out with an infrared laser, the undercoat layer functions as a heat insulating layer; as a consequence, the heat generated by photoexposure is prevented from diffusing to the support and is thereby efficiently utilized, accruing the advantage of supporting an increase in the sensitivity.

When, in particular, a UV ink is employed, the undercoat layer in the present invention preferably contains, with the goal of improving the fine line reproducibility, a compound that contains both an addition-polymerizable ethylenic double bond and a group adsorptive to the surface of the hydrophilic support.

Preferred compounds for forming the undercoat layer (undercoat compounds) can be specifically exemplified by silane coupling agents that contain an addition-polymerizable ethylenic double bond reactive group, as described in Japanese Patent Application Publication No. Hei 10-282679, and phosphorus compounds containing an ethylenic double bond reactive group, as described in Japanese Patent Application Publication No. Hei 2-304441.

The most preferred undercoat compounds can be exemplified by polymer resins obtained by the copolymerization of adsorptive group-containing monomer, hydrophilic group-containing monomer, and crosslinking group-containing monomer.

A group that adsorbs to the surface of the hydrophilic support is an essential component of the polymer resin for undercoat formation. The presence/absence of adsorptivity to the surface of the hydrophilic support can be determined, for example, by the following method.

A coating solution is prepared by dissolving the test compound in a good solvent and this coating solution is coated and dried on the support so as to provide a post-drying coating rate of 30 mg/m². The support coated with the test compound is then thoroughly rinsed with the good solvent, and the residual quantity of the test compound that has not been removed by rinsing is subsequently measured in order to determine the quantity adsorbed to the support. Measurement of this residual quantity can be carried out by a direct determination of the residual quantity of the compound, or the quantity of the test compound that has dissolved in the rinse solution can be determined and used to calculate the residual quantity. Determination of the compound can be carried out, for example, by x-ray fluorescence measurements, reflection absorption spectroscopic measurements, liquid chromatographic measurement, and so forth. A compound that is adsorptive to the support will have a residue of at least 1 mg/m² even when the cited rinsing treatment is carried out.

The group adsorptive to the surface of the hydrophilic support is a functional group that can produce a chemical bond (for example, an ionic bond, hydrogen bond, coordination bond, or a bond due to intermolecular forces) with a substance (for example, a metal or metal oxide) or a functional group (for example, the hydroxyl group) present at the surface of the hydrophilic support. The adsorptive group is preferably an acid group or a cationic group.

The acid group preferably has an acid dissociation constant (pKa) no greater than 7. Examples of the acid group are the phenolic hydroxyl group, the carboxyl group, —SO₃H, —OSO₃H, —PO₃H₂, —OPO₃H₂, —CONHSO₂—, —SO₂NHSO₂—, and COCH₂COCH₃. Particularly preferred among the preceding are OPO₃H₂ and PO₃H₂. This acid group may also be a metal salt.

The cationic group is preferably an onium group. Examples of onium groups are ammonium, phosphonium, arsonium, stibonium, oxonium, sulfonium, selenonium, stannonium, and iodonium. Preferred thereamong are ammonium, phosphonium, and sulfonium. Ammonium and phosphonium are more preferred, and ammonium is most preferred.

Compounds represented by the following general formula (iii) and general formula (iv) are particularly preferred examples of adsorptive group-containing monomers.

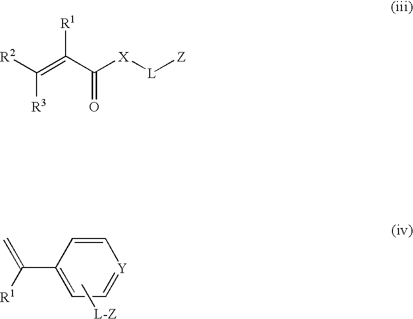

R¹, R², and R³ in the preceding formulas are each independently the hydrogen atom, a halogen atom, or C₁₋₆ alkyl. R¹, R², and R³ are each independently preferably the hydrogen atom or C₁₋₆ alkyl, more preferably the hydrogen atom or C₁₋₃ alkyl, and most preferably the hydrogen atom or methyl group R² and R³ are particularly preferably the hydrogen atom. Z is a functional group that adsorbs to the surface of the hydrophilic support.

X in formula (iii) is the oxygen atom (—O—) or imino (—NH—). X is more preferably the oxygen atom. L in formula (iii) is a divalent linking group. L is preferably a divalent aliphatic group (alkylene, substituted alkylene, alkenylene, substituted alkenylene, alkynylene, substituted alkynylene), divalent aromatic group (arylene, substituted arylene), or divalent heterocyclic group, or a combination of the preceding with the oxygen atom (—O—), sulfur atom (—S—), imino (—NH—), substituted imino (—NR— wherein R is an aliphatic group, aromatic group, or heterocyclic group), or carbonyl (—CO—).

The aforementioned aliphatic group may have a cyclic structure or a branched structure. The number of carbons in the aliphatic group is preferably 1 to 20, more preferably 1 to 15, and most preferably 1 to 10. A saturated aliphatic group is more preferred for the aliphatic group than an unsaturated aliphatic group. The aliphatic group may bear a substituent, and this substituent can be exemplified by halogen atoms, the hydroxyl group, aromatic groups, and heterocyclic groups.

The number of carbons in the aromatic group is preferably 6 to 20, more preferably 6 to 15, and most preferably 6 to 10. The aromatic group may bear a substituent, and this substituent can be exemplified by halogen atoms, the hydroxyl group, aliphatic groups, aromatic groups, and heterocyclic groups.

The aforementioned heterocyclic group preferably has a five-membered ring or six-membered ring for its heterocyclic ring. In addition, this heterocyclic ring may be condensed with an aliphatic ring, aromatic ring, or another heterocyclic ring. The heterocyclic group may bear a substituent, and this substituent can be exemplified by halogen atoms, the hydroxyl group, the oxo group (═O), the thioxo group (═S), the imino group (═NH), substituted imino (═N—R wherein R is an aliphatic group, aromatic group, or heterocyclic group), aliphatic groups, aromatic groups, and heterocyclic groups.

L is preferably a divalent linking group that contains a plurality of polyoxyalkylene structures. The polyoxyalkylene structure is more preferably a polyoxyethylene structure. In other words, L preferably contains —(OCH₂CH₂)ₙ—(n is an integer with a value of at least 2).

Y in formula (iv) is the carbon atom or nitrogen atom. In those instances where Y=nitrogen atom and L is connected to Y and a quaternary pyridinium group is thereby created, such a group is itself adsorptive and Z then becomes unnecessary and may be a hydrogen atom. L is a divalent linking group defined in the same manner as for formula (iii) or is a single bond.

The adsorptive functional group is as described above.

Examples of representative compounds with formula (iii) or (iv) are provided below.

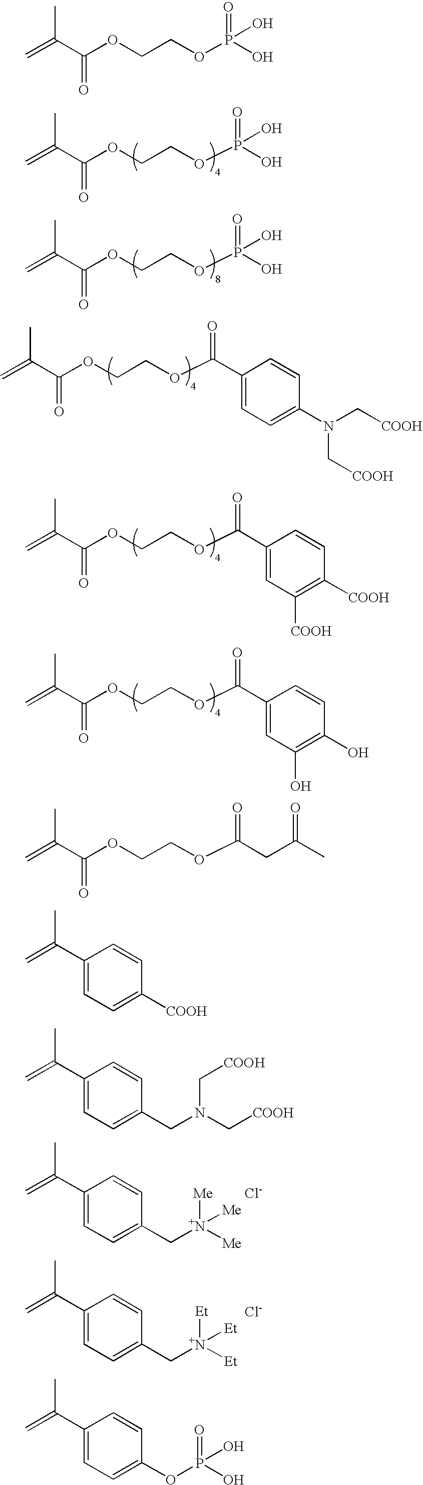

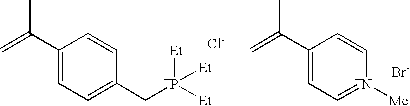

Suitable examples of the hydrophilic group in undercoat polymer resins usable in the present invention are the hydroxyl group, carboxyl group, carboxylate group, hydroxyethyl, polyoxyethyl, hydroxypropyl, polyoxypropyl, the amino group, aminoethyl, aminopropyl, the ammonium group, amide groups, carboxymethyl, the sulfo group, the phosphate group, and so forth. Monomer containing the highly hydrophilic sulfo group is preferred among the preceding. The following are specific examples of sulfo group-containing monomers: the sodium and amine salts of methallyloxybenzenesulfonic acid, allyloxybenzenesulfonic acid, allylsulfonic acid, vinylsulfonic acid, p-styrenesulfonic acid, methallylsulfonic acid, acrylamide-t-butylsulfonic acid, 2-acrylamido-2-methylpropanesulfonic acid, and (3-acryloyloxypropyl)butylsulfonic acid. Sodium 2-acrylamido-2-methylpropanesulfonate is preferred among the preceding for its hydrophilicity and handling during synthesis.

The polymer resin used to form the undercoat layer in the present invention preferably has a crosslinking group. An improved adhesion with the image areas is provided by the crosslinking group. In order to endow the polymer resin used to form the undercoat layer with the ability to crosslink, a crosslinking functional group, e.g., an ethylenically unsaturated bond, may be introduced into side chain position on the polymer, and/or the crosslinking functional group may be introduced by forming a salt structure with a compound that has an ethylenically unsaturated bond and a substituent that carries a charge opposite that of a polar substituent in the polymer resin.

Examples of polymers that have ethylenically unsaturated bonds in side chain position on the molecule are polymers of an ester or amide of acrylic acid or methacrylic acid wherein the ester or amide residue (R in —COOR or CONHR) contains an ethylenically unsaturated bond.

Examples of the ethylenically unsaturated bond-containing residue (the R cited above) are as follows: —CR¹═CR²R³, —(CH₂)ₙCR₁═CR₂R₃, —(CH₂O)ₙCH₂CR₁═CR₂R₃, —(CH₂CH₂O)ₙCH₂CR₁═CR₂R₃, —(CH₂)ₙNH—CO—O—CH₂CR₁═CR₂R₃, —(CH₂)ₙ—O—CO—CR₁═CR₂R₃, and (CH₂CH₂O)₂—X (in these formulas, R₁ to R₃ each represent the hydrogen atom, a halogen atom, or C₁₋₂₀ alkyl, aryl, alkoxy, or aryloxy; R₁ may be bonded with R₂ or R₃ to form a ring; n is an integer from 1 to 10; and X is the dicyclopentadienyl residue).

The following are specific examples of the ester residue: —CH═CH₂, —C(CH₃)═CH₂, —CH₂CH═CH₂ (described in Japanese Patent Publication No. Hei 7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂NHCOO—CH₂CH═CH₂, and CH₂CH₂O—X (X in the formula represents the dicyclopentadienyl residue).

The following are specific examples of the amide residue: —CH═CH₂, —C(CH₃)═CH₂, —CH₂CH═CH₂, —CH₂CH₂O—Y (Y in the formula represents the cyclohexene residue), and —CH₂CH₂OCO—CH═CH₂.

The aforementioned crosslinking group-containing ester or amide of acrylic acid or methacrylic acid is well suited for use as the crosslinking group-containing monomer for the polymer resin for undercoat layer formation.

The content of the crosslinking group in the polymer resin for undercoat layer formation (i.e., the content of the radically polymerizable unsaturated double bond, as yielded by iodine titration) is preferably 0.1 to 10.0 mmol per 1 g of the polymer resin, more preferably 1.0 to 7.0 mmol per 1 g of the polymer resin, and most preferably 2.0 to 5.5 mmol per 1 g of the polymer resin. An excellent combination of sensitivity and scumming behavior and an excellent storage stability are obtained in the cited range.

The polymer resin for undercoat layer formation has a mass-average molecular weight preferably of at least 5000 and more preferably of 10,000 to 300,000 and has a number-average molecular weight preferably of at least 1000 and more preferably of 2000 to 250,000. The polydispersity (mass-average molecular weight/number-average molecular weight) is preferably 1.1 to 10.

The polymer resin for undercoat layer formation may be a random polymer, block polymer, graft polymer, and so forth, wherein a random polymer is preferred.

A single polymer resin for undercoat layer formation may be used or a mixture of two or more may be used. The coating solution for undercoat layer formation is obtained by dissolving the aforementioned polymer resin for undercoat formation in organic solvent (for example, methanol, ethanol, acetone, methyl ethyl ketone, and so forth) and/or water. The coating solution for undercoat layer formation may also contain an infrared absorber.

Various known methods can be used to coat the support with the coating solution for undercoat layer formation. Examples of these methods are coating with a bar coater, spin coating, spray coating, curtain coating, dip coating, air knife coating, blade coating, roll coating, and so forth.

The coating rate (solids fraction) for the undercoat layer is preferably 0.1 to 100 mg/m² and more preferably 1 to 30 mg/m².

### <Protective Layer>

A protective layer (overcoat layer) may optionally be provided on the photopolymerizable layer of the lithographic printing plate precursor of the present invention in order to provide an oxygen-blocking action, prevent damage to the photopolymerizable layer, and prevent the ablation that can occur during photoexposure with a high intensity laser.

The photoexposure of lithographic printing plates is generally carried out in the air. Low molecular weight compounds present in the air, such as oxygen and basic substances, can inhibit the photoexposure-induced image-forming reactions in the photopolymerizable layer. The protective layer prevents these low molecular weight compounds (e.g., oxygen and basic substances) from mixing into the photopolymerizable layer and as a result prevents reactions that would inhibit image formation in the air. Thus, the characteristics desired for the protective layer are the ability to reduce the permeability of the low molecular weight compounds (e.g., oxygen), an excellent transmittance for the light used for photoexposure, an excellent adhesion to the photopolymerizable layer, and the ability to be easily removed in the on-press development treatment process following photoexposure. Protective layers having such characteristics are described in, for example, U.S. Pat. No. 3,458,311 and Japanese Patent Publication No. Sho 55-49729.

The material used for the protective layer is suitably selected from water-soluble polymers and water-insoluble polymers. Specific examples are water-soluble polymers, e.g., polyvinyl alcohol, modified polyvinyl alcohol, polyvinylpyrrolidone, polyvinylimidazole, polyacrylic acid, polyacrylamide, the partial saponification products of polyvinyl acetate, ethylene-vinyl alcohol copolymers, water-soluble cellulose derivatives, gelatin, starch derivatives, gum arabic, and so forth, as well as polymers such as polyvinylidene chloride, poly(meth)acrylonitrile, polysulfone, polyvinyl chloride, polyethylene, polycarbonate, polystyrene, polyamide, cellophane, and so forth. As necessary, these may also be used in combinations of two or more.

Water-soluble polymer compounds that exhibit an excellent crystaninity are relatively useful materials among the materials listed above. Preferred specific examples are polyvinyl alcohol, polyvinylpyrrolidone, polyvinylimidazole, water-soluble acrylic resins, e.g., polyacrylic acid, gelatin, gum arabic, and so forth. In terms of being coatable using water as the solvent and being easy to remove by the fountain solution during printing, polyvinyl alcohol, polyvinylpyrrolidone, and polyvinylimidazole are preferred among the preceding. Among these latter polymers, polyvinyl alcohol (PVA) provides the best results with respect to the basic characteristics, i.e., oxygen-barrier performance and removability during development.

Polyvinyl alcohols that can be used for the protective layer may be partially substituted with an ester, ether, or acetal as long as the unsubstituted vinyl alcohol unit is present in substantially the amount that provides the necessary water solubility. Other copolymer components may be present to some degree under the same conditions. For example, the use is also preferred of polyvinyl alcohol with various degrees of polymerization that randomly contains any of various hydrophilic modified sites, such as anion-modified sites that have been modified with an anion (e.g., the carboxyl group or sulfo group), cation-modified sites that have been modified with a cation (e.g., an amino group or ammonium group), silanol-modified sites, thiol-modified sites, and so forth, and polyvinyl alcohols with various degrees of polymerization that have various modified sites at the polymer chain terminals, e.g., the aforementioned anion-modified sites, the aforementioned cation-modified sites, silanol-modified sites, and thiol-modified sites as well as alkoxyl-modified sites, sulfide-modified sites, ester-modified sites between the vinyl alcohol and an organic acid, ester-modified sites between the aforementioned anion-modified site and, for example, an alcohol, epoxy-modified sites, and so forth.

These modified polyvinyl alcohols are preferably compounds that have been from 71 to 100 mol % hydrolyzed and that have a degree of polymerization in the range from 300 to 2,400. Specific examples are PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613, and L-8 (from Kuraray Co., Ltd.). The following are additional examples of modified polyvinyl alcohols: KL-318, KL-118, KM-618, KM-118, and SK-5102, which each have anion-modified sites; C-318, C-118, and CM-318, which each have cation-modified sites; M-205 and M-115, which each have terminal thiol-modified sites; MP-103, MP-203, MP-102, and MP-202, which each have terminal sulfide-modified site; HL-12E and HL-1203, which have terminal ester (higher aliphatic acid)-modified sites; and R-1130, R-2105, and R-2130, which each have reactive silane-modified sites.

The protective layer also preferably contains a layer compound. This layer compound denotes particles that have a thin plate shape and is exemplified by the mica group, for example, synthetic micas and natural micas with the following general formula

A(B,C)₂₋₅D₄O₁₀(OH,F,O)₂

(wherein A represents any selection from Li, K, Na, Ca, Mg, and organic cations; B and C represent any selection from Fe(II), Fe(III), Mn, Al, Mg, and V; and D represents Si or Al), and by talc as represented by the formula 3MgO·4SiO·H₂O, taeniolite, montmorillonite, saponite, hectorite, and zirconium phosphate.

The natural micas cited above are exemplifed by muscovite, paragonite, phlogopite, biotite, and lepidolite. The synthetic micas can be exemplified by non-swellable micas, e.g., fluorophlogopite KMg₃(AlSi₃O₁₀)F₂ and potassium tetrasilicic mica KMg_{2.5}(Si₄O₁₀)F₂, and swellable micas, for example, Na tetrasilicic mica NaMg_{2.5}(Si₄O₁₀)F₂, Na or Li taeniolite (Na,Li)Mg₂Li(Si₄O₁₀)F₂, and montmorillonite series Na or Li hectorite (Na,Li)_{1/8}Mg_{2/5}Li_{1/8}(Si₄O₁₀)F₂. Synthetic smectites are also useful.

Among the layer compounds described above, fluorine-containing swellable micas that are synthetic layer compounds are particularly useful. Thus, swellable clay minerals, e.g., mica, montmorillonite, saponite, hectorite, and bentonite, have a layer structure comprising a unit crystal lattice layer having a thickness of 10 to 15 Å, and metal atom substitution within the lattice is much greater than in other clay minerals. As a result, a positive charge deficiency is produced in the lattice layer, and cations such as Li⁺, Na⁺, Ca²⁺, and Mg²⁺ and organic cations (e.g., amine salts, quaternary ammonium salts, phosphonium salts, sulfonium salts, and so forth) are adsorbed between the layers to compensate for this deficiency. These layer compounds are swollen by water. When shear is applied in the swollen state, cleavage readily occurs and a stable sol is formed in water. Bentonite and swellable synthetic micas strongly exhibit this tendency.

On the subject of the shape of the layer compound, with regard to thickness, thinner is more desirable from the standpoint of controlling diffusion; with regard to the size of the flat side, larger is more desirable as long as neither the smoothness of the coated surface nor the transmission of the active light are impaired. The aspect ratio is therefore at least 20, preferably at least 100, and particularly preferably at least 200. Here, the aspect ratio is the ratio between the longer diameter of the particle and the thickness thereof, and can be measured, for example, from the projection yielded by a microphotograph of the particle. A larger aspect ratio provides a greater effect.

With regard to the average particle size of the layer compound, its average diameter is from 1 to 20 μm, preferably from 1 to 10 μm, and particularly preferably from 2 to 5 μm. The inhibition of oxygen and moisture permeation is inadequate at a particle size smaller than 1 μm and an adequate effect therefore cannot be evidenced. When the particle size is larger than 20 μm, the dispersion stability in the coating fluid is inadequate and coating cannot be carried out in a stable manner. The average thickness of the particles is no more than 0.1 μm, preferably no more than 0.05 μm, and particularly preferably no more than 0.01 μm. For example, among the inorganic layer compounds, the swellable synthetic micas, taken as representative compounds, have a thickness from 1 to 50 nm and a face size from 1 to 20 μm.

The coated film strength can be improved and the permeation of oxygen and moisture can be effectively prevented when the protective layer contains the high aspect ratio inorganic layer compound particles described above. As a consequence, impairment of the protective layer due, for example, to deformation, can be prevented, and an excellent storage stability—including no decline in the image-forming performance of the lithographic printing plate precursor due to humidity changes—is obtained even for long-term storage under high humidity conditions.

The content of the inorganic layer compound in the protective layer is preferably from 5/1 to 1/100 as the mass ratio with respect to the amount of binder used in the protective layer. 2/1 to 1/5 is more preferred. When a plurality of inorganic layer compounds are used in combination, it is again preferred that the total quantity of these inorganic layer compounds satisfy this mass ratio.

In order to improve the receptivity, a phosphonium compound is preferably also added to the photopolymerizable layer and/or protective layer in those instances where the above-described inorganic layer compound is used in the protective layer. Phosphonium compounds with the following general formulas (v) and (vi) are preferred for this phosphonium compound, wherein phosphonium compounds with general formula (v) are preferred therebetween.

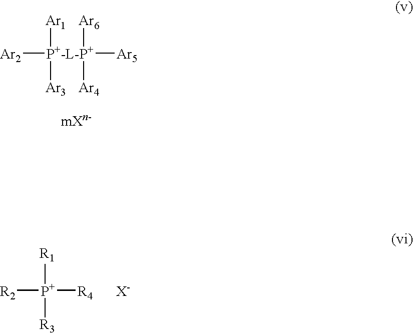

Ar₁ to Ar₆ in formula (v) each independently represent aryl or a heterocyclic group; L represents a divalent linking group; X represents an n-valent counteranion; n represents an integer with a value of 1 to 3; and m represents a number that satisfies n×m=2. Preferred examples of the aryl here are phenyl, naphthyl, tolyl, xylyl, fluorophenyl, chlorophenyl, bromophenyl, methoxyphenyl, ethoxyphenyl, dimethoxyphenyl, methoxycarbonylphenyl, dimethylaminophenyl, and so forth. The heterocyclic group can be exemplified by pyridyl, quinolyl, pyrimidinyl, thienyl, furyl, and so forth.

L represents a divalent linking group. The number of carbons in the linking group is preferably 6 to 15, and more preferably this is a C₆₋₁₂ linking group.

X— represents a counteranion, wherein preferred counteranions are halogen anions such as Cl—, Br—, and I—, the sulfonate anion, carboxylate anions, sulfate ester anions, PF₆—, BF₄—, and the perchlorate anion. Particularly preferred thereamong are halogen anions such as Cl—, Br—, and I—, the sulfonate anion, and carboxylate anions.

Specific examples of phosphonium salts with general formula (v) for use in the present invention are provided below.

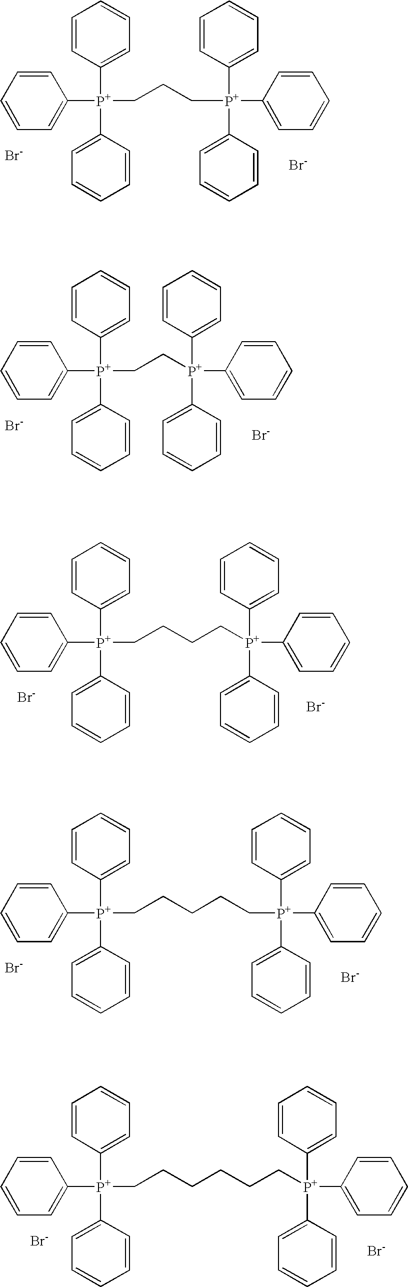

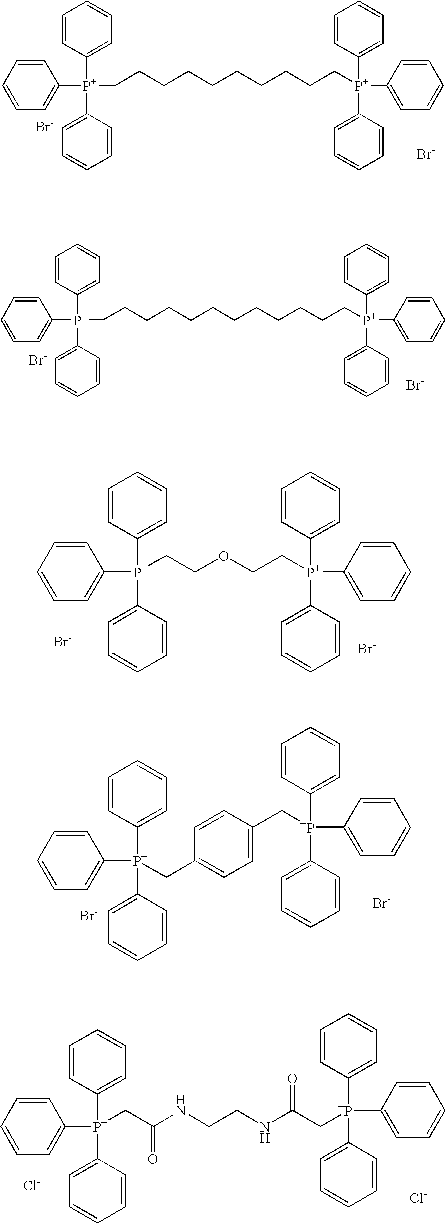

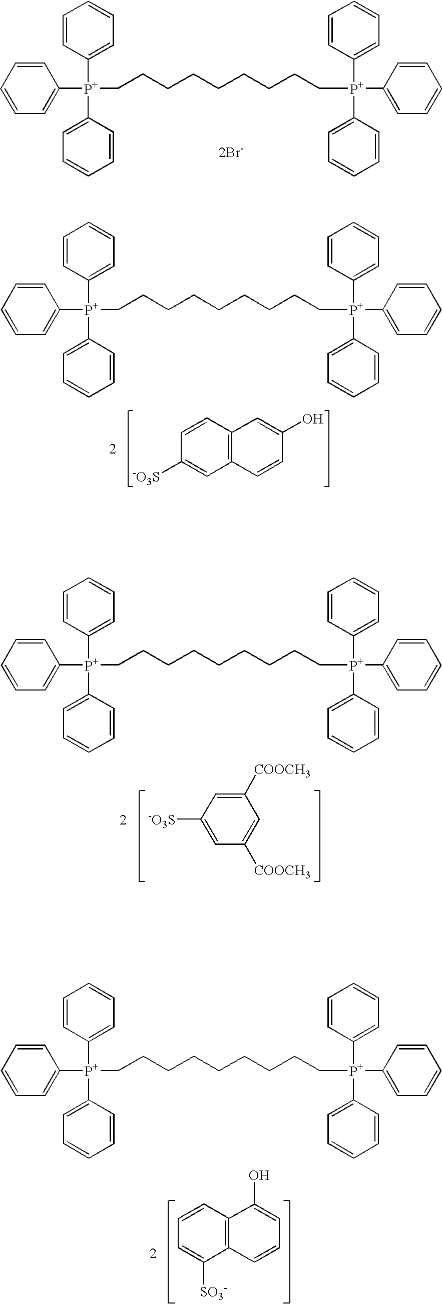

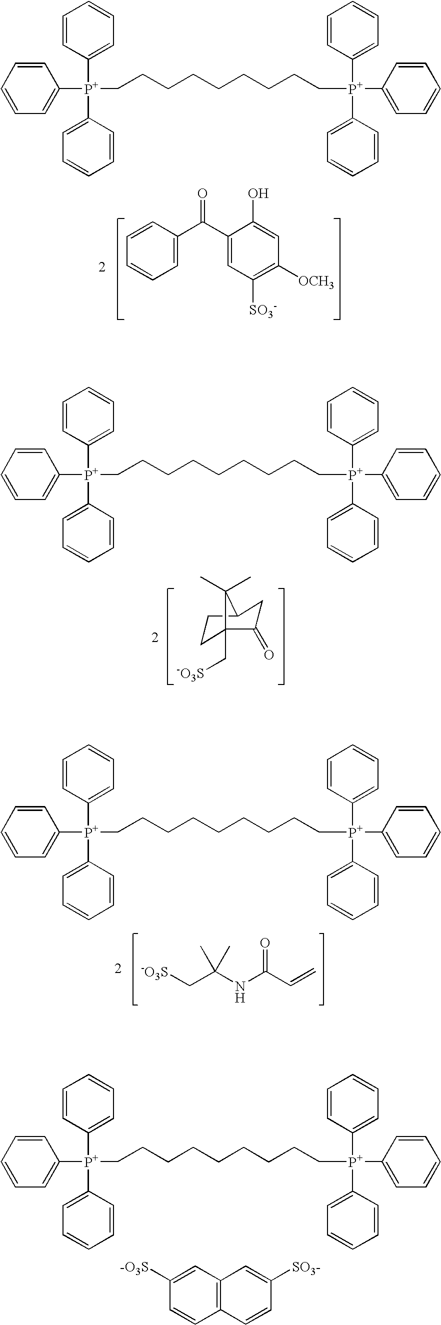

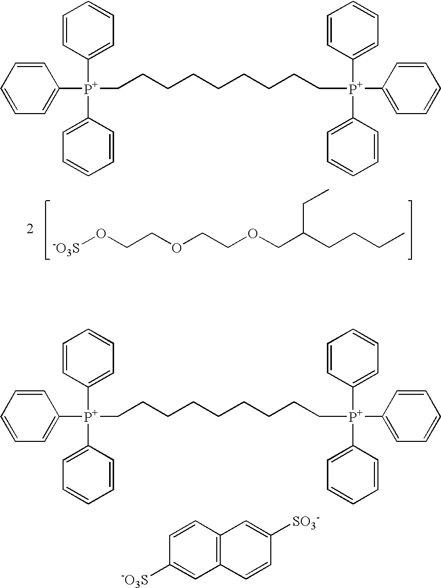

R₁ to R₄ in general formula (vi) each independently represent possibly substituted alkyl, alkenyl, alkynyl, cycloalkyl, alkoxy, aryl, aryloxy, alkylthio, or a heterocyclic group or the hydrogen atom. Two or more of R₁ to R₄ may be bonded to each other to form a ring. X— represents a counteranion.

The number of carbons is generally 1 to 20 when R₁ to R₄ is alkyl, alkoxy, or alkylthio; the number of carbons is generally 2 to 15 when R₁ to R₄ is alkenyl or alkynyl; and the number of carbons is generally 3 to 8 when R₁ to R₄ is cycloalkyl. The aryl is exemplified by phenyl, naphthyl, and so forth; the aryloxy is exemplified by phenoxy, naphthyloxy, and so forth; the arylthio is exemplified by phenylthio and so forth; and the heterocyclic group is exemplified by furyl, thienyl, and so forth. The substituents possibly present on these groups are exemplified by alkyl, alkenyl, alkynyl, cycloalkyl, alkoxy, alkoxycarbonyl, acyl, alkylthio, aryl, aryloxy, arylthio, sulfino, sulfo, phosphino, phosphoryl, the amino group, the nitro group, the cyano group, the hydroxyl group, and halogen atoms. These substituents may themselves be substituted.

The anion represented by X— can be exemplified by halogen ions such as Cl—, Br—, and I—; the anions of inorganic acids, such as ClO₄—, PF₆—, and SO₄²—; organocarboxylate anions; and organosulfonate anions. The organic group in the organocarboxylate anion and organosulfonate anion can be exemplified by methyl, ethyl, propyl, butyl, phenyl, methoxyphenyl, naphthyl, fluorophenyl, difluorophenyl, pentafluorophenyl, thienyl, pyrrolyl, and so forth. Cl—, Br—, I—, ClO₄—, PF₆—, and so forth are preferred among the preceding. Specific examples of phosphonium compounds suitable for the present invention are given below.

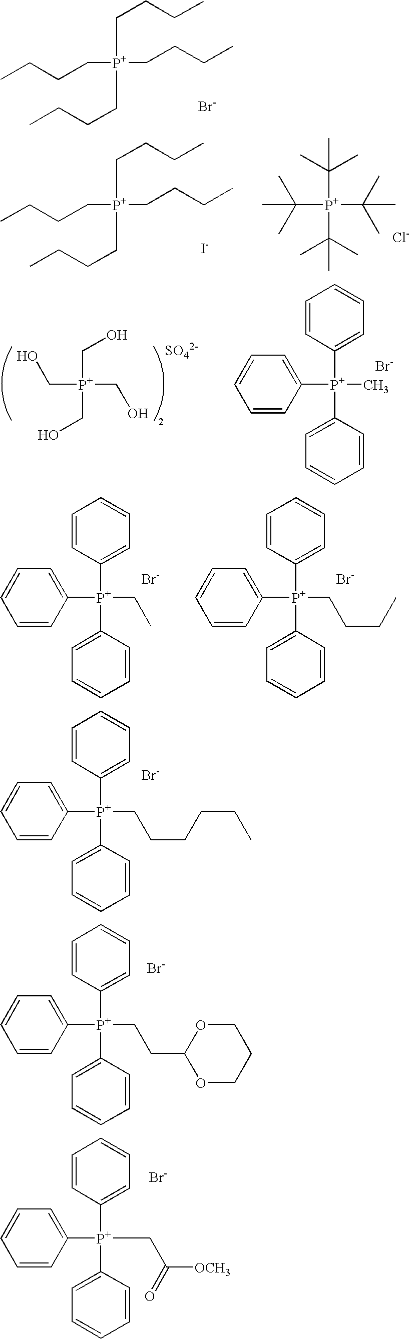

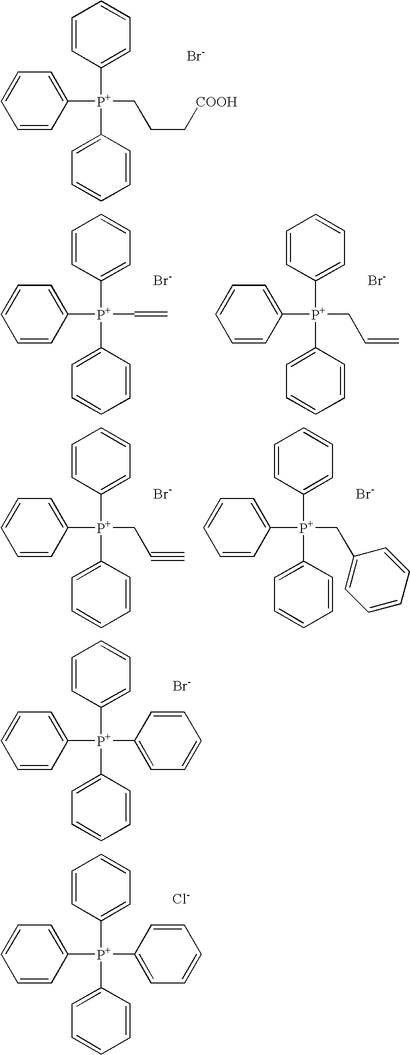

The quantity of phosphonium salt addition to the photopolymerizable layer or protective layer is preferably 0.01 to 20 mass %, more preferably 0.05 to 10 mass %, and most preferably 0.1 to 5 mass %, in each case with reference to the solids fraction in the particular layer. An excellent ink receptivity is obtained in these ranges.

With regard to other components in the protective layer, the addition of, for example, glycerol or dipropylene glycol in an amount corresponding to several mass % with reference to the (co)polymer can provide flexibility. An anionic surfactant such as a sodium alkyl sulfate, sodium alkylsulfonate, and so forth, an amphoteric surfactant such as an alkylaminocarboxylic acid salt, alkylaminodicarboxylic acid salt, and so forth, or a nonionic surfactant such as a polyoxyethylene alkylphenyl ether and so forth, can also be added. These surfactants can be added at from 0.1 to 100 mass % with reference to the (co)polymer.

In order to bring about an excellent adhesion with the image areas, Japanese Patent Application Publication No. Sho 49-70702 and GB 1,303,578 teach that a satisfactory adhesion is obtained by mixing 20 to 60 mass % of, for example, an acrylic emulsion or a water-insoluble vinylpyrrolidone-vinyl acetate copolymer, into a hydrophllic polymer comprising mainly polyvinyl alcohol and layering this on the photopolymerizable layer. Any of these known technologies may be used in the present invention.

The protective layer may also be provided with other functionalities. For example, the safelight fitness can be improved without causing a decline in sensitivity by adding a colorant (e.g., a water-soluble dye) that exhibits an excellent transmittance for the infrared radiation used in photoexposure and that can efficiently absorb light at other wavelengths.

Examples of general methods for dispersing the layer compound used in the protective layer are provided in the following. First, from 5 to 10 mass parts of the swellable layer compound, which was provided as a preferred layer compound among the previously described layer compounds, is added to 100 mass parts water. After thorough mixing into the water and swelling, the mixture is transferred to a disperser and dispersion is carried out. The disperser used here can be exemplified by mills that carry out dispersion by the direct application of mechanical force, high-speed stirring-type dispersers that generate high shear forces, and dispersers that apply high intensity ultrasonic energy. Specific examples are ball mills, sand grinder mills, viscomills, colloid mills, homogenizers, dissolvers, Polytrons, homomixers, homoblenders, Kady mills, the Jet Agitor, capillary emulsifying devices, liquid sirens, piezoelectric-type ultrasonic generators, and emulsifying devices equipped with a Polman whistle The dispersion, containing 5 to 10 mass % of the inorganic layer compound dispersed by the previously described method, has a high viscosity or is a gel and exhibits an extremely good storage stability. To prepare a coating fluid for protective layer formation using this dispersion, the dispersion is preferably diluted with water and thoroughly stirred and then blended with the binder solution.

Known additives may be added to the coating fluid for forming the protective layer. Thus, an anionic surfactant, nonionic surfactant, cationic surfactant, or fluorosurfactant can be added in order to improve the coating characteristics, while a water-soluble plasticizer can be added in order to improve the physical properties of the applied film. The water-soluble plasticizer can be exemplified by propionamide, cyclohexanediol, glycerol, sorbitol, and so forth. A water-soluble (meth)acrylic polymer may also be added. Moreover, known additives may be added to this coating fluid in order to improve the adhesion to the photopolymerizable layer and improve the timewise stability of the coating fluid.

The protective layer is formed by coating the coating fluid for protective layer formation, prepared as described in the preceding, on a photopolymerizable layer that itself has been disposed on a support. The solvent used for coating can be selected as appropriate in relation to the binder, wherein the use of distilled water or purified water is preferred when a water-soluble polymer is used. The method for applying the protective layer is not particularly limited and known methods, e.g., the methods described in U.S. Pat. No. 3,458,311 and Japanese Patent Publication No. Sho 55-49729, can be used. Specifically, for example, blade coating, air knife coating, gravure coating, roll coating, spray coating, dip coating, or bar coating may be used to form the protective layer.

The coating rate for the protective layer is preferably in the range from 0.01 to 10 g/m², more preferably in the range from 0.02 to 3 g/m², and most preferably in the range from 0.02 to 1 g/m², in each case as the coating rate after drying.

### [The Method of Lithographic Printing]

The lithographic printing plate precursor may be subjected to imagewise photoexposure by carrying out photoexposure through a transparent master image comprising line images, halftone images, and so forth, or may be subjected to imagewise photoexposure by laser photoscanning from digital data. Known light sources can be used as the light source for photoexposing the lithographic printing plate precursor. In specific terms, various lasers are preferably used as the light source. The lithographic printing plate precursor can be imagewise photoexposed using, for example, an infrared laser in the method of lithographic printing according to the present invention. While there are no particular limitations on the infrared laser used, solid state lasers and semiconductor lasers that emit infrared radiation at wavelengths of 760 to 1200 nm are preferred examples.

The photoexposure mechanism may be any selection from internal drum, external drum, and flat bad configurations. The output of the infrared laser is preferably at least 100 mW. The use of a multibeam laser device is preferred in order to shorten the photoexposure time. The photoexposure time per pixel is preferably no more than 20 μs. The irradiated energy dose is preferably 10 to 300 mJ/cm².

A preferred light source also operates at wavelengths of 350 to 450 nm, and an InGaN-type semiconductor laser is specifically preferred. The photoexposure mechanism may be any selection from internal drum, external drum, and flat bad configurations.

Other photoexposure light sources usable by the present invention are mercury lamps (ultrahigh pressure, high pressure, medium pressure, low pressure), chemical lamps, carbon arc lamps, xenon lamps, metal halide lamps, various visible and ultraviolet laser lamps, fluorescent lamps, tungsten lamps, sunlight, and so forth.

The following available 350 nm to 450 nm laser light sources can be used.

Gas lasers: Ar ion laser (364 nm, 351 nm, 10 mW to 1 W), Kr ion laser (356 nm, 351 nm, 10 mW to 1 W), He—Cd laser (441 nm, 325 nm, 1 mW to 100 mW); solid state lasers: the combination of Nd:YAG (YVO₄) and SHG crystal×2 (355 nm, 5 mW to 1 W), the combination of Cr:LiSAF and SHG crystal (430 nm, 10 mW); semiconductor lasers: KNbO₃ ring resonator (430 nm, 30 mW), the combination of a waveguide-type wavelength converter and AlGaAs or InGaAs semiconductor (380 nm to 450 nm, 5 mW to 100 mW), the combination of a waveguide-type wavelength converter and AlGaInP or AlGaAs semiconductor (300 nm to 350 nm, 5 mW to 100 mW), AlGaInN (350 nm to 450 nm, 5 mW to 30 mW); other: pulse lasers such as the N₂ laser (337 nm, 0.1 to 10 mJ pulse), XeF (351 nm, 10 to 250 mJ pulse). Among the preceding, the AlGaInN semiconductor laser (commercial InGaN-type semiconductor laser, 400 to 410 nm, 5 to 30 mW) is particularly preferred based on its wavelength characteristics and cost.

The scanning photoexposure-type lithographic printing plate photoexposure device can employ an internal drum configuration, external drum configuration, or flat bed configuration for its photoexposure mechanism, and, among the light sources cited above, the use of a continuous-oscillation light source is preferred. At a practical level, the following photoexposure devices are particularly preferred in view of the relationship between the platemaking time and the sensitivity of the sensitive material.
an internal drum-type single-beam to triple-beam photoexposure device that uses one or more semiconductor, gas, or solid state laser light sources to provide a total output of at least 20 mW
a flat bed-type multibeam (1 to 10 beams) photoexposure device that uses one or more semiconductor, gas, or solid state lasers to provide a total output of at least 20 mW
an external drum-type multibeam (1 to 9 beams) photoexposure device that uses one or more semiconductor, gas, or solid state lasers to provide a total output of at least 20 mW
an external drum-type multibeam (at least 10 beams) photoexposure device that uses one or more semiconductor or solid state lasers to provide a total output of at least 20 mW

For a laser direct-write lithographic printing plate as described above, equation 1 generally obtains for the sensitivity X (J/cm²) of the sensitive material, the area S (cm²) over which the sensitive material is photoexposed, the power q (W) of a single laser light source, the number n of lasers, and the total photoexposure time t (s).

X·S=n·q·t equation 1

### i) Analysis for an Internal Drum (Single Beam) Configuration

Equation 2 generally obtains for the laser rotation rate f (radian/s), the subscan length Lx (cm) of the sensitive material, the resolution Z (dot/cm), and the total photoexposure time t (s).

f·Z·t=Lx equation 2

### ii) Analysis for an External Drum (Multibeam) Configuration

Equation 3 generally obtains for the drum rotation rate F (radian/s), the subscan length Lx (cm) of the sensitive material, the resolution Z (dot/cm), the total photoexposure time t (s), and the number of beams n.

F·Z·n·t=Lx equation 3

iii) Analysis for a Flat Bed (Multibeam) Configuration

Equation 4 generally obtains for the polygonal mirror rotation rate H (radian/s), the subscan length Lx (cm) of the sensitive material, the resolution Z (dot/cm), the total photoexposure time t (s), and the number of beams n.

H·Z·n·t=Lx equation 4

By substituting the photoexposure conditions actually required of printing plates (resolution=2560 dpi, plate size=A1/B1, 42 inch subscan length, approximately 20 plates per hour) and the photosensitivity characteristics of the lithographic printing plate precursor of the present invention (photosensitive wavelength, sensitivity=approximately 0.1 mJ/cm²) into the preceding equations, the conclusion can be drawn that the lithographic printing plate precursor of the present invention is particularly preferably combined with a multibeam photoexposure configuration that uses a total laser output of at least 20 mW. Upon factoring in, for example, the operability and costs, the combination with an external drum-type semiconductor laser multibeam (at least 10) photoexposure device is the most preferred.

### (1) Lithographic Printing Using On-Press Development

Printing can be carried out in the lithographic printing method of the present invention by subjecting the lithographic printing plate precursor of the present invention to imagewise photoexposure with an infrared laser as described above and by subsequently supplying, without going through any development process step, an oil-based ink and a water-based component.

In specific terms, for example, a method can be used in which the lithographic printing plate precursor is photoexposed with an infrared laser followed by mounting on the press, without going through any development process step, and printing, or a method can be used in which the lithographic printing plate precursor is mounted on the press followed by photoexposure with an infrared laser on the press and printing.

When, for the case of an on-press-developable lithographic printing plate precursor, the lithographic printing plate precursor is imagewise photoexposed with an infrared laser followed -without going through a development process step such as a wet development process step - by printing in which a water-based component and oil-based ink are supplied, the photoexposure-cured photopolymerizable layer in the photoexposed areas of the photopolymerizable layer forms an oil-based ink receptive region that has an oleophilic surface. In the unexposed areas, on the other hand, the uncured photopolymerizable layer is removed by dissolution or dispersion by the supplied water-based component and/or oil-based ink and the hydrophilic surface is exposed in these areas. As a result, the water-based component attaches to the exposed hydrophilic surface, the oil-based ink is taken up by the photopolymerizable layer in the photoexposed regions, and printing is initiated.

Here, either the water-based component or the oil-based ink may be supplied to the plate surface at the very first; however, for the on-press-developable lithographic printing plate precursor of the present invention, the water-based component is preferably supplied at the outset in order to carry out on-press development rapidly. The fountain solution and printing ink typically employed for lithographic printing are used as the water-based component and oil-based ink.

Even in those instances where a UV ink is employed, the use of the lithographic printing plate precursor of the present invention makes it possible to carry out on-press development and subsequent printing according to the same lithographic printing methods described above and to obtain an excellent printing durability. The usual commercially available inks can be used as the UV ink.

Proceeding in the described manner, the lithographic printing plate precursor undergoes on-press development on the offset press and is used as such for long-run printing.

(2) Lithographic Printing Using Development with an Aqueous Solution that Contains Water-Soluble Resin

After the lithographic printing plate precursor has been imagewise photoexposed with a laser, the nonimage areas in the photopolymerizable layer may be removed using an aqueous solution that contains water-soluble resin. The lithographic printing plate precursor is then used for printing. The presence of this hydrophilic resin makes it possible to protect the hydrophilic support that has been exposed by removal of the nonimage areas and to protect the image areas.

An aqueous solution of gum arabic, which has a strong desensitizing action and an excellent scum dispersing performance, is preferably used for the water-soluble resin-containing aqueous solution. The gum arabic content in the aqueous solution is preferably 0.1 to 20 mass % and more preferably 0.5 to 10 mass %. Various water-soluble resins other than gum arabic can also be used as the desensitizer. Preferred examples in this regard are dextrin, sterabic, stractan, alginate salts, polyacrylate salts, hydroxyethyl cellulose, polyvinylpyrrolidone, polyacrylamide, methyl cellulose, hydroxypropyl cellulose, hydroxymethyl cellulose, carboxyalkyl cellulose salts, and the water-soluble polysaccharides extracted from soy bean curd lees. Pullulan, pullulan derivatives, and polyvinyl alcohol are also preferred.

The following are preferred modified starch derivatives: roasted starches such as British gum; enzyme-modified dextrins such as enzymatically produced dextrin and Schardinger dextrin; oxidized starches represented by solubilized starch; pregelatinized starches such as modified pregelatinized starch and unmodified pregelatinized starch; esterified starches such as starch phosphate, fatty starch esters, starch sulfate, starch nitrate, starch xanthate, and starch carbamate; etherized starches such as carboxyalkyl starch, hydroxyalkyl starch, sulfoalkyl starch, cyanoethyl starch, allyl starch, benzyl starch, carbamylethyl starch, and dialkylamino starch; crosslinked starches such as methylol-crosslinked starch, hydroxyalkyl-crosslinked starch, phosphate-crosslinked starch, and dicarboxylic acid-crosslinked starch; and graft polymerized starches such as starch/polyacrylamide copolymers, starch/polyacrylic acid copolymers, starch/polyvinyl acetate copolymers, starch/polyacrylonitrile copolymers, cationic starch/polyacrylate ester copolymers, cationic starch/vinyl polymer copolymers, starch/polystyrene/maleic acid copolymers, starch/polyethylene oxide copolymers, and starch/polypropylene copolymers.

The following are preferred natural polymer compounds: starches as sweet potato starch, potato starch, tapioca starch, wheat starch, and corn starch; natural polymer compounds obtained from seaweed, such as carrageenan, laminaran, mannan derived from seaweed, funori, Irish moss, agar, and sodium alginate; plant mucilages such as tororoaoi mucilage, mannan, quince seed mucilage, pectin, tragacanth gum, karaya gum, xanthine gum, guar bean gum, locust bean gum, carob gum, and benzoin gum; microbial mucilages such as homopolysaccharides, e.g., dextran, glucan, and levan, and heteropolysaccharides, e.g., succinoglucan and xanthan gum; and proteins such as glue, gelatin, casein, and collagen.

Two or more of these water-soluble resins may be used in combination, and these water-soluble resins are present in the aforementioned aqueous solution preferably in the range of 1 to 50 mass % and more preferably in the range of 3 to 30 mass %.

In addition to the water-soluble resin as described above, the water-soluble resin-containing aqueous solution used by the present invention may contain a pH adjuster, pH buffer, surfactant, antiseptic, antimold, oleophilic substance, wetting agent, chelating agent, defoamer, and so forth.

The water-soluble resin-containing aqueous solution is advantageously used in the pH range of 3 to 12. A pH adjuster is generally added for this reason. In order to bring the pH to 3 to 12, adjustment is generally carried out by adding a mineral acid, organic acid, or inorganic salt to the aqueous solution under consideration. The quantity of addition is 0.01 to 2 mass %. The mineral acid can be exemplified by nitric acid, sulfuric acid, phosphoric acid, metaphosphoric acid, and so forth. The organic acid can be exemplified by acetic acid, oxalic acid, malonic acid, p-toluenesulfonic acid, levulinic acid, phytic acid, organophosphonic acids, and amino acids such as glycine, α-alanine, and β-alanine. The inorganic salt can be exemplified by magnesium nitrate, primary sodium phosphate, secondary sodium phosphate, nickel sulfate, sodium hexametaphosphate, sodium tripolyphosphate, and so forth. At least one mineral acid, organic acid, or inorganic salt can be used or two or more may be used in combination.

A base may also be used as necessary to adjust the pH, for example, sodium hydroxide, potassium hydroxide, lithium hydroxide, sodium carbonate, potassium carbonate, ammonium carbonate, and so forth. Combinations of these bases may also be used.

The water-soluble resin-containing aqueous solution used in the present invention (also referred to in the following as the gum developing solution) is particularly preferably used in the pH range of 8.5 to 10.8.

A pH buffer is therefore desirably present in the gum developing solution. This pH buffer is a basic buffer and can be, for example, (a) carbonate ion and bicarbonate ion, (b) borate ion, (c) a water-soluble amine compound and the ion of this amine compound, or a combination of the preceding. Thus, for example, the (a) carbonate ion-bicarbonate ion combination, the (b) borate ion, or the (c) water-soluble amine compound-ion thereof combination exhibits a pH-buffering action in the developing solution and can inhibit pH changes even during long-term use of the developing solution and thus can prevent the decline in developing performance due to pH changes and can prevent the production of development scum. The use of the carbonate ion-bicarbonate ion combination is particularly preferred.

In order to bring about the presence of the (a) carbonate ion and bicarbonate ion in the gum developing solution, a carbonate salt and a bicarbonate salt may be added to the developing solution or a carbonate salt or a bicarbonate salt may be added and the carbonate ion and bicarbonate ion may then be generated by adjusting the pH. While there are no particular limitations on the carbonate salt and bicarbonate salt, the use of an alkali metal salt is preferred. The alkali metal can be, for example, lithium, sodium, or potassium, wherein sodium is particularly preferred. A single alkali metal salt may be used or two or more may be used in combination.

In order to bring about the presence of the (b) borate ion in the gum developing solution, boric acid or a borate salt is added to the gum developing solution followed by adjustment of the pH using base or acid and base to produce the desired borate ion.

There are no particular limitations on the boric acid and borate salt used here; the boric acid can be exemplified by orthoboric acid, metaboric acid, and tetraboric acid, wherein orthoboric acid and tetraboric acid are preferred thereamong. The borate salt can be exemplified by alkali metal salts and alkaline-earth metal salts and by the orthoborate salts, diborate salts, metaborate salts, tetraborate salts, pentaborate salts, hexaborate salts, and so forth, whereamong the orthoborate salts and tetraborate salts are preferred and the alkali metal salts of tetraboric acid are particularly preferred. Preferred tetraborate salts are sodium tetraborate, potassium tetraborate, and lithium tetraborate, whereamong sodium tetraborate is preferred. Two or more of these borate salts may be used in combination.

The boric acid or borate salt used in the present invention is particularly preferably orthoboric acid or tetraboric acid or sodium tetraborate. A boric acid and a borate salt may be used in combination in the developing solution.

The (c) ion of a water-soluble amine compound can be produced in an aqueous solution of the water-soluble amine compound: acid or base can be added to an aqueous solution of the water-soluble amine compound or a compound that is already the salt of the amine compound can be added to provide the ion in aqueous solution.

There are no particular limitations on the water-soluble amine compound, but a water-soluble amine compound that has a group that promotes water solubility is preferred. Groups that promote water solubility can be exemplified by the carboxylic acid group, sulfonic acid group, sulfinic acid group, phosphonic acid group, and the hydroxyl group. A plurality of these groups may be combined in the water-soluble amine compound.

The promotion of the water solubility of the amine compound by the carboxylic acid group, sulfonic acid group, sulfinic acid group, or phosphonic acid group corresponds to the use of an amino acid. Amino acids participate in an equilibrium in aqueous solution; this equilibrium is as shown below for the example of the use of the carboxylic acid group as the acid group. For the purposes of the present invention, the amino acid refers to state B while the amino acid ion refers to state C. The counterion in state C is preferably the sodium ion or the potassium ion.

### [The Amino Acid Equilibrium (Acid Group=Carboxyl Group)]

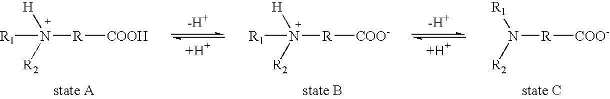

(For example, R₁ and R₂ each independently represent the hydrogen atom, alkyl, or aryl and R represents a linking group.)

The following are specific examples of water-soluble amine compounds that contain the carboxylic acid group, sulfonic acid group, or sulfinic acid group: amino acids such as glycine, iminodiacetic acid, lysine, threonine, serine, aspartic acid, para-hydroxyphenylglycine, dihydroxyethylglycine, alanine, anthranilic acid, tryptophan, and so forth; sulfamic acid; cyclohexylsulfamic acid; aliphatic amine sulfonic acids such as taurine and so forth; and aliphatic amine sulfinic acids such as aminoethanesullinic acid and so forth. Glycine and iminodiacetic acid are preferred among the preceding.

The following are specific examples of water-soluble amine compounds that contain the phosphonic acid group (also including the phosphinic acid group): 2-aminoethylphosphonic acid, 1-aminoethane-1,1-diphosphonic acid, 1-amino-1-phenylmethane-1,1-diphosphonic acid, 1-dimethylaminoethane-1,1-diphosphonic acid, ethylenediaminopentamethylenephosphonic acid, and so forth. 2-aminoethylphosphonic acid is particularly preferred.

The water-soluble amine compound that contains the hydroxyl group as the group promoting water solubility refers to an alkylamine that has the hydroxyl group in the alkyl moiety (state B below), while the corresponding ion refers to the ammonium ion originating from the amino group (state A below).

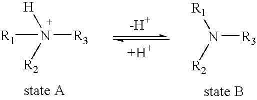

(For example, R₁, R₂, and R₃ each independently represent the hydrogen atom, alkyl, or aryl wherein at least one of these is hydroxyl-containing alkyl.)

Specific examples of hydroxyl-functional water-soluble amine compounds are monoethanolamine, diethanolamine, trimethanolamine, triethanolamine, tripropanolamine, triisopropanolamine, and so forth. Triethanolamine and diethanolamine are preferred among the preceding. The counterion for the ammonium ion is the chlorine ion.

Bases that can be used to adjust the pH as described above can be exemplified by sodium hydroxide, potassium hydroxide, lithium hydroxide, sodium carbonate, potassium carbonate, ammonium carbonate, sodium bicarbonate, potassium bicarbonate, ammonium bicarbonate, organic bases, and combinations of the preceding. Inorganic acids can be used as the acid, for example, hydrochloric acid, sulfuric acid, nitric acid, and so forth. Fine adjustments in the pH can be made by the addition of this base or acid.

By using the gum developing solution used by the present invention in the range of pH 8.5 to 10.8, the pH of at least 8.5 makes it possible to obtain good developability in the nonimage areas, while the pH no greater than 10.8 provides a resistance to the influence of atmospheric carbon dioxide and can inhibit the decline in processing performance caused by the influence of carbon dioxide. Thus, the gum developing solution preferably has a pH in the cited range due to the resulting resistance to a reduction in the developability of the nonimage areas and due to the absence of variations in the processing performance caused by the influence of atmospheric carbon dioxide. The range of pH 9.0 to 10.5 is more preferred and the range of pH 9.5 to 10.3 is particularly preferred.

For the use of the (a) carbonate ion and bicarbonate ion combination as the pH buffer, the total quantity of the carbonate ion and bicarbonate ion is preferably 0.05 to 5 mol/L, more preferably 0.1 to 2 mol/L, and particularly preferably 0.2 to 1 mol/L, in each case with reference to the total mass of the aqueous solution. The developability and processing performance do not decline when this total quantity is at least 0.05 mol/L. The use of 5 mol/L or less inhibits the production of precipitate and crystals and inhibits gelation during neutralization during treatment of the waste effluent from the developing solution, thus avoiding problems with waste effluent treatment.

A base, for example, an organic base, may also be used on an auxiliary basis with the goal of assisting very fine adjustments in the base concentration and assisting dissolution of the photosensitive layer in the nonimage areas. This organic base can be exemplified by monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisoprop anolamine, ethyleneimine, ethylenediamine, pyridine, tetramethylammonium hydroxide, and so forth. A single such base may be used or two or more may be used in combination.

For the use of the (b) borate ion as the pH buffer, the total quantity of the borate ion is preferably 0.05 to 5 mol/L, more preferably 0.1 to 2 mol/L, and particularly preferably 0.2 to 1 mol/L, in each case with reference to the total mass of the aqueous solution. The developability and processing performance do not decline when the total quantity of borate salt is at least 0.05 mol/L. The use of 5 mol/L or less inhibits the production of precipitate and crystals and inhibits gelation during neutralization during treatment of the waste effluent from the gum developing solution, thus avoiding problems with waste effluent treatment.

For the use of the (c) water-soluble amine compound and ion of the amine compound as the pH buffer, the total quantity of the water-soluble amine compound and ion of the amine compound is preferably 0.01 to 1 mol/L with reference to the total mass of the aqueous solution. When the total quantity is in this range, the developability and processing performance do not decline while the waste effluent is easily treated. The range of 0.03 to 0.7 mol/L is more preferred, while the range of 0.05 to 0.5 mol/L is particularly preferred The surfactant in the water-soluble resin-containing aqueous solution can be an anionic surfactant, cationic surfactant, amphoteric surfactant, or nonionic surfactant. The anionic surfactant can be exemplified by fatty acid salts, abietic acid salts, hydroxyalkanesulfonic acid salts, alkanesulfonic acid salts, α-olefinsulfonic acid salts, dialkyl sulfosuccinate salts, alkyldiphenyl ether disulfonic acid salts, straight-chain alkylbenzenesulfonic acid salts, branched alkylbenzenesulfonic acid salts, alkylnaphthalenesulfonic acid salts, alkylphenoxy polyoxyethylenepropylsulfonic acid salts, polyoxyethylene alkylsulfophenyl ether salts, sodium N-methyl-N-oleyltaurate, N-alkylsulfosuccinic acid monoamide disodium salts, petroleum sulfonic acid salts, sulfated castor oil, sulfated beef tallow oil, salts of sulfate esters of alkyl esters of fatty acids, salts of alkyl sulfates, salts of sulfate esters of polyoxyethylene alkyl ethers, salts of sulfate esters of fatty acid monoglycerides, salts of sulfate esters of polyoxyethylene alkylphenyl ethers, salts of sulfate esters of polyoxyethylene styrylphenyl ethers, alkyl phosphate ester salts, salts of phosphate esters of polyoxyethylene alkyl ethers, salts of phosphate esters of polyoxyethylene alkylphenyl ethers, partially saponified styrene/maleic anhydride copolymers, partially saponified olefin/maleic anhydride copolymers, and naphthalenesulfonate/formalin condensates. The use is particularly preferred among the preceding of dialkyl sulfosuccinate salts, salts of alkyl sulfates, alkylnaphthalenesulfonic acid salts, a-olefinsulfonic acid salts, and alkyldiphenyl ether disulfonic acid salts.

Alkylamine salts, quaternary ammonium salts, and so forth, can be used as the cationic surfactant.

Alkylcarboxybetaines, alkylimidazolines, alkylaminocarboxylic acids, and so forth, can be used as the amphoteric surfactant.

The nonionic surfactant can be exemplified by polyoxyethylene alkyl ethers, polyoxyethylene alkylphenyl ethers, polyoxyethylene polystyrylphenyl ethers, polyoxyethylene-polyoxypropylene alkyl ethers, glycerol/fatty acid partial esters, sorbitan/fatty acid partial esters, pentaerythritol/fatty acid partial esters, propylene glycol/fatty acid monoesters, sucrose/fatty acid partial esters, polyoxyethylene sorbitan/fatty acid partial esters, polyoxyethylene sorbitol/fatty acid partial esters, polyethylene glycol/fatty acid esters, polyglycerol/fatty acid partial esters, polyoxyethylenated castor oil, polyoxyethylene glycerol/fatty acid partial esters, fatty acid diethanolamides, N,N-bis-2-hydroxyalkylamines, polyoxyethylene alkylamines, triethanolaminelfatty acid esters, trialkylamine oxides, polypropylene glycol with a molecular weight of 200 to 5000, polyoxyethylene or polyoxypropylene adducts on trimethylolpropane or glycerol or sorbitol, acetylene glycol, and so forth. Fluorine-type and silicon-type nonionic surfactants can also be similarly used.

Two or more of these surfactants can be used in combination. There are no particular limitations on the quantity of use; however, with regard to the preferred range, 0.01 to 20 mass % based on the total mass of the water-soluble resin-containing aqueous solution is suitable while 0.05 to 10 mass % based on the total mass of the water-soluble resin-containing aqueous solution is preferred.

The preservative can be the known substances used in the textile, wood processing, food, drug, cosmetic, and agrochemical sectors. The known preservatives can be used, for example, quaternary ammonium salts, monohydric phenol derivatives, dihydric phenol derivatives, polyhydric phenol derivatives, imidazole derivatives, pyrazolopyrimidine derivatives, monohydric naphthol, carbonates, sulfone derivatives, organotin compounds, cyclopentane derivatives, phenyl derivatives, phenol ether derivatives, phenol ester derivatives, hydroxylamine derivatives, nitrile derivatives, naphthalenes, pyrrole derivatives, quinoline derivatives, benzothiazole derivatives, secondary amines, 1,3,5-triazine derivatives, thiadiazole derivatives, anilide derivatives, halogen derivatives, dihydric alcohol derivatives, dithiol derivatives, cyanic acid derivatives, thiocarbamate derivatives, diamine derivatives, isothiazole derivatives, monohydric alcohols, saturated aldehydes, unsaturated monocarboxylic acids, saturated ethers, unsaturated ethers, lactones, amino acid derivatives, hydantoin, cyanuric acid derivatives, guanidine derivatives, pyridine derivatives, saturated monocarboxylic acids, benzenecarboxylic acid derivatives, hydroxycarboxylic acid derivatives, biphenyl, hydroxamic acid derivatives, aromatic alcohols, halogenophenol derivatives, mercaptocarboxylic acid derivatives, quaternary ammonium salt derivatives, triphenylmethane derivatives, hinokithiol, furan derivatives, benzofuran derivatives, acridine derivatives, isoquinoline derivatives, arsine derivatives, thiocarbamic acid derivatives, phosphate esters, halobenzene derivatives, quinone derivatives, benzenesulfonic acid derivatives, monoamine derivatives, organophosphate esters, piperazine derivatives, phenazine derivatives, pyrimidine derivatives, thiophanate derivatives, imidazoline derivatives, isoxazole derivatives, ammonium salt derivatives, and so forth. The following are particularly preferred preservatives: the salts of pyridinethiol-1-oxide, salicylic acid and its salts, 1,3,5-trishydroxyethylhexahydro-s-triazine, 1,3,5-trishydroxymethylhexahydro-s-triazine, 1,2-benzisothiazolin-3-one, 5-chloro-2-methyl-4-isothiazolin-3-one, and 2-bromo-2-nitro- 1,3-propanediol. The preferred quantity of addition is a quantity that provides a stable efficacy with respect to bacteria, mold, yeast, and so forth, and while this will vary with the species of bacteria, mold, or yeast, the range of 0.01 to 4 mass % with respect to the water-soluble resin-containing aqueous solution at the time of use is preferred. The combined use of two or more preservatives in order to be efficacious against various mold and bacteria is preferred.

An oleophilic substance may also be present in the water-soluble resin-containing aqueous solution. Preferred oleophilic substances include, for example, castor oil and C₅₋₂₅ organic carboxylic acids such as oleic acid, lanolic acid, valeric acid, nonanoic acid, caprylic acid, myristic acid, palmitic acid, and so forth. A single oleophilic substance can be used or two or more can be used in combination. The content of the oleophilic substance in the water-soluble resin-containing aqueous solution is in the range from 0.005 to 10 mass % and more preferably in the range from 0.05 to 5 mass %, in each case with respect to the total mass of the water-soluble resin-containing aqueous solution.

In addition, the wetting agent that can be added as necessary to the water-soluble resin-containing aqueous solution is, for example, glycerol, ethylene glycol, propylene glycol, triethylene glycol, butylene glycol, hexylene glycol, diethylene glycol, dipropylene glycol, trimethylolpropane, diglycerol, and so forth. A single one of these wetting agents may be used or two or more may be used in combination. The preferred quantity of use of these wetting agents is 0.1 to 5 mass %.

A chelating compound may also be added to the water-soluble resin-containing aqueous solution. The water-soluble resin-containing aqueous solutions are typically sold as concentrates, which are diluted at the time of use with, for example, tap water or well water, and then used. The calcium ion and so forth present in this tap water or well water used for dilution has a negative effect on printing and functions to facilitate scumming on the printed material; these problems can be dealt with by the addition of a chelating compound. Preferred chelating compounds are, for example, ethylenediaminetetraacetic acid and its potassium and sodium salts; diethylenetriaminepentaacetic and its potassium and sodium salts; triethylenetetraminehexaacetic acid and its potassium and sodium salts; hydroxyethylethylenediaminetriacetic acid and its potassium and sodium salts; nitrilotriacetic acid and its sodium salt; and organophosphonic acids and phosphonoalkanetricarboxylic acids, e.g., 1-hydroxyethane-1,1-diphosphonic acid and its potassium and sodium salts, aminotri(methylenephosphonic acid) and its potassium and sodium salts, and so forth. In addition to the sodium and potassium salts, the salts of these chelating agents with organic amines are also effective. A chelating agent is selected that is stable in the composition of the water-soluble resin-containing aqueous solution and that does not impair the printing characteristics. The quantity of addition is suitably 0.001 to 1.0 mass % with reference to the water-soluble resin-containing aqueous solution at the time of use.

A defoamer can also be added to the water-soluble resin-containing aqueous solution, and silicone defoamers are particularly preferred. Among these defoamers, either of an emulsion/dispersion type or a solubilizing type can be used. A range of 0.001 to 1.0 mass % with respect to the water-soluble resin-containing aqueous solution at the time of use is optimal.

Water is the component that balances out the water-soluble resin-containing aqueous solution under consideration. From a transportation standpoint, the water-soluble resin-containing aqueous solution advantageously is made as a concentrate having a smaller water content than at the time of use and is diluted with water at the time of use. The concentration in such cases is desirably a concentration that does not result in separation or precipitation of the components. The water-soluble resin-containing aqueous solution may be prepared as an emulsion/dispersion type wherein organic solvent is used as the oil phase thereof, and, using the assistance of a surfactant as described above, may be formulated as a solubilizing type (emulsion type).

The organic solvent preferably is an organic solvent that has a solubility in water at 20° C. of no more than 5 mass % and a boiling point of at least 160° C. A plasticizer with a solidification point no greater than 15° C. and a boiling point at 1 atmosphere of at least 300° C. is present, for example, a phthalate diester such as dibutyl phthalate, diheptyl phthalate, di-n-octyl phthalate, di(2-ethylhexyl) phthalate, dinonyl phthalate, didecyl phthalate, dilauryl phthalate, butyl benzyl phthalate, and so forth; esters of aliphatic dibasic acids, such as dioctyl adipate, butyl glycol adipate, dioctyl azelate, dibutyl sebacate, di(2-ethylhexyl) sebacate, dioctyl sebacate, and so forth; epoxidized triglycerides such as epoxidized soy oil and so forth; phosphate esters such as tricresyl phosphate, trioctyl phosphate, trischloroethyl phosphate, and so forth; and benzoate esters such as benzyl benzoate and so forth.

In addition, the alcohol system can be exemplified by 2-octanol, 2-ethylhexanol, nonanol, n-decanol, undecanol, n-dodecanol, trimethylnonyl alcohol, tetradecanol, benzyl alcohol, and so forth. The glycol system can be exemplified by ethylene glycol isoamyl ether, ethylene glycol monophenyl ether, ethylene glycol benzyl ether, ethylene glycol hexyl ether, octylene glycol, and so forth.

Odor is a particular consideration when selecting the preceding compounds. The preferred range for the quantity of use of these solvents is 0.1 to 5 mass % of the water-soluble resin-containing aqueous solution and the more preferred range is 0.5 to 3 mass % of the water-soluble resin-containing aqueous solution. A single solvent can be used or two or more can be used in combination.

The water-soluble resin-containing aqueous solution used by the present invention is produced by bringing the aqueous phase to a temperature of 40° C. ±5° C.; slowly dripping the prepared oil phase into the aqueous phase while stirring at high speed; and, after thorough stirring, carrying out emulsification and dispersion by passage through a pressure-type homogenizer.

In the present invention, removal of the nonimage areas of the photopolymerizable layer and desensitization are carried out at the same time in a development tank using the aforementioned water-soluble resin-containing aqueous solution, and this step can be followed as appropriate by a water rinse step and/or a subsequent additional step of desensitizing the nonimage areas using the water-soluble resin-containing aqueous solution.

The development process in the present invention using the water-soluble resin-containing aqueous solution can be suitably carried out using an automatic processor that is provided with a rubbing member and a means of supplying, inter alia, the aforementioned aqueous solution. An example of an automatic processor is the automatic processor described in Japanese Patent Application Publication No. 2006-235227, which after imaging carries out a rubbing process while transporting the lithographic printing plate precursor. A particularly preferred automatic processor in this sphere uses a rotating brush roll as the rubbing member.

A rotating brush roll preferred for use in the present invention can be selected as appropriate based on considerations of preventing damage to the image areas, the rigidity of the support in the lithographic printing plate precursor, and so forth. The rotating brush roll can be a known rotating brush roll in which brush elements are attached to a plastic or metal roll. Examples of usable rotating brush rolls are described in Japanese Patent Application Publication Nos. Sho 58-159533 and H3-100554 and in Japanese Examined Utility Model Publication No. S62-167253, which describes a brush roll in which a metal or plastic channel-shaped member having brush elements implanted therein in a row configuration is wound without gaps and in a radiating manner on a core comprising a plastic or metal roll. A plastic fiber (for example, a synthetic fiber of, for example, a polyester such as polyethylene terephthalate, polybutylene terephthalate, and so forth; a polyamide such as nylon 6,6, nylon 6,10, and so forth; a polyacrylic type such as polyacrylonitrile, poly(alkyl (meth)acrylate), and so forth; or a polyolefin such as polypropylene, polystyrene, and so forth) can be used as the brush element. For example, the diameter of the fiber bristle is suitably 20 to 400 μm and its length is suitably 5 to 30 mm.

The outer diameter of the rotating brush roll is preferably 30 to 200 mm and the peripheral velocity at the end of the brush that rubs the plate surface is preferably 0.1 to 5 m/sec.

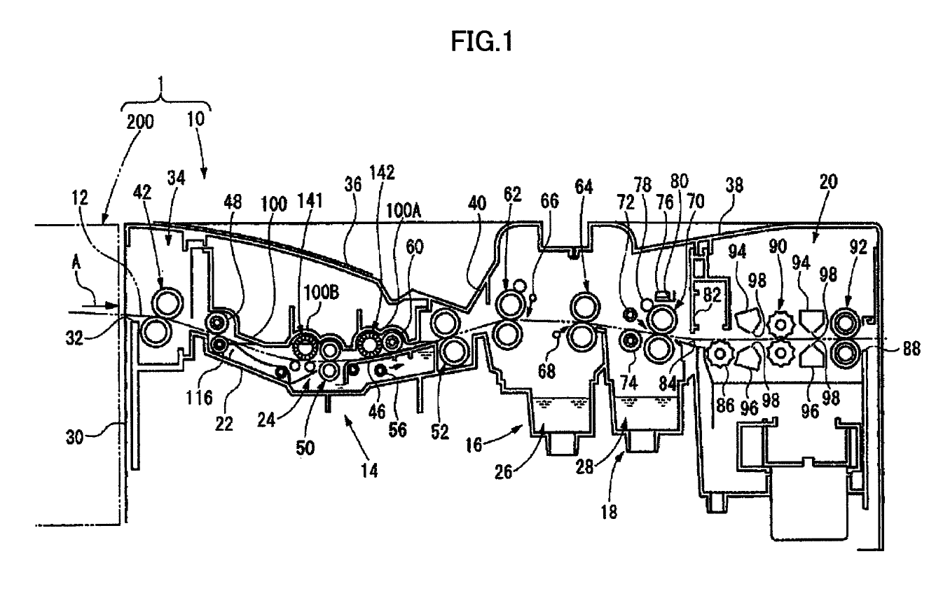

The direction of rotation of the rotating brush roll used in the present invention may be the same direction as the direction of transport of the lithographic printing plate precursor of the present invention or may be the direction opposite from the direction of transport of the lithographic printing plate precursor of the present invention. However, in a preferred embodiment for the use of at least two rotating brush rolls, as in the automatic developing apparatus shown as an example in FIG. 1, at least one rotating brush roll rotates in the same direction and at least one rotating brush roll rotates in the opposite direction. This serves to provide an even more secure and reliable removal of the image recording layer in the nonimage areas. Rocking the rotating brush roll along the axis of rotation of the brush roll is also effective.

In the present invention, execution of nonimage area removal and desensitization in the developing tank may be followed by a water rinse or an additional desensitization treatment.

In the present invention, the temperature of the aqueous solution used for development by the water-soluble resin-containing aqueous solution and the temperature of the rinse water in subsequent steps can be freely selected independently from one another, but are preferably 10° C. to 50° C.

A drying step may be provided at any point after development in the development method of the present invention that employs the water-soluble resin-containing aqueous solution. The drying step is generally carried out by the application of a dry air current with a freely selected temperature after most of the processing solution has been removed by the roller nip.

After development processing as described above by the water-soluble resin-containing aqueous solution, the plate is installed on an offset press; fountain solution and oil-based ink (for example, UV ink) are supplied; and high-quality long-run printing can be performed.

### EXAMPLES

The present invention is described in detail in the following using examples and comparative examples, but the present invention is not limited to these examples and comparative examples.

### Examples 1 to 5 and Comparative Examples 1 and 2

### 1. Fabrication of Lithographic Printing Plate Precursors

(1) Preparation of the Support

0.3 mm-thick aluminum sheet (quality: 1050) was subjected to a degreasing treatment with 10 mass % aqueous sodium aluminate solution at 50° C. for 30 seconds in order to remove the rolling oil on the surface. The aluminum surface was thereafter grained using three bundled nylon brushes (bristle diameter=0.3 mm) and an aqueous suspension of pumice (median diameter=25 μm, specific gravity of the suspension=1.1 g/cm³) and was then thoroughly washed with water. This sheet was immersed for 9 seconds in 25 mass % aqueous sodium hydroxide solution at 45° C. to carry out etching, washed with water, immersed in 20 mass % nitric acid at 60° C. for 20 seconds, and washed with water. The etching rate on the grained surface in this case was approximately 3 g/m².

A continuous electrochemical roughening treatment was then carried out using 60-Hz AC voltage. The electrolytic solution used for this treatment was a 1 mass % aqueous nitric acid solution (containing 0.5 mass % aluminum ion) and the bath temperature was 50° C. The AC power source waveform provided trapezoidal square wave alternating current with a TP (time required for the current value to go from zero to the peak) of 0.8 msec and a duty ratio of 1:1, and electrochemical roughening was carried out using a carbon electrode as the counterelectrode. Ferrite was used as an auxiliary anode. The current density was 30 A/dm² at the current peak value. 5% of the current flowing from the power source was branched to the auxiliary anode. The quantity of electricity in this nitric acid electrolysis was 175 C/dm² for the time in which the aluminum sheet was functioning as an anode. This treatment was followed by a water rinse by spraying.

An electrochemical roughening treatment was then carried out by the same method as for the nitric acid electrolysis, but using the following conditions: electrolytic solution=0.5 mass % aqueous hydrochloric acid solution (containing 0.5 mass % aluminum ion), bath temperature=50° C., quantity of electricity=50 C/dm² for the time in which the aluminum sheet was functioning as an anode. This was followed by a water rinse by spraying. A 2.5 g/m² direct-current anodic oxidation film was then disposed on this sheet using a current density of 15 A/dm² and using 15 mass % sulfuric acid (containing 0.5 mass % aluminum ion) as the electrolytic solution; this was followed by a water rinse and drying. This substrate was immersed for 7 seconds in a 2.5 mass % aqueous #3 sodium silicate solution held at 70° C. followed by a water rinse and drying. The center-line average surface roughness (Ra) of this substrate was measured at 0.51 μm using a needle with a diameter of 2 μm. The undercoat solution (1) described below was applied to give a dry coating rate of 18 mg/m², yielding the support.

-Undercoat solution (1)-

| | | |
|---|---|---|
| undercoat compound (1) | 0.051 | g |
| (mass-average molecular weight: 60,000) | | |
| methanol | 9.00 | g |
| water | 1.00 | g |

undercoat compound (1)

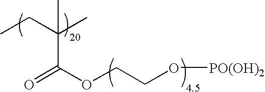

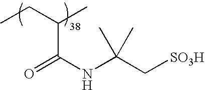

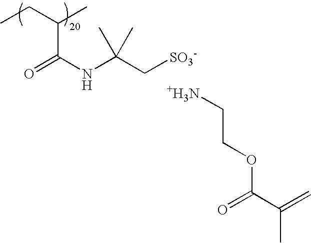

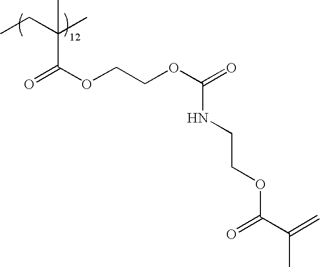

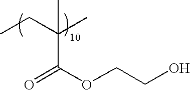

(2) Formation of the Photopolymerizable Layer and Protective Layer

A solution (the coating solution for formation of the photopolymerizable layer), prepared by dissolving the components in the compositions (unit: g) shown in Table 1 below in 12.00 g solvent (propylene glycol monomethyl ether/methyl ethyl ketone/methyl alcohol/water=55/20/15/10 (mass ratio)), was coated on the aforementioned support on which the undercoat layer had already been formed. Coating was carried out using a wire bar so as to provide a dry coating rate of 1.2 g/m². Drying at 120° C. for 40 seconds in an oven then gave the photopolymerizable layer.

A coating solution for protective layer formation with the composition given below was then coated on the aforementioned photopolymerizable layer; drying for 75 seconds at 125° C. in an oven resulted in the formation of a protective layer at a dry coating rate of 0.18 g/m², thus yielding the lithographic printing plate precursors of Examples 1 to 5 and the lithographic printing plate precursors of Comparative Examples 1 and 2.

The coating solution for photopolymerizable layer formation was obtained by mixing/stirring the photosensitive solution shown in Table 1 with microgel fluid (1), infra, immediately prior to coating. The exemplary compounds (9), (10), (11), (25), and (41) used here refer to the (1) to (60) designations of the previously cited specific examples of special polymer binders used by the present invention.

Comparative Example 1 used a polymethyl methacrylate (Mw=70,000) in place of the special polymer binder of the present invention, while Comparative Example 2 used the comparative special polymer (R-1) (Mw=70,000) with the structure shown below in place of the special polymer binder of the present invention.

TABLE 1

| | | | | | | comparative | |
|---|---|---|---|---|---|---|---|
| | examples | | | | | examples | |
| component | 1 | 2 | 3 | 4 | 5 | 1 | 2 |
| polymerizable monomer (NK Ester A- | 2.00 | 2.00 | 2.00 | 2.00 | 2.00 | 2.00 | 2.00 |
| 9300, Shin-Nakamura Chemical Co., | | | | | | | |
| Ltd.) | | | | | | | |
| microgel dispersion (1) | 16.51 | 16.51 | 16.51 | 16.51 | 16.51 | 16.51 | 16.51 |
| infrared absorber (1) | 0.28 | 0.28 | 0.28 | 0.28 | 0.28 | 0.28 | 0.28 |
| polymerization initiator (1) | 1.77 | 1.77 | 1.77 | 1.77 | 1.77 | 1.77 | 1.77 |
| phosphonium compound (1) | 0.55 | 0.55 | 0.55 | 0.55 | 0.55 | 0.55 | 0.55 |
| 2-hydroxyethyl isocyanurate | 0.64 | 0.64 | 0.64 | 0.64 | 0.64 | 0.64 | 0.64 |
| fluorosurfactant (1), | 0.04 | 0.04 | 0.04 | 0.04 | 0.04 | 0.04 | 0.04 |
| 10 mass % aqueous solution | | | | | | | |
| anionic surfactant (Paionin A-24-EA, | 0.125 | 0.125 | 0.125 | 0.125 | 0.125 | 0.125 | 0.125 |
| Takemoto Oil & Fat Co., Ltd., | | | | | | | |
| 40 mass % aqueous solution) | | | | | | | |
| polymethyl methacrylate | — | — | — | — | — | 0.254 | — |
| (Mw = 70,000) | | | | | | | |
| comparative special polymer | — | — | — | — | — | — | 0.254 |
| (R-1) (Mw = 70,000) | | | | | | | |
| exemplary compound (9) | 0.254 | — | — | — | — | — | — |
| (Mw = 50,000) | | | | | | | |
| exemplary compound (10) | — | 0.254 | — | — | — | — | |
| (Mw = 50,000) | | | | | | | |
| exemplary compound (11) | — | — | 0.254 | — | — | — | — |
| (Mw = 50,000) | | | | | | | |
| exemplary compound (25) | — | — | — | 0.254 | — | — | — |
| (Mw = 60,000) | | | | | | | |
| exemplary compound (41) | — | — | — | — | 0.254 | — | — |
| (Mw = 70,000) | | | | | | | |

### —Synthesis of Microgel Dispersion (1)—

8.4 g trimethylolpropane/xylylene diisocyanate adduct (Takenate D-110N from Mitsui Takeda Chemicals Inc., 75 mass % ethyl acetate solution), 3.15 g of the 1:1 (mass ratio) adduct (50 mass % ethyl acetate solution) between Takenate D-1110N and Uniox M-4000 (NOF Corporation), 6.30 g SR399E (Sartomer Company, Inc.) as polymerizable monomer, and 0.19 g Paionin A-41-C (Takemoto Oil & Fat Co., Ltd.) were dissolved in 16.39 g ethyl acetate as the oil phase component. This oil phase component and 39.4 g distilled water were mixed and were emulsified for 10 minutes at 12,000 rpm using a homogenizer. The resulting emulsion was added to 24 g distilled water and this was stirred for 4 hours at 40° C. The resulting microgel dispersion was diluted with distilled water to bring the solids fraction concentration thereof to 21 mass %, thus yielding microgel dispersion (1). The average particle size was 0.23 μm.

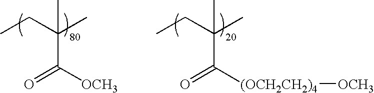

comparative special polymer (R-1)

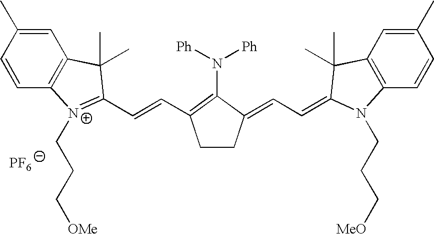

infrared absorber (1)

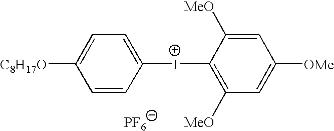

polimerization initiator (1)

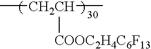

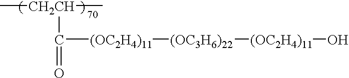

fluorosurfactant (1)

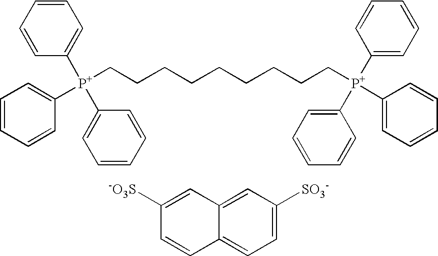

phosphoium compound (1)
Coating solution for forming the protective layer

| | | |
|---|---|---|
| inorganic layer compound dispersion (1), | 1.50 | g |
| see below | | |
| polyvinyl alcohol | 0.01 | g |
| (PVA405, Kuraray Co., Ltd., degree of | | |
| saponification = 81.5 mol %) | | |
| polyvinyl alcohol | 0.03 | g |
| (CKS-50, Nippon Synthetic Chemical | | |
| Industry Co., Ltd., degree of saponification = | | |
| 99 mol %, anion modified) | | |
| surfactant | 0.01 | g |
| (Emalex 710, Nihon Emulsion Co., Ltd.) | | |
| silica filler | 0.05 | g |
| (MP-1040, Nissan Chemical Industries, Ltd.) | | |
| water | 3.51 | g |

### —Preparation of the Inorganic Layer Compound Dispersion (1)—

6.4 g of the synthetic mica Somashif ME-100 (Co-op Chemical Co., Ltd.) was added to 193.6 g ion-exchanged water, and dispersion was carried out using a homogenizer until the average particle size reached 3 μm (laser scattering method). The aspect ratio of the resulting dispersed layer compound particles was at least 100.

### Examples 6 to 10 and Comparative Example 3

### 1. Fabrication of Lithographic Printing Plate Precursors

A solution (the coating solution for formation of the photopolymerizable layer), prepared by dissolving the components in the compositions (unit: g) shown in Table 2 below in 500 g solvent (n-propanol/water/2-butanone=76/20/4 (mass ratio)), was coated on an aluminum substrate prepared as described for Examples 1 to 5. Coating was carried out using a wire bar so as to provide a dry coating rate of 1.5 g/m², and drying was carried out at 100° C. for 90 seconds.

TABLE 2

| | | | | | | comparative |
|---|---|---|---|---|---|---|
| | examples | | | | | example |
| component | 6 | 7 | 8 | 9 | 10 | 3 |
| urethane acrylate (see | 30.00 | 30.00 | 30.00 | 30.00 | 30.00 | 30.00 |
| note 1) | | | | | | |
| dispersion of particles | 46.25 | 46.25 | 46.25 | 46.25 | 46.25 | 46.25 |
| of acrylonitrile- | | | | | | |
| containing copolymer | | | | | | |
| (see note 2) | | | | | | |
| Sartomer SR399E | 4.90 | 4.90 | 4.90 | 4.90 | 4.90 | 4.90 |
| (see note 3) | | | | | | |
| polymethyl | — | — | — | — | — | 10.00 |
| methacrylate | | | | | | |
| (Mw = 70,000) | | | | | | |
| hydroxypropyl | 1.00 | 1.00 | 1.00 | 1.00 | 1.00 | 1.00 |
| cellulose (see note 4) | | | | | | |
| Irgacure 250 | 4.69 | 4.69 | 4.69 | 4.69 | 4.69 | 4.69 |
| (see note 5) | | | | | | |
| mercapto-3-triazole | 2.73 | 2.73 | 2.73 | 2.73 | 2.73 | 2.73 |
| (see note 6) | | | | | | |
| BYK336 (see note 7) | 2.23 | 2.23 | 2.23 | 2.23 | 2.23 | 2.23 |
| infrared absorber, | 1.96 | 1.96 | 1.96 | 1.96 | 1.96 | 1.96 |
| see (8) below | | | | | | |
| exemplary compound | 10.00 | — | — | — | — | — |
| (9) (Mw = 50,000) | | | | | | |
| exemplary compound | — | 10.00 | — | — | — | — |
| (10) (Mw = 50,000) | | | | | | |
| exemplary compound | | | | | | |
| (11) (Mw = 50,000) | — | — | 10.00 | — | — | — |
| exemplary compound | — | — | — | 10.00 | — | — |
| (25) (Mw = 60,000) | | | | | | |
| exemplary compound | — | — | — | — | 10.00 | — |
| (41) (Mw = 70,000) | | | | | | |

note 1.
Polymerizable compound obtained by the reaction of hydroxyethyl acrylate and
pentaerythritol triacrylate with DESMODUR N100 (hexamethylene diisocyanate-containing
aliphatic polyisocyanate resin from Bayer). 80 mass % solution in 2-butanone
note 2.
21 mass % dispersion in n-propanol/water (80/20) mixed solvent of polyethylene
glycol methyl ether methacrylate/styrene/acrylonitrile (10/20/70) copolymer
note 3.
ditrimethylolpropane tetraacrylate (Sartomer Company, Inc.)
note 4.
2 mass % aqueous solution
note 5.
75 mass % solution of iodonium (4-methoxyphenyl[4-(2-
methylpropyl)phenyl]hexafluorophosphoric acid)
in propylene carbonate (Ciba Specialty Chemical Corp.)
note 6.
mercapto-3-triazole-1H,2,4, available from PCAS (France)
note 7.
25 mass % solution of modified dimethylpolysiloxane copolymer
in xylene/methoxypropyl acetate solution (BYK Chemie)
infrared absorber (8)

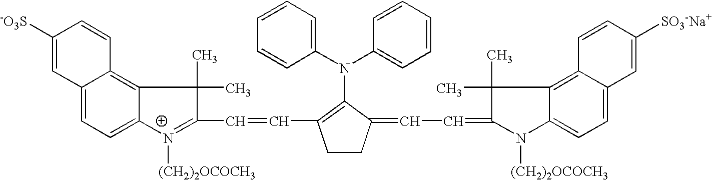

2. Photoexposure of Printing with and Evaluation of the Lithographic Printing Plate Precursors

The lithographic printing plate precursors obtained in the previously described examples and comparative examples were subjected to photoexposure using a Trendsetter 3244 VX (Creo) equipped with a water-cooled 40 W infrared semiconductor laser. The following conditions were used: output=9 W, external drum rotation rate=210 rpm, resolution=2400 dpi. A fine line chart was included in the photoexposed image.

In general with negative-working lithographic printing plate precursors, lower photoexposure levels result in a lower degree of cure in the photosensitive layer (the photopolymerizable layer in the present invention) while higher photoexposure levels result in a higher degree of cure. When the degree of cure of the photopolymerizable layer is too low, the printing durability by the lithographic printing plate declines and the reproducibility (small dots, fine lines) becomes unsatisfactory. High degrees of cure for the photopolymerizable layer, on the other hand, provide a high printing durability and an excellent reproducibility (small dots, fine lines).

In these examples, the printing durability and fine line reproducibility of the negative-working lithographic printing plate precursors prepared as described above were evaluated using the same photoexposure level, supra, and these evaluations were used as an indicator of the sensitivity of the lithographic printing plate precursor. Thus, a higher number of impressions for the printing durability and a finer fine line width in the fine line reproducibility can be said to indicate a higher sensitivity for the lithographic printing plate precursor.

(1) On-Press Developability

On-press development was carried out as follows using the following printing inks: (i) ordinary ink (TRANS-G(N) black ink (Dainippon Ink and Chemicals, Incorporated)) and (ii) UV ink (Best Cure UV-BF-WRO standard black ink (T & K TOKA Co., Ltd.)).

The resulting photoexposed precursor was installed, without a development process, on the cylinder of a Dia IF-2 press from Mitsubishi Heavy Industries, Ltd.; fountain solution (EU-3 etching solution from Fujifilm Corporation/water/isopropyl alcohol=1/89/10 (volume ratio)) and a printing ink as described above were supplied; and printing was then carried out at a printing rate of 6,000 impressions per hour. At this point, the number of sheets of printing paper required until there was no ink transfer to the unexposed areas (nonimage areas) of the photopolymerizable layer was evaluated as the on-press developability. A smaller number of impressions is regarded as a better on-press developability. The results of the evaluation are shown in Table 3.

(2) Fine Line Reproducibility

After printing 100 impressions as described above and confirming that prints free of ink scumming in the nonimage areas were being obtained, 500 impressions were then printed. The fine line chart (the chart contained 10, 12, 14, 16, 18, 20, 25, 30, 35, 40, 60, 80, 100, and 200 μm fine line images and nonimage areas present in alternation at the same width) on the six-hundredth (total) print was inspected with a 25× loupe, and the fine line reproducibility was evaluated based on the fine line width that was reproduced without gaps. The results of the evaluation are shown in Table 3.

(3) On-Press Development Scum

After the completion of printing in the evaluation of fine line reproducibility as described above, the status of the adhesion of removal scum on the water form roll was evaluated at the same time. This was scored on the following scale.
+:no scum is seen on the water form roll
Δ:a small amount of scum is seen on the water form roll
×:a large amount of scum is seen on the water form roll

(4) Printing Durability

(i) Printing with Ordinary Ink

Printing was continued after carrying out the evaluation of on-press development scum. As the number of printed impressions grew, the ink receptivity declined due to gradual wear of the photopolymerizable layer, which resulted in a decline in the ink density on the printing paper. The printing durability was evaluated based on the number of impressions required for the ink density (reflection density) to decline 0.1 from the value at the start of printing. The results of the evaluation are shown in Table 3.

(ii) Printing with UV Ink

Printing was continued after carrying out the evaluation of on-press development scum. As the number of printed impressions grew, the ink receptivity declined due to gradual wear of the photopolymerizable layer, which resulted in a decline in the ink density on the printing paper. The printing durability was evaluated based on the number of impressions required for the ink density (reflection density) to decline 0.1 from the value at the start of printing. The results of the evaluation are shown in Table 3.

TABLE 3

| | | ordinary ink | | | |
|---|---|---|---|---|---|
| | | on-press | | | printing |
| | | developability | fine line | on-press | durability |
| | | (number of | reproducibility | development | (thousands |
| | special polymer binder | impressions) | (μm) | scum | of impressions) |
| Ex. 1 | exemplary compound | 20 | 10 | + | 50 |
| | (9) (Mw = 50,000) | | | | |
| Ex. 2 | exemplary compound | 16 | 10 | + | 50 |
| | (10) (Mw = 50,000) | | | | |
| Ex. 3 | exemplary compound | 18 | 10 | + | 50 |
| | (11) (Mw = 50,000) | | | | |
| Ex. 4 | exemplary compound | 20 | 10 | + | 50 |
| | (25) (Mw = 60,000) | | | | |
| Ex. 5 | exemplary compound | 20 | 10 | + | 60 |
| | (41) (Mw = 70,000) | | | | |
| Comp. | polymethyl | 20 | 10 | x | 50 |
| Ex. 1 | methacrylate | | | | |
| | (Mw = 70,000) | | | | |
| Comp. | comparative special | 20 | 10 | Δ | 50 |
| Ex. 2 | polymer | | | | |
| | (R-1) (Mw = 70,000) | | | | |
| Ex. 6 | exemplary compound | 40 | 30 | + | 25 |
| | (9) (Mw = 50,000) | | | | |
| Ex. 7 | exemplary compound | 32 | 30 | + | 25 |
| | (10) (Mw = 50,000) | | | | |
| Ex. 8 | exemplary compound | 35 | 30 | + | 25 |
| | (11) (Mw = 50,000) | | | | |
| Ex. 9 | exemplary compound | 40 | 30 | + | 25 |
| | (25) (Mw = 60,000) | | | | |
| Ex. 10 | exemplary compound | 38 | 30 | + | 30 |
| | (41) (Mw = 70,000) | | | | |
| Comp. | polymethyl | 40 | 30 | x | 25 |
| Ex. 3 | methacrylate | | | | |
| | (Mw = 70,000) | | | | |
| | | UV ink | | | |
| | | on-press | | | printing |
| | | developability | fine line | on-press | durability |
| | | (number of | reproducibility | development | (thousands |
| | special polymer binder | impressions) | (μm) | scum | of impressions) |
| Ex. 1 | exemplary compound | 25 | 12 | + | 20 |
| | (9) (Mw = 50,000) | | | | |
| Ex. 2 | exemplary compound | 20 | 12 | + | 15 |
| | (10) (Mw = 50,000) | | | | |
| Ex. 3 | exemplary compound | 23 | 12 | + | 18 |
| | (11) (Mw = 50,000) | | | | |
| Ex. 4 | exemplary compound | 30 | 12 | + | 25 |
| | (25) (Mw = 60,000) | | | | |
| Ex. 5 | exemplary compound | 25 | 12 | + | 27 |
| | (41) (Mw = 70,000) | | | | |
| Comp. | polymethyl | 30 | 30 | x | 8 |
| Ex. 1 | methacrylate | | | | |
| | (Mw = 70,000) | | | | |
| Comp. | comparative special | 25 | 25 | Δ | 8 |
| Ex. 2 | polymer | | | | |
| | (R-1) (Mw = 70,000) | | | | |
| Ex. 6 | exemplary compound | 45 | 35 | + | 15 |
| | (9) (Mw = 50,000) | | | | |
| Ex. 7 | exemplary compound | 38 | 35 | + | 10 |
| | (10) (Mw = 50,000) | | | | |
| Ex. 8 | exemplary compound | 40 | 35 | + | 12 |
| | (11) (Mw = 50,000) | | | | |
| Ex. 9 | exemplary compound | 50 | 35 | + | 17 |
| | (25) (Mw = 60,000) | | | | |
| Ex. 10 | exemplary compound | 45 | 35 | + | 20 |
| | (41) (Mw = 70,000) | | | | |
| Comp. | polymethyl | 55 | 50 | x | 3 |
| Ex. 3 | methacrylate | | | | |
| | (Mw = 70,000) | | | | |

The results in Table 3 demonstrated that a negative-working lithographic printing plate precursor that contains a special polymer binder according to the present invention in its photopolymerizable layer exhibits not only an excellent printing durability with ordinary ink and an excellent on-press developability in lithographic printing using on-press development, but also an excellent printing durability with UV ink in lithographic printing using on-press development.

### Examples 11 to 20 and Comparative Examples 4 to 6

—Development with a Water-Soluble Resin-Containing Aqueous Solution—

Lithographic printing plate precursors were fabricated as described in Examples 1 to 10 and Comparative Examples 1 to 3 above. After photoexposure with an infrared laser using these lithographic printing plate precursors, development was carried out by the method described in (1) and printing was evaluated according to (2) to (4).

(1) Development with a Water-Soluble Resin-Containing Aqueous Solution

The lithographic printing plate precursor was imagewise photoexposed using a Trendsetter 3244 VX (Creo) equipped with an infrared semiconductor laser. The following conditions were used: output=6.4 W, external drum rotation rate=150 rpm, resolution=2400 dpi. A solid image and a fine line image were included in the photoexposed image.

Using the automatic developing apparatus shown in FIG. 1, the nonimage areas on the resulting photoexposed precursor were removed in the development section at 14 in the figure; this was followed by drying at 20 in the figure, but no water rinse was carried out in the water rinse section at 16 in the figure and no desensitization treatment was carried out at the desensitization section at 18 in the figure. Treatment bath (1) with the following composition was used as the treatment bath in the development section.

treatment bath (1)

| | |
|---|---|
| water | 100.00 g |
| benzyl alcohol | 1.00 g |
| polyoxyethylene naphthyl ether | 1.00 g |
| (average oxyethylene number n = 13) | |
| sodium dioctyl sulfosuccinate | 0.50 g |
| gum arabic | 1.00 g |
| ethylene glycol | 0.50 g |
| primary ammonium phosphate | 0.05 g |
| citric acid | 0.05 g |
| tetrasodium ethylenediaminetetraacetate | 0.05 g |

(2) Development Scum

The number of adhesions with a long diameter of at least 0.05 mm adhered per 1 m² nonimage area on the plate was scored visually.

+:0

Δ:fewer then 20

×:20 or more

(3) Fine Line Reproducibility

Printing was starting as described below using the following printing inks: (i) ordinary ink (TRANS-G(N) black ink (Dainippon Ink and Chemicals, Incorporated)) and (ii) UV ink (Best Cure UV-BF-VRO standard black ink (T & K TOKA Co., Ltd.)).

The developed plate was installed on the cylinder of a Dia IF-2 press from Mitsubishi Heavy Industries, Ltd.; fountain solution (IF102 etching solution from Fujifilm Corporation/water=3/97 (volume ratio)) and a printing ink as described above were supplied; and 100 impressions were printed at a printing rate of 6,000 impressions per hour.

After printing 100 impressions as described above and confirming that prints free of ink scumming in the nonimage areas were being obtained, 500 impressions were then printed. The fine line chart (the chart contained 10, 12, 14, 16, 18, 20, 25, 30, 35, 40, 60, 80, 100, and 200 μm fine line images and nonimage areas present in alternation at the same width) on the six-hundredth (total) print was inspected with a 25× loupe, and the fine line reproducibility was evaluated based on the fine line width that was reproduced without gaps. The results of the evaluation are shown in Table 4.

(4) Printing Durability

(i) Printing with Ordinary Ink

Printing was continued after the printing in the evaluation of fine line reproducibility described above. As the number of printed impressions grew, the ink receptivity declined due to gradual wear of the photopolymerizable layer, which resulted in a decline in the ink density on the printing paper. The printing durability was evaluated based on the number of impressions required for the ink density (reflection density) to decline 0.1 from the value at the start of printing. The results of the evaluation are shown in Table 4.

(ii) Printing with UV Ink

Printing was continued after the printing in the evaluation of fine line reproducibility described above. As the number of printed impressions grew, the ink receptivity declined due to gradual wear of the photopolymerizable layer, which resulted in a decline in the ink density on the printing paper. The printing durability was evaluated based on the number of impressions required for the ink density (reflection density) to decline 0.1 from the value at the start of printing. The results of the evaluation are shown in Table 4.

TABLE 4

| | | | ordinary ink | | UV ink | |
|---|---|---|---|---|---|---|
| | | | | printing | | printing |
| | | | fine line | durability | fine line | durability |
| | special polymer | | reproducibility | (thousands | reproducibility | (thousands |
| | binder | scum | (μm) | of impressions) | (μm) | of impressions) |
| Ex. 11 | exemplary compound | + | 14 | 50 | 14 | 20 |
| | (9) (Mw = 50,000) | | | | | |
| Ex. 12 | exemplary compound | + | 10 | 50 | 10 | 15 |
| | (10) (Mw = 50,000) | | | | | |
| Ex. 13 | exemplary compound | + | 12 | 50 | 12 | 18 |
| | (11) (Mw = 50,000) | | | | | |
| Ex. 14 | exemplary compound | + | 16 | 50 | 16 | 25 |
| | (25) (Mw = 60,000) | | | | | |
| Ex. 15 | exemplary compound | + | 14 | 60 | 14 | 27 |
| | (41) (Mw = 70,000) | | | | | |
| Comp. | polymethyl | x | 18 | 50 | 25 | 8 |
| Ex. 4 | methacrylate | | | | | |
| | (Mw = 70,000) | | | | | |
| Comp. | comparative special | Δ | 14 | 50 | 18 | 8 |
| Ex. 5 | polymer | | | | | |
| | (R-1) (Mw = 70,000) | | | | | |
| Ex. 16 | exemplary compound | + | 35 | 25 | 35 | 15 |
| | (9) (Mw = 50,000) | | | | | |
| Ex. 17 | exemplary compound | + | 30 | 25 | 30 | 10 |
| | (10) (Mw = 50,000) | | | | | |
| Ex. 18 | exemplary compound | + | 30 | 25 | 30 | 12 |
| | (11) (Mw = 50,000) | | | | | |
| Ex. 19 | exemplary compound | + | 40 | 25 | 40 | 17 |
| | (25) (Mw = 60,000) | | | | | |
| Ex. 20 | exemplary compound | + | 30 | 30 | 30 | 20 |
| | (41) (Mw = 70,000) | | | | | |
| Comp. | polymethyl | x | 40 | 25 | 45 | 6 |
| Ex. 6 | methacrylate | | | | | |
| | (Mw = 70,000) | | | | | |

### Examples 21 to 30 and Comparative Examples 7 to 9

—Development with a Water-Soluble Resin-Containing Aqueous Solution (Weakly Basic)

Lithographic printing plate precursors were fabricated as described in Examples 1 to 10 and Comparative Examples 1 to 3 above. After photoexposure with an infrared laser using these lithographic printing plate precursors, development was carried out by the method described in (1) and printing was evaluated according to (2) to (4).

(1) Development with a Water-Soluble Resin-Containing Aqueous Solution

The lithographic printing plate precursor was imagewise photoexposed using a Trendsetter 3244 VX (Creo) equipped with an infrared semiconductor laser. The following conditions were used: output=6.4 W, external drum rotation rate=150 rpm, resolution=2400 dpi. A solid image and a fine line image were included in the photoexposed image.

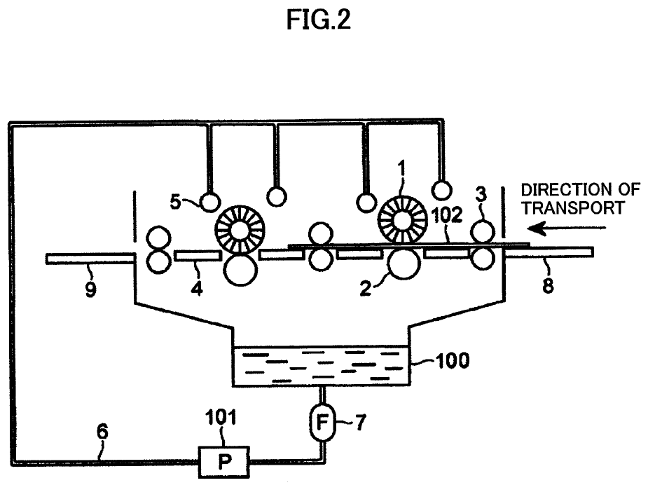

The resulting photoexposed precursor was processed with the automatic developing apparatus shown in FIG. 2. The treatment bath that was used was prepared by adding sodium hydroxide to the previously described treatment bath (1) to bring it to pH 9.0.

(2) Development Scum

The number of adhesions with a long diameter of at least 0.05 mm adhered per 1 m² nonimage area on the plate was scored visually.

+:0

Δ:fewer then 20

×:20 or more

(3) Fine Line Reproducibility

Printing was starting as described below using the following printing inks: (i) ordinary ink (TRANS-G(N) black ink (Dainippon Ink and Chemicals, Incorporated)) and (ii) UV ink (Best Cure UV-BF-WRO standard black ink (T & K TOKA Co., Ltd.)).

The developed plate was installed on the cylinder of a Dia IF-2 press from Mitsubishi Heavy Industries, Ltd.; fountain solution (IF 102 etching solution from Fujifilm Corporation/water=3/97 (volume ratio)) and a printing ink as described above were supplied; and 100 impressions were printed at a printing rate of 6,000 impressions per hour.

After printing 100 impressions as described above and confirming that prints free of ink scumming in the nonimage areas were being obtained, 500 impressions were then printed. The fine line chart (the chart contained 10, 12, 14, 16, 18, 20, 25, 30, 35, 40, 60, 80, 100, and 200 μm fine line images and nonimage areas present in alternation at the same width) on the six-hundredth (total) print was inspected with a 25× loupe, and the fine line reproducibility was evaluated based on the fine line width that was reproduced without gaps. The results of the evaluation are shown in Table 5.

(4) Printing Durability

(i) Printing with Ordinary Ink

Printing was continued after the printing in the evaluation of fine line reproducibility described above. As the number of printed impressions grew, the ink receptivity declined due to gradual wear of the photopolymerizable layer, which resulted in a decline in the ink density on the printing paper. The printing durability was evaluated based on the number of impressions required for the ink density (reflection density) to decline 0.1 from the value at the start of printing. The results of the evaluation are shown in Table 5.

(ii) Printing with UV Ink

Printing was continued after the printing in the evaluation of fine line reproducibility described above. As the number of printed impressions grew, the ink receptivity declined due to gradual wear of the photopolymerizable layer, which resulted in a decline in the ink density on the printing paper. The printing durability was evaluated based on the number of impressions required for the ink density (reflection density) to decline 0.1 from the value at the start of printing. The results of the evaluation are shown in Table 5.

TABLE 5

| | | | ordinary ink | | UV ink | |
|---|---|---|---|---|---|---|
| | | | | printing | | printing |
| | | | fine line | durability | fine line | durability |
| | special polymer | | reproducibility | (thousands | reproducibility | (thousands |
| | binder | scum | (μm) | of impressions) | (μm) | of impressions) |
| Ex. 21 | exemplary | + | 12 | 45 | 12 | 16 |
| | compound | | | | | |
| | (9) (Mw = 50,000) | | | | | |
| Ex. 22 | exemplary | + | 10 | 45 | 10 | 12 |
| | compound | | | | | |
| | (10) (Mw = 50,000) | | | | | |
| Ex. 23 | exemplary | + | 10 | 45 | 10 | 15 |
| | compound | | | | | |
| | (11) (Mw = 50,000) | | | | | |
| Ex. 24 | exemplary | + | 14 | 45 | 14 | 22 |
| | compound | | | | | |
| | (25) (Mw = 60,000) | | | | | |
| Ex. 25 | exemplary | + | 12 | 55 | 12 | 24 |
| | compound | | | | | |
| | (41) (Mw = 70,000) | | | | | |
| Comp. | polymethyl | x | 18 | 45 | 20 | 6 |
| Ex. 7 | methacrylate | | | | | |
| | (Mw = 70,000) | | | | | |
| Comp. | comparative | Δ | 16 | 45 | 15 | 6 |
| Ex. 8 | special polymer | | | | | |
| | (R-1) (Mw = 70,000) | | | | | |
| Ex. 26 | exemplary | + | 30 | 20 | 30 | 12 |
| | compound | | | | | |
| | (9) (Mw = 50,000) | | | | | |
| Ex. 27 | exemplary | + | 30 | 20 | 30 | 9 |
| | compound | | | | | |
| | (10) (Mw = 50,000) | | | | | |
| Ex. 28 | exemplary | + | 30 | 20 | 30 | 10 |
| | compound | | | | | |
| | (11) (Mw = 50,000) | | | | | |
| Ex. 29 | exemplary | + | 35 | 20 | 35 | 15 |
| | compound | | | | | |
| | (25) (Mw = 60,000) | | | | | |
| Ex. 30 | exemplary | + | 30 | 25 | 30 | 17 |
| | compound | | | | | |
| | (41) (Mw = 70,000) | | | | | |
| Comp. | polymethyl | x | 40 | 25 | 45 | 2 |
| Ex. 9 | methacrylate | | | | | |
| | (Mw = 70,000) | | | | | |

The results in Tables 4 and 5 demonstrated that a negative-working lithographic printing plate precursor that contains a special polymer binder according to the present invention in its photopolymerizable layer exhibits an excellent developability in lithographic printing that employs a water-soluble resin-containing aqueous solution in the development process and exhibits an excellent printing durability not only with ordinary ink, but also with UV ink.

### Examples 31 to 37 and Comparative Example 10

### Fabrication of the Lithographic Printing Plate Precursor

(1) Fabrication of the Support

The following processes (a) to (k) were carried out in succession to fabricate the aluminum support. The bath was drained off after each process and the water rinses using a nip roller.

(a) Mechanical Surface Roughening Treatment

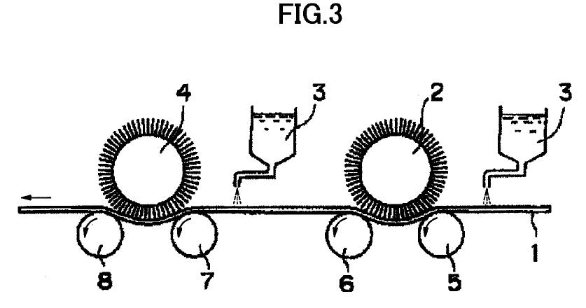

Using the apparatus shown in FIG. 3, a mechanical surface roughening treatment was carried out using rotating roller-shaped nylon brushes; this was carried out while feeding a polishing agent (pumice)+water suspension (specific gravity=1.12) as a polishing slurry to the surface of the aluminum plate. In FIG. 3, 1 refers to the aluminum plate; 2 and 4 refer to roller-shaped brushes; 3 refers to the polishing slurry; and 5, 6, 7, and 8 refer to support rollers. The average particle size in the polishing agent was 30 μm and the maximum particle size was 100 μm. The nylon brushes were nylon 6,10; the bristle length was 45 mm and the bristle diameter was 0.3 mm. The bristles in the nylon brush were densely implanted in holes in a 300 mmφ stainless steel cylinder. Three rotating brushes were used. The gap between the two support rollers (200 mmφ) underneath a brush was 300 mm. The brush rollers were pressed down until the load on the drive motor rotating the brush reached +7 kW with respect to the load prior to the application of the brush roller to the aluminum plate. The direction of brush rotation was the same as the transport direction of the aluminum plate. The brushes were rotated at 200 rpm.

(b) Alkali Etching Treatment

The aluminum plate yielded by the preceding process was etched by spraying with an aqueous solution (70° C.) containing 2.6 mass % sodium hydroxide and 6.5 mass % aluminum ion. 10 g/m² of the aluminum plate was dissolved. This was followed by a water rinse by spraying.

(c) Desmutting

Desmutting was carried out by spraying with a 1 mass % aqueous nitric acid solution (contained 0.5 mass % aluminum ion) at 30° C.; this was followed by a water rinse by spraying. The aqueous nitric acid solution used for desmutting was the waste effluent from the electrochemical surface roughening process that used alternating current in an aqueous nitric acid solution.

(d) Electrochemical Surface Roughening Process

Continuous electrochemical surface roughening was carried out using 60 Hz alternating voltage. The electrolyte solution was a 10.5 g/L aqueous nitric acid solution (contained 5 g/L aluminum ion and 0.007 mass % ammonium ion); the bath temperature was 50° C. For the AC power source waveform, a trapezoidal square wave alternating current with a TP (time required for the current value to go from zero to the peak) of 0.8 msec and a duty ratio of 1:1 was used, and the electrochemical surface roughening was carried out using a carbon electrode as the counterelectrode. Ferrite was used as an auxiliary anode.

The current density was 30 A/dm² at the current peak value, and the amount of electricity was 220 C/dm² as the sum of the amount of the electricity when the aluminum plate was operating as an anode. 5% of the current flowing from the power source was branched to the auxiliary anode. This process was followed by a water rinse by spraying.

(e) Alkali Etch

Etching was carried out at 32° C. by spraying the aluminum plate with an aqueous solution that had a sodium hydroxide concentration of 26 mass % and an aluminum ion concentration of 6.5 mass %. 0.50 g/m² of the aluminum plate was dissolved. This step removed the smut component, which consisted mainly of aluminum hydroxide produced during the electrochemical surface roughening treatment carried out in the preceding step using alternating current; this step also dissolved the edge region of the produced pits and thereby smoothed these edge regions. This step was followed by a water rinse by spraying.

(f) Desmutting

Desmutting was carried out by spraying with a 30° C. aqueous solution having a nitric acid concentration of 15 mass % (contained 4.5 mass % aluminum ion); this was followed by a water rinse by spraying. The aqueous nitric acid solution used for this desmutting was the waste effluent from the step of electrochemical surface roughening that used alternating current in aqueous nitric acid solution.

(g) Electrochemical Surface Roughening Treatment

Continuous electrochemical surface roughening was carried out using 60 Hz alternating voltage. The electrolyte solution was a 5.0 g/L aqueous hydrochloric acid solution (contained 5 g/L aluminum ion); the bath temperature was 35° C. A trapezoidal square wave alternating current with a TP (time required for the current value to go from zero to the peak) of 0.8 msec and a duty ratio of 1:1 was used for the AC power source waveform, and the electrochemical surface roughening was carried out using a carbon electrode as the counterelectrode. Ferrite was used as an auxiliary anode.

The current density was 25 A/dm² at the current peak value, and the amount of electricity was 50 C/dm² as the sum of the amount of the electricity when the aluminum plate was operating as an anode. This process was followed by a water rinse by spraying.

(h) Alkali Etch

Etching was carried out at 32° C. by spraying the aluminum plate with an aqueous solution that had a sodium hydroxide concentration of 26 mass % and an aluminum ion concentration of 6.5 mass %. 0.10 g/m² of the aluminum plate was dissolved. This step removed the smut component, which consisted mainly of aluminum hydroxide produced during the electrochemical surface roughening treatment carried out in the preceding step using alternating current; this step also dissolved the edge region of the produced pits and thereby smoothed these edge regions. This step was followed by a water rinse by spraying.

(i) Desmutting

Desmutting was carried out by spraying with a 60° C. aqueous solution that had a sulfuric acid concentration of 25 mass % (contained 0.5 mass % aluminum ion); this was followed by a water rinse by spraying.

(j) Anodic Oxidation

An anodic oxidation treatment was carried out using an anodic oxidation apparatus (first and second electrolysis sections, length=6 m each; first and second current feed sections, length=3 m each; first and second current feed sections, length=2.4 m). Sulfuric acid was used for the electrolyte bath provided to the first and second electrolysis sections. The electrolyte bath had a sulfuric acid concentration in each case of 50 g/L (contained 0.5 mass % aluminum ion), and the temperature was 20° C. This was followed by a water rinse by spraying.

(k) Treatment with Alkali Metal Silicate

The aluminum support yielded by the anodic oxidation step was treated with alkali metal silicate (silicate treatment) by immersion for 10 seconds in a treatment tank that contained a 1 mass % aqueous solution of #3 sodium silicate at 30° C. This was followed by a water rinse using a spray of well water to obtain a support whose surface had been subjected to a silicate hydrophilization treatment.

(2) Intermediate Layer Formation

The below-described coating fluid for intermediate layer formation was then coated on the aluminum support afforded by the surface treatment described above; coating was carried out so as to provide a dry coating weight of 10 mg/M² and was followed by drying.

[Coating fluid for intermediate layer formation]

| | | |
|---|---|---|
| compound (1), see below | 0.017 | mass part |
| methanol | 9.00 | mass parts |
| water | 1.00 | mass part |

compound (1)

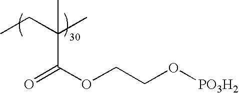

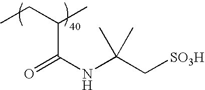

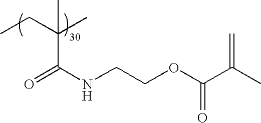

(3) Photopolymerizable Layer Formation and Protective Layer Formation

The below-described coating fluid for photopolymerizable layer formation was prepared and was coated using a wire bar on the intermediate layer that had been formed as described above. Drying was carried out for 34 seconds at 125° C. using a convection dryer. The coating weight after drying was 1.4 g/m².

(Coating fluid for photopolymerizable layer formation)

| | |
|---|---|
| infrared absorber (IR-1) | 0.038 mass part |
| polymerization initiator A (S-1) | 0.061 mass part |
| polymerization initiator B (I-1) | 0.094 mass part |
| mercapto compound (E-1) | 0.015 mass part |
| ethylenically unsaturated compound | 0.425 mass part |
| (M-1) (product name: A-BPE-4 from | |
| Shin-Nakamura Chemical Co., Ltd.) | |
| binder polymer (described in Table 6) | 0.623 mass part |
| additive (T-1) | 0.079 mass part |
| polymerization inhibitor (Q-1) | 0.0012 mass part |
| Ethyl Violet (EV-1) | 0.021 mass part |
| fluorosurfactant (Megaface F-780-F | |
| from Dainippon Ink and Chemicals, | |
| Incorporated, 30 mass % solution in | |
| methyl isobutyl ketone (MIBK)) | 0.0081 mass part |
| methyl ethyl ketone | 5.886 mass parts |
| methanol | 2.733 mass parts |
| 1-methoxy-2-propanol | 5.886 mass parts |

TABLE 6

| | | binder polymers |
|---|---|---|
| examples | 31 | exemplary compound (54) (Mw = 50,000) |
| | 32 | exemplary compound (55) (Mw = 50,000) |
| | 33 | exemplary compound (56) (Mw = 50,000) |
| | 34 | exemplary compound (57) (Mw = 50,000) |
| | 35 | exemplary compound (58) (Mw = 50,000) |
| | 36 | exemplary compound (59) (Mw = 50,000) |
| | 37 | exemplary compound (60) (Mw = 50,000) |
| comparative example | 10 | polymethyl methacrylate (Mw = 50,000) |

The structures of the infrared absorber (IR-1), polymerization initiator A (S-1), polymerization initiator B (I-1), mercapto compound (E-1), polymerizable monomer (M-1), additive (T-1), polymerization inhibitor (Q-1), and Ethyl Violet (EV-1) used in the coating fluid for photopolymerizable layer formation are given below.

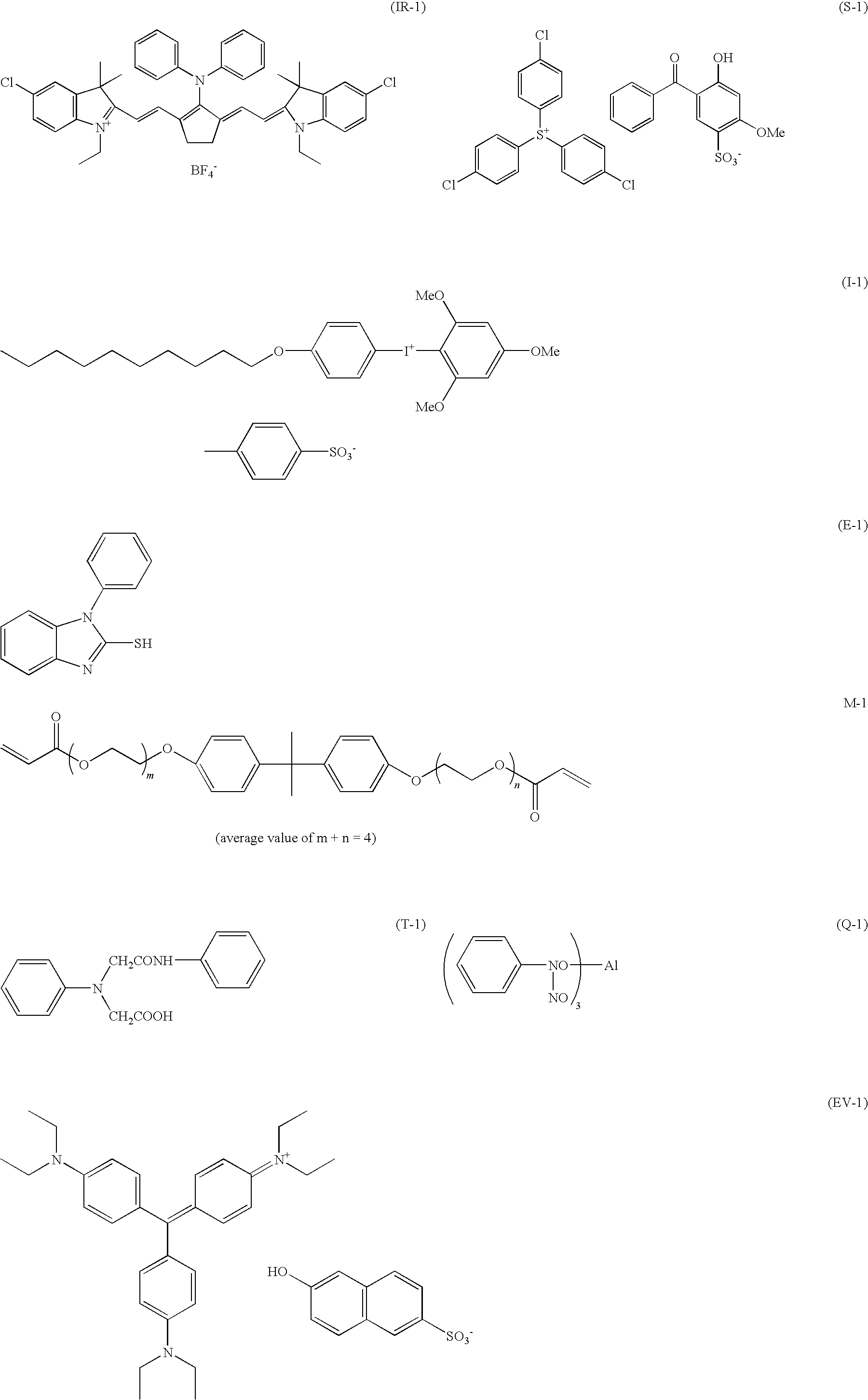

### <Lower Protective Layer Formation>

A mixed aqueous solution (the coating fluid for lower protective layer formation) of synthetic mica (Somashif MEB-3L, 3.2% aqueous dispersion, from Co-op Chemical Co., Ltd.), polyvinyl alcohol (Gohselan CKS-50, degree of saponification=99 mol %, degree of polymerization=300, sulfonic acid-modified polyvinyl alcohol, from Nippon Synthetic Chemical Industry Co., Ltd.), surfactant A (Emalex 710 from Nihon Emulsion Co., Ltd.), and surfactant B (Adeka Pluronic P-84 from the Adeka Corporation) was coated with a wire bar on the photopolymerizable layer that had been formed. This was followed by drying for 30 seconds at 125° C. in a convection dryer.

The proportions in this mixed aqueous solution (the coating fluid for lower protective layer formation) were synthetic mica (solids fraction)/polyvinyl alcohol/surfactant A/surfactant B=7.5/89/2/1.5 (mass %), and the coating weight (post-drying coating weight) was 0.5 g/m².

### <Upper Protective Layer Formation>

A mixed aqueous solution (the coating fluid for upper protective layer formation) of organic filler (Art Pearl J-7P, from Negami Chemical Industrial Co., Ltd.), synthetic mica (Somashif MEB-3L, 3.2% aqueous dispersion, from Co-op Chemical Co., Ltd.), polyvinyl alcohol (L-3266, degree of saponification=87 mol %, degree of polymerization=300, sulfonic acid-modified polyvinyl alcohol, from Nippon Synthetic Chemical Industry Co., Ltd.), thickener (Celogen FS-B from Dai-ichi Kogyo Seiyaku Co., Ltd.), and surfactant (Emalex 710 from Nihon Emulsion Co., Ltd.) was coated with a wire bar on the lower protective layer. This was followed by drying for 30 seconds at 125° C. in a convection dryer.

The proportions in this mixed aqueous solution (the coating fluid for upper protective layer formation) were organic filler/synthetic mica (solids fraction)/polyvinyl alcohol/thickener/surfactant=3.2/2.0/80.5/11.5/2.8 (mass %), and the coating weight (post-drying coating weight) was 1.76 g/m².

Photoexposure and Development of, Printing with, and Evaluation of the Lithographic Printing Plate Precursors

The lithographic printing plate precursors obtained as described above were photoexposed, developed, and dried in the sequence given.

Imagewise photoexposure was carried out using an infrared semiconductor laser (Trendsetter 3244 VX (Creo) equipped with a water-cooled 40 W infrared semiconductor laser) as the light source (setter) for photoexposure. The conditions were as follows: output=9 W, external drum rotation rate=210 rpm, resolution=2,400 dpi.

Photoexposure was followed, without a heat treatment and without a water rinse, by development with the automatic developer with the structure shown in FIG. 2, using in each case the treatment bath (3) with the composition shown below for no more than 30 seconds. This automatic developer had two rotating brush rolls. The first brush roll had a 50 mm outer diameter and was fitted with polybutylene terephthalate fibers (bristle diameter=200 μm, bristle length=17 mm) and was rotated at 200 rpm (peripheral velocity at the brush tip=0.52 m/sec) in the same direction as the transport direction. The second brush roll had a 50 mm outer diameter and was fitted with polybutylene terephthalate fibers (bristle diameter=200 μm, bristle length=17 mm) and was rotated at 200 rpm (peripheral velocity at the brush tip=0.52 m/sec) in the direction opposite from the transport direction. The lithographic printing plate precursor was transported at a transport velocity of 100 cm/min.

The development bath was fed to the plate surface as a shower from a spray pipe under the action of a circulation pump. The development bath tank capacity was 10 liters.

Development bath (3) (pH 9.8)

| | |
|---|---|
| water | 8619.8 g |
| sodium carbonate | 200 g |
| sodium bicarbonate | 100 g |
| Newcol B4SN (as 100%) | 400 g |
| gum arabic | 400 g |
| phosphate-modified starch (Petrocoat HN25 | 200 g |
| from Nippon Starch Chemical Co., Ltd.) | |
| EDTA 4Na | 80 g |
| 2-bromo-2-nitropropane-1,3-diol | 0.1 g |
| 2-methyl-4-isothiazolin-3-one | 0.1 g |

Using the same methods as described in the preceding examples, the lithographic printing plates obtained in the described manner were evaluated for development scum, fine line reproducibility, and printing durability. The results are shown in Table 7.

TABLE 7

| | | | ordinary ink | | UV ink | |
|---|---|---|---|---|---|---|
| | | | | printing | | printing |
| | | | fine line | durability | fine line | durability |
| | special polymer | | reproducibility | (thousands | reproducibility | (thousands |
| | compound | scum | (μm) | of impressions) | (μm) | of impressions) |
| Ex. 31 | exemplary | + | 10 | 40 | 12 | 12 |
| | compound | | | | | |
| | (54) (Mw = 50,000) | | | | | |
| Ex. 32 | exemplary | + | 10 | 40 | 10 | 12 |
| | compound | | | | | |
| | (55) (Mw = 50,000) | | | | | |
| Ex. 33 | exemplary | + | 10 | 45 | 12 | 15 |
| | compound | | | | | |
| | (56) (Mw = 50,000) | | | | | |
| Ex. 34 | exemplary | + | 10 | 45 | 12 | 20 |
| | compound | | | | | |
| | (57) (Mw = 50,000) | | | | | |
| Ex. 35 | exemplary | + | 10 | 50 | 10 | 22 |
| | compound | | | | | |
| | (58) (Mw = 50,000) | | | | | |
| Ex. 36 | exemplary | + | 10 | 65 | 10 | 30 |
| | compound | | | | | |
| | (59) (Mw = 50,000) | | | | | |
| Ex. 37 | exemplary | + | 12 | 55 | 12 | 20 |
| | compound | | | | | |
| | (60) (Mw = 50,000) | | | | | |
| Comp. | polymethyl | x | 30 | 20 | 30 | 6 |
| Ex. 10 | methacrylate | | | | | |
| | (Mw = 50,000) | | | | | |

### Examples 38 and 39 and Comparative Example 11

### Fabrication of the Lithographic Printing Plate Precursors

(1) Production of the Support

0.3 mm-thick aluminum plate was etched by immersion for 25 seconds in 10 mass % sodium hydroxide at 60° C. and then rinsed with running water, neutralized by rinsing with 20 mass % nitric acid, and subsequently rinsed with water. This was then subjected to an electrolytic surface roughening treatment in a 1 mass % aqueous nitric acid solution using sine wave alternating current and using an amount of electricity during anodic operation of 300 C/dm². Desmutting was subsequently performed by immersion for 5 seconds in 1 mass % aqueous sodium hydroxide solution at 40° C. and then immersion for 40 seconds in a 30 mass % aqueous sulfuric acid solution at 60° C. This was followed by anodic oxidation for 2 minutes at a current density of 2 A/dm² in 20 mass % aqueous sulfuric acid solution to thereby provide a thickness of 2.7 g/m² for the anodic oxidation film. The resulting surface roughness was measured at 0.3 μm (reported as Ra according to JIS B 0601).

The aluminum support fabricated in the described manner was coated with the high-sensitivity photopolymerizable composition shown below at a dry coating mass of 1.4 g/m²; drying for 1 minute at 100° C. then yielded the photopolymerizable layer.

(Photopolymerizable composition)

| | | |
|---|---|---|
| ethylenically unsaturated bond-containing | 4.0 | mass parts |
| compound (compound A) | | |
| binder polymer (shown in Table 8) | 2.0 | mass parts |
| sensitizing dye (C-1) | 0.32 | mass part |
| polymerization initiator (D-1) | 0.61 | mass part |
| chain-transfer agent (E-1) | 0.57 | mass part |
| N-nitrosophenylhydroxylamine, aluminum salt | 0.020 | mass part |
| s-phthalocyanine dispersion | 0.71 | mass part |
| nonionic fluorosurfactant, Megaface F780 | 0.016 | mass part |
| (Dainippon Ink and Chemicals, Incorporated) | | |
| methyl ethyl ketone | 47 | mass parts |
| propylene glycol monomethyl ether | 45 | mass parts |

sensitizing dye C-1

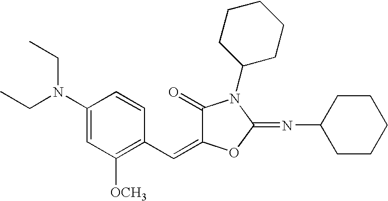

polymerization initiator D-1

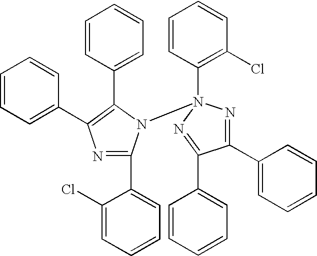

chain-transfer agent E-1

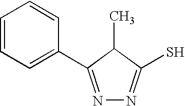

compound A

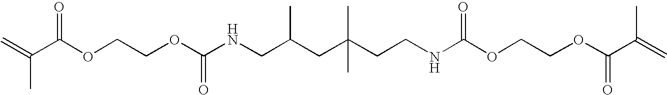

TABLE 8

| | | binder polymers |
|---|---|---|
| examples | 38 | exemplary compound (54) (Mw = 50,000) |
| | 39 | exemplary compound (57) (Mw = 50,000) |
| comparative example | 11 | polymethyl methacrylate (Mw = 50,000) |

### <Protective Layer Formation>

The coating fluid for protective layer formation described below was bar coated on the photopolymerizable layer formed in the manner described above; this was followed by drying for 70 seconds at 125° C. to form a protective layer with a drying coating weight of 1.25 g/m².

Coating fluid for protective layer formation

| | |
|---|---|
| mica dispersion, see below | 0.6 g |
| sulfonic acid-modified polyvinyl alcohol | 0.8 g |
| (Gohselan CKS-50, degree of saponification = | |
| 99 mol %, average degree of polymerization = | |
| 300, degree of modification = approximately | |
| 0.4 mol %, from Nippon Synthetic Chemical | |
| Industry Co., Ltd.) | |
| poly(vinylpyrrolidone/vinyl acetate (1/1)) | 0.001 g |
| (molecular weight = 70,000) | |
| surfactant (Emalex 710, Nihon Emulsion | 0.002 g |
| Co., Ltd.) | |
| water | 13 g |

### (Preparation of the Mica Suspension)

32 g synthetic mica (Somashif ME-100 from Co-op Chemical Co., Ltd., aspect ratio at least 1000) was added to 368 g water, and dispersion was carried out using a homogenizer until the average particle size reached 0.5 μm (laser scattering method) to yield the mica suspension.

Photoexposure and Development of, Printing with, and Evaluation of the Lithographic Printing Plates

Each of the resulting lithographic printing plate precursors was imagewise photoexposed using a Violet semiconductor laser Vx-9600 platesetter from FFEI (equipped with an InGaN-type semiconductor laser, 405 nm±10 nm emission/output 30 mW). Imaging was done at a plate surface photoexposure dose of 0.05 mJ/cm² using an FM screen (TAFFETA 20 from FUJIFILM Corporation) at a resolution of 2438 dpi.

Then, after preheating for 30 seconds at 100° C., development was carried out with the automatic developing apparatus with the structure shown in FIG. 1, using in each case the treatment bath (4) with the composition shown below. This automatic developer had two rotating brush rolls. The first brush roll had a 50 mm outer diameter and was fitted with polybutylene terephthalate fibers (bristle diameter=200 μm, bristle length=17 mm) and was rotated at 200 rpm (peripheral velocity at the brush tip=0.52 m/sec) in the same direction as the transport direction. The second brush roll had a 50 mm outer diameter and was fitted with polybutylene terephthalate fibers (bristle diameter=200 μm, bristle length=17 mm) and was rotated at 200 rpm (peripheral velocity at the brush tip=0.52 m/sec) in the direction opposite from the transport direction. The to lithographic printing plate precursor was transported at a transport velocity of 100 cm/min.

The development bath was fed to the plate surface as a shower from a spray pipe under the action of a circulation pump. The development bath tank capacity was 10 liters.

Development bath (4) (pH 9.8)

| | |
|---|---|
| water | 8260 g |
| sodium carbonate | 200 g |
| sodium bicarbonate | 100 g |
| Eleminol MON (as 100%) | 350 g |
| gum arabic | 400 g |
| phosphate-modified starch (Petrocoat HN25 | 200 g |
| from Nippon Starch Chemical Co., Ltd.) | |
| EDTA 4Na | 80 g |
| 2-bromo-2-nitropropane-1,3-diol | 0.1 g |
| 2-methyl-4-isothiazolin-3-one | 0.1 g |

Using the same methods as described in the preceding examples, the lithographic printing plates obtained in the described manner were evaluated for development scum, fine line reproducibility, and printing durability. The results are shown in Table 9.

TABLE 9

| | | | ordinary ink | | UV ink | |
|---|---|---|---|---|---|---|
| | | | | printing | | printing |
| | | | fine line | durability | fine line | durability |
| | special polymer | | reproducibility | (thousands | reproducibility | (thousands |
| | compound | scum | (μm) | of impressions) | (μm) | of impressions) |
| Ex. 38 | exemplary | + | 20 | 45 | 20 | 15 |
| | compound | | | | | |
| | (54) (Mw = 50,000) | | | | | |
| Ex. 39 | exemplary | + | 20 | 60 | 20 | 25 |
| | compound | | | | | |
| | (57) (Mw = 50,000) | | | | | |
| Comp. | polymethyl | x | 30 | 25 | 30 | 7 |
| Ex. 11 | methacrylate | | | | | |
| | (Mw = 50,000) | | | | | |

The results shown in Tables 7 and 9 demonstrated that the platemaking method of the present invention for lithographic printing plates exhibits an excellent developability and an excellent fine line reproducibility in methods that employ a water-soluble resin-containing aqueous solution in the development process, and also demonstrated that an excellent printing durability not only with ordinary ink, but also with UV ink is obtained in lithographic printing that uses a lithographic printing plate provided by platemaking in this manner.

What is claimed is:

1. A negative-working lithographic printing plate precursor comprising on a hydrophilic support a photopolymerizable layer that contains a polymer compound that has the urea bond in a side chain position and a hydrophilic group.

2. The negative-working lithographic printing plate precursor according to claim 1, wherein the polymer compound has a unit derived from a monomer that has the urea bond in the side chain position and that is represented by the following general formula (I) 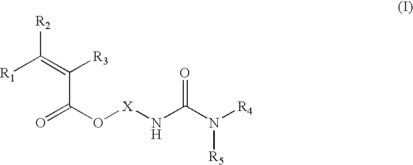
(in the formula, R₁ and R₂ each represent a hydrogen atom, a halogen atom, an alkyl, aryl, heterocyclic group, or carboxyl group or a salt thereof; R₃ represents a hydrogen atom, a halogen atom, an alkyl or aryl group; R₄ and R₅ each independently represent a hydrogen atom, an alkyl, aryl, or heterocyclic group; and X represents a divalent linking group).

3. The negative-working lithographic printing plate precursor according to claim 1, wherein the hydrophilic group comprises an alkylene oxide structure represented by the following general formula (II) 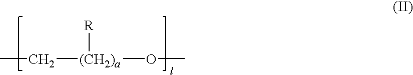
(in the formula, R represents a hydrogen atom or methyl group; a is 1, 3, or 5; and I is an integer of 1 to 9).

4. The negative-working lithographic printing plate precursor according to of claim 1, wherein the polymer compound has an ethylenically unsaturated bond in the side chain position.

5. The negative-working lithographic printing plate precursor according to claim 1, wherein the photopolymerizable layer contains a sensitizing dye, polymerization initiator, and polymerizable monomer.

6. The negative-working lithographic printing plate precursor according to claim 1, wherein the photopolymerizable layer contains an infrared absorber, polymerization initiator, and polymerizable monomer.

7. The negative-working lithographic printing plate precursor according to claim 1, wherein the photopolymerizable layer contains microcapsules or a microgel.

8. The negative-working lithographic printing plate precursor according to claim 1, wherein a mass ratio in the photopolymerizable layer between binder polymer that contains the polymer compound, having the urea bond in a side chain position and a hydrophilic group, and the polymerizable monomer is 3/2 to 1/3.

9. The negative-working lithographic printing plate precursor according to claim 1, having an undercoat layer between the hydrophilic support and the photopolymerizable layer, said undercoat layer comprising a compound that has a group that adsorbs to the hydrophilic support and an addition-polymerizable ethylenic double bond.

10. The negative-working lithographic printing plate precursor according to claim 1, wherein the photopolymerizable layer can be removed by printing ink and/or fountain solution.

11. The negative-working lithographic printing plate precursor according to claim 10, wherein the printing ink is a UV ink.

12. A method of lithographic printing comprising the steps of:
mounting the negative-working lithographic printing plate precursor according to claim 1 on a press and thereafter subjecting the negative-working lithographic printing plate precursor to imagewise exposure with a laser, or subjecting the negative-working lithographic printing plate precursor to imagewise exposure with a laser and thereafter mounting the same on a press; and
removing unexposed areas of the photopolymerizable layer by feeding printing ink and/or fountain solution to the negative-working lithographic printing plate precursor to perform printing.

13. The lithographic printing method according to claim 12, wherein the printing ink is a UV ink.

14. The negative-working lithographic printing plate precursor according to claim 1, wherein the photopolymerizable layer can be removed by an aqueous solution that contains a water-soluble resin.

15. The negative-working lithographic printing plate precursor according to claim 1, wherein the photopolymerizable layer can be removed by an aqueous solution that contains a water-soluble resin and that has a pH in the range from 8.5 to 10.8.

16. The negative-working lithographic printing plate precursor according to claim 1, wherein the photopolymerizable layer can be removed by an aqueous solution that contains carbonate ion, bicarbonate ion, and water-soluble resin and that has a pH in the range from 8.5 to 10.8.

17. The negative-working lithographic printing plate precursor according to claim 1, wherein the hydrophilic group is an acid group.

18. The negative-working lithographic printing plate precursor according to claim 17, wherein the acid group is a carboxyl group.

19. A method of lithographic printing comprising the steps of:
imagewise exposing with a laser the negative-working lithographic printing plate precursor according to claim 1;
removing unexposed areas of the photopolymerizable layer by carrying out a development process by effecting contact with an aqueous solution that contains a water-soluble resin and rubbing with a brush;
mounting the lithographic printing plate precursor on a press; and
printing while supplying printing ink and/or fountain solution to the negative-working lithographic printing plate precursor.
